(19) United States
(12) Patent Application Publication
(10) Pub. No.: US 2016/0268256 A1
(43) Pub. Date: Sep. 15, 2016

(54) COMPLEMENTARY METAL-OXIDE SEMICONDUCTOR (CMOS) TRANSISTOR AND TUNNEL FIELD-EFFECT TRANSISTOR (TFET) ON A SINGLE SUBSTRATE

(71) Applicant: QUALCOMM Incorporated, San Diego, CA (US)

(72) Inventors: Bin Yang, San Diego, CA (US); Xia Li, San Diego, CA (US); Jun Yuan, San Diego, CA (US)

(21) Appl. No.: 14/657,021

(22) Filed: Mar. 13, 2015

(51) Int. Cl. H01L 27/088; H01L 29/161; H01L 21/02; H01L 29/78; H01L 21/8234; H01L 29/16; H01L 29/165

(52) U.S. Cl. CPC H01L 27/088; H01L 29/1608; H01L 29/161; H01L 29/165; H01L 29/7851; H01L 29/7848; H01L 21/823418; H01L 21/02529; H01L 21/02532; H01L 21/823487; H01L 29/7827

(57) ABSTRACT

An apparatus includes a structure that includes a single substrate, a planar complementary metal-oxide semiconductor (CMOS) transistor formed on the single substrate, a planar tunnel field-effect transistor (TFET) formed on the single substrate, and a mobility enhancement strength layer included in the planar CMOS transistor or included in the planar TFET.

### I. FIELD

The present disclosure is generally related to complementary metal-oxide semiconductor (CMOS) transistor and tunnel field-effect transistor (TFET) on a single substrate.

### II. DESCRIPTION OF RELATED ART

Advances in technology have resulted in smaller and more powerful personal computing devices. For example, there exist a variety of portable personal computing devices, including wireless computing devices, such as mobile phones, smart phones, netbooks, and laptops that are small, lightweight, and easily carried by users. More specifically, such devices may communicate voice and data packets over wireless networks. Many such devices incorporate additional features to provide enhanced functionality for end users. For example, a smart phone can also include a digital still camera, a digital video camera, a digital recorder, and an audio file player. Also, such devices can process executable instructions, including software applications, such as a web browser application, that can be used to access the Internet. As such, these devices can include significant computing capabilities.

As technology advances, computing devices may become more power efficient, have higher performance, or both. An integrated circuit chip (e.g., a system-on-chip (SoC)) with complementary metal-oxide semiconductor (CMOS) transistors may have higher performance (e.g., speed) than a SoC with tunnel field-effect transistor (TFET) technology and a SoC that uses TFET technology may have lower power consumption than a SoC with CMOS. For example, a drain current of a transistor (e.g., a CMOS transistor and/or a TFET) may increase as gate voltage increases. A higher drain current may correspond to a higher speed of the transistor. A higher gate voltage may correspond to higher power consumption of the transistor. The CMOS transistor may achieve a higher drain current (e.g., a first drain current) than the TFET at a first gate voltage that is higher than a particular gate voltage. The TFET may have a higher drain current (e.g., a second drain current) than the CMOS transistor at a second gate voltage that is lower than the particular gate voltage. The first drain current may be higher than the second drain current. The second gate voltage may be lower than the first gate voltage. The CMOS transistor may thus achieve a higher speed than the TFET, but at a higher power consumption. Using the CMOS transistor may incur higher power costs while using the TFET may incur a performance penalty.

### III. SUMMARY

An electronic circuit (e.g., an integrated circuit) may include CMOS transistors and TFET technology. The CMOS transistors may perform operations faster than TFET devices. For example, a CMOS transistor may have a higher processing speed (e.g., a higher drain current) than a TFET. TFET devices may consume less power than the CMOS transistors. A balance between performance and power consumption may be reached by assigning higher priority (e.g., critical) operations to CMOS devices and assigning lower priority (e.g., non-critical) operations to TFET devices.

In a particular aspect, an apparatus includes a structure that has a single substrate, a planar complementary metal-oxide semiconductor (CMOS) transistor, a planar tunnel field-effect transistor (TFET), and a mobility enhancement strength layer. The planar CMOS transistor is formed on the single substrate. The TFET is formed on the single substrate. The mobility enhancement strength layer is included in the planar CMOS transistor or included in the planar TFET. The mobility enhancement strength layer may include at least one of silicon-carbide or silicon-germanium.

In another aspect, an apparatus includes a structure that has a single substrate, a complementary metal-oxide semiconductor (CMOS) transistor, and a tunnel field-effect transistor (TFET). The CMOS transistor is formed on the single substrate. The TFET is formed on the single substrate. At least one of the CMOS transistor or the TFET is configured to support a current flow direction between a source and a drain that is perpendicular to the substrate.

In another aspect, a method of forming a structure includes forming a complementary metal-oxide semiconductor (CMOS) transistor on a single substrate. The method also includes forming a tunnel field-effect transistor (TFET) on the single substrate. At least one of the CMOS transistor or the TFET is configured to support a current flow direction between a source and a drain that is perpendicular to the single substrate.

In another aspect, a method of forming a structure includes forming a planar complementary metal-oxide semiconductor (CMOS) transistor on a single substrate. The method also includes forming a planar tunnel field-effect transistor (TFET) on the single substrate. At least one of the planar CMOS transistor or the planar TFET includes a mobility enhancement strength layer. The mobility enhancement strength layer may include at least one of silicon-carbide or silicon-germanium.

In another aspect, a computer-readable medium stores data which is usable by fabrication equipment to form a device. The device includes a single substrate. The device also includes a planar complementary metal-oxide semiconductor (CMOS) transistor formed on the single substrate. The device further includes a planar tunnel field-effect transistor (TFET) formed on the single substrate. The device also includes a mobility enhancement strength layer included in the planar CMOS transistor or included in the planar TFET.

In another aspect, a computer-readable medium stores data which is usable by fabrication equipment to form a device. The device includes a single substrate. The device also includes a complementary metal-oxide semiconductor (CMOS) transistor formed on the single substrate. The semiconductor device further includes a tunnel field-effect transistor (TFET) formed on the single substrate. At least one of the CMOS transistor or the TFET is configured to support a current flow direction between a source and a drain that is perpendicular to the single substrate.

One particular advantage provided by at least one of the disclosed embodiments is that a balance between performance and power consumption may be reached by assigning higher priority (e.g., critical) operations to CMOS devices of an integrated circuit and assigning lower priority (e.g., non-critical) operations to TFET devices of the integrated circuit.

Other aspects, advantages, and features of the present disclosure will become apparent after review of the entire application, including the following sections: Brief Description of the Drawings, Detailed Description, and the Claims.

### IV. BRIEF DESCRIPTION OF THE DRAWINGS

FIG. 1 is a diagram of a top view of a structure during at least one stage in a process of fabricating an electronic device;

FIG. 2 is a diagram of a top view of another structure during at least one stage in a process of fabricating an electronic device;

FIG. 3 is a flow chart of a particular illustrative embodiment of a method of fabricating the structure of FIG. 1;

FIG. 4 is a diagram of a side view of the structure of FIG. 1 during at least one stage in a process of fabricating an electronic device;

FIG. 5 is a diagram of a side view of the structure of FIG. 1 during another stage in the process of fabricating the electronic device;

FIG. 6 is a diagram of a side view of the structure of FIG. 1 during another stage in the process of fabricating the electronic device;

FIG. 7 is a diagram of a side view of the structure of FIG. 1 during another stage in the process of fabricating the electronic device;

FIG. 8 is a diagram of a side view of the structure of FIG. 1 during another stage in the process of fabricating the electronic device;

FIG. 9 is a diagram of a side view of the structure of FIG. 1 during another stage in the process of fabricating the electronic device;

FIG. 10 is a diagram of a side view of the structure of FIG. 1 during another stage in the process of fabricating the electronic device;

FIG. 11 is a diagram of a side view of the structure of FIG. 1 during another stage in the process of fabricating the electronic device;

FIG. 12 is a diagram of a side view of the structure of FIG. 1 during another stage in the process of fabricating the electronic device;

FIG. 13 is a diagram of a side view of the structure of FIG. 1 during another stage in the process of fabricating the electronic device;

FIG. 14 is a diagram of a side view of the structure of FIG. 1 during another stage in the process of fabricating the electronic device;

FIG. 15 is a diagram of a side view of the structure of FIG. 1 during another stage in the process of fabricating the electronic device;

FIG. 16 is a diagram of a side view of the structure of FIG. 1 during another stage in the process of fabricating the electronic device;

FIG. 17 is a diagram of a side view of the structure of FIG. 1 during another stage in the process of fabricating the electronic device;

FIG. 18 is a diagram of a side view of the structure of FIG. 1 during another stage in the process of fabricating the electronic device;

FIG. 19 is a diagram of a side view of the structure of FIG. 1 during another stage in the process of fabricating the electronic device;

FIG. 20 is a diagram of a side view of the structure of FIG. 1 during another stage in the process of fabricating the electronic device;

FIG. 21 is a diagram of a side view of the structure of FIG. 1 during another stage in the process of fabricating the electronic device;

FIG. 22 is a diagram of a side view of the structure of FIG. 1 during another stage in the process of fabricating the electronic device;

FIG. 23 is a diagram of a side view of the structure of FIG. 1 during another stage in the process of fabricating the electronic device;

FIG. 24 is a diagram of a side view of the structure of FIG. 1 during another stage in the process of fabricating the electronic device;

FIG. 25 is a diagram of a side view of the structure of FIG. 1 during another stage in the process of fabricating the electronic device;

FIG. 26 is a diagram of a side view of the structure of FIG. 1 during another stage in the process of fabricating the electronic device;

FIG. 27 is a diagram of a side view of the structure of FIG. 1 during another stage in the process of fabricating the electronic device;

FIG. 28 is a diagram of a side view of the structure of FIG. 1 during another stage in the process of fabricating the electronic device;

FIG. 29 is a diagram of a side view of the structure of FIG. 1 during another stage in the process of fabricating the electronic device;

FIG. 30 is a diagram of a side view of the structure of FIG. 1 during another stage in the process of fabricating the electronic device;

FIG. 31 is a diagram of a side view of the structure of FIG. 1 during another stage in the process of fabricating the electronic device;

FIG. 32 is a diagram of a side view of the structure of FIG. 1 during another stage in the process of fabricating the electronic device;

FIG. 33 is a diagram of a side view of the structure of FIG. 1 during another stage in the process of fabricating the electronic device;

FIG. 34 is a flow chart of a particular illustrative embodiment of a method of fabricating the structure of FIG. 2;

FIG. 35 is a diagram of a side view of the structure of FIG. 2 during at least one stage in a process of fabricating an electronic device;

FIG. 36 is a diagram of a side view of the structure of FIG. 2 during another stage in the process of fabricating the electronic device;

FIG. 37 is a diagram of a side view of the structure of FIG. 2 during another stage in the process of fabricating the electronic device;

FIG. 38 is a diagram of a side view of the structure of FIG. 2 during another stage in the process of fabricating the electronic device;

FIG. 39 is a diagram of a side view of the structure of FIG. 2 during another stage in the process of fabricating the electronic device;

FIG. 40 is a diagram of a side view of the structure of FIG. 2 during another stage in the process of fabricating the electronic device;

FIG. 41 is a diagram of a side view of the structure of FIG. 2 during another stage in the process of fabricating the electronic device;

FIG. 42 is a diagram of a side view of the structure of FIG. 2 during another stage in the process of fabricating the electronic device;

FIG. 43 is a diagram of a side view of the structure of FIG. 2 during another stage in the process of fabricating the electronic device;

FIG. 44 is a diagram of a side view of the structure of FIG. 2 during another stage in the process of fabricating the electronic device;

FIG. 45 is a diagram of a side view of the structure of FIG. 2 during another stage in the process of fabricating the electronic device;

FIG. 46 is a diagram of a side view of the structure of FIG. 2 during another stage in the process of fabricating the electronic device;

FIG. 47 is a diagram of a side view of the structure of FIG. 2 during another stage in the process of fabricating the electronic device;

FIG. 48 is a diagram of a side view of the structure of FIG. 2 during another stage in the process of fabricating the electronic device;

FIG. 49 is a diagram of a side view of the structure of FIG. 2 during another stage in the process of fabricating the electronic device;

FIG. 50 is a diagram of a side view of the structure of FIG. 2 during another stage in the process of fabricating the electronic device;

FIG. 51 is a diagram of a side view of the structure of FIG. 2 during another stage in the process of fabricating the electronic device;

FIG. 52 is a diagram of a side view of the structure of FIG. 2 during another stage in the process of fabricating the electronic device;

FIG. 53 is a diagram of a side view of the structure of FIG. 2 during another stage in the process of fabricating the electronic device;

FIG. 54 is a diagram of a side view of the structure of FIG. 2 during another stage in the process of fabricating the electronic device;

FIG. 55 is a diagram of a side view of the structure of FIG. 2 during another stage in the process of fabricating the electronic device;

FIG. 56 is a diagram of a side view of the structure of FIG. 2 during another stage in the process of fabricating the electronic device;

FIG. 57 is a flow chart of a particular illustrative embodiment of a method of fabricating the structure of FIG. 1;

FIG. 58 is a flow chart of a particular illustrative embodiment of a method of fabricating the structure of FIG. 2; and

FIG. 59 is a block diagram of a computing device including the structure of FIG. 1, the structure of FIG. 2, or both.

### V. DETAILED DESCRIPTION

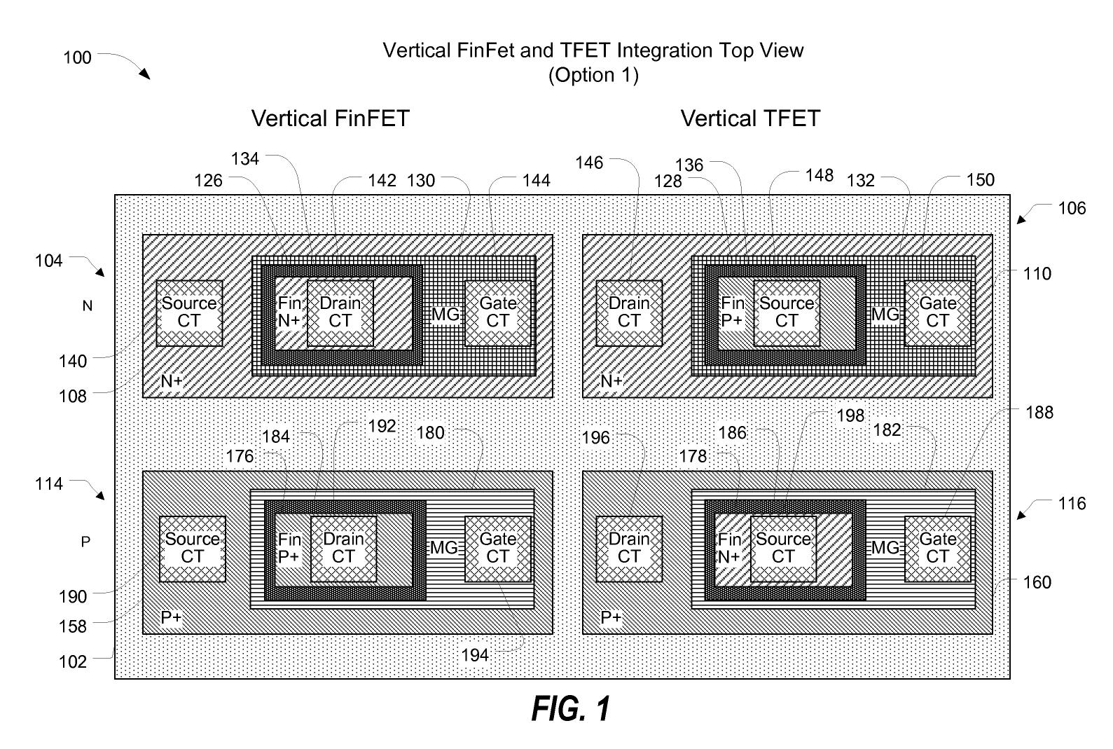

Referring to FIG. 1, an illustrative diagram of a top view of a structure as formed during at least one stage in a process of fabricating an electronic device is disclosed and generally designated 100. The structure 100 may correspond to a semiconductor device, an integrated circuit device, or another electronic device. The structure 100 includes a vertical CMOS transistor and a vertical TFET formed on a single substrate 102 (e.g., a III-V compound layer or a silicon (Si) layer). At least one of the vertical CMOS transistor or the vertical TFET may be configured to support a current flow direction between a source and drain that is perpendicular to the single substrate 102, as described herein. The CMOS transistor may include an n-type metal-oxide semiconductor transistor (nMOS) 104 and a p-type metal-oxide semiconductor transistor (pMOS) 114. The TFET may include an n-type TFET (nTFET) 106 and a p-type TFET (pTFET) 116. The nMOS 104 may correspond to an n-type fin-shaped field effect transistor (nFinFET). The pMOS 114 may correspond to a p-type fin-shaped field effect transistor (nFinFET).

The nMOS 104 may include an n-layer 108 (e.g., N+), an n-metal gate (N MG) 130, a spacer 134 (e.g., silicon mononitride (SiN)), and an n-layer 126 (e.g., N+). The nMOS 104 may include a source contact 140, a drain contact 142, and a gate contact 144. The nMOS 104 may be configured to support a current flow direction between a source coupled to the source contact 140 and a drain coupled to the drain contact 142. The current flow direction may be perpendicular to the single substrate 102. The pMOS 114 may include a p-layer 158 (e.g., P+), a p-metal gate (P MG) 180, a spacer 184 (e.g., SiN), and a p-layer 176 (e.g., P+). The pMOS 114 may include a source contact 190, a drain contact 192, and a gate contact 194. The pMOS 114 may be configured to support a current flow direction between a source coupled to the source contact 190 and a drain coupled to the drain contact 192. The current flow direction may be perpendicular to the single substrate 102.

The nTFET 106 may include an n-layer 110 (e.g., N+), an n-metal gate (N MG) 132, a spacer 136 (e.g., SiN), and a p-layer 128 (e.g., P+). The nTFET 106 may include a drain contact 146, a source contact 148, and a gate contact 150. The nTFET 106 may be configured to support a current flow direction between a source coupled to the source contact 148 and a drain coupled to the drain contact 146. The current flow direction may be perpendicular to the single substrate 102. The pTFET 116 may include a p-layer 160 (e.g., P+), a p-metal gate (P MG) 182, a spacer 186 (e.g., SiN), and an n-layer 178 (e.g., N+). The pTFET 116 may include a drain contact 196, a source contact 198, and a gate contact 188. The pTFET 116 may be configured to support a current flow direction between a source coupled to the source contact 198 and a drain coupled to the drain contact 196. The current flow direction may be perpendicular to the single substrate 102.

The structure 100 may thus include a CMOS transistor and a TFET on the single substrate 102. The CMOS transistor may perform higher priority (e.g., critical) operations and the TFET may perform lower priority (e.g., non-critical) operations. For example, higher priority operations may be assigned to the CMOS transistor and lower priority operations may be assigned to the TFET.

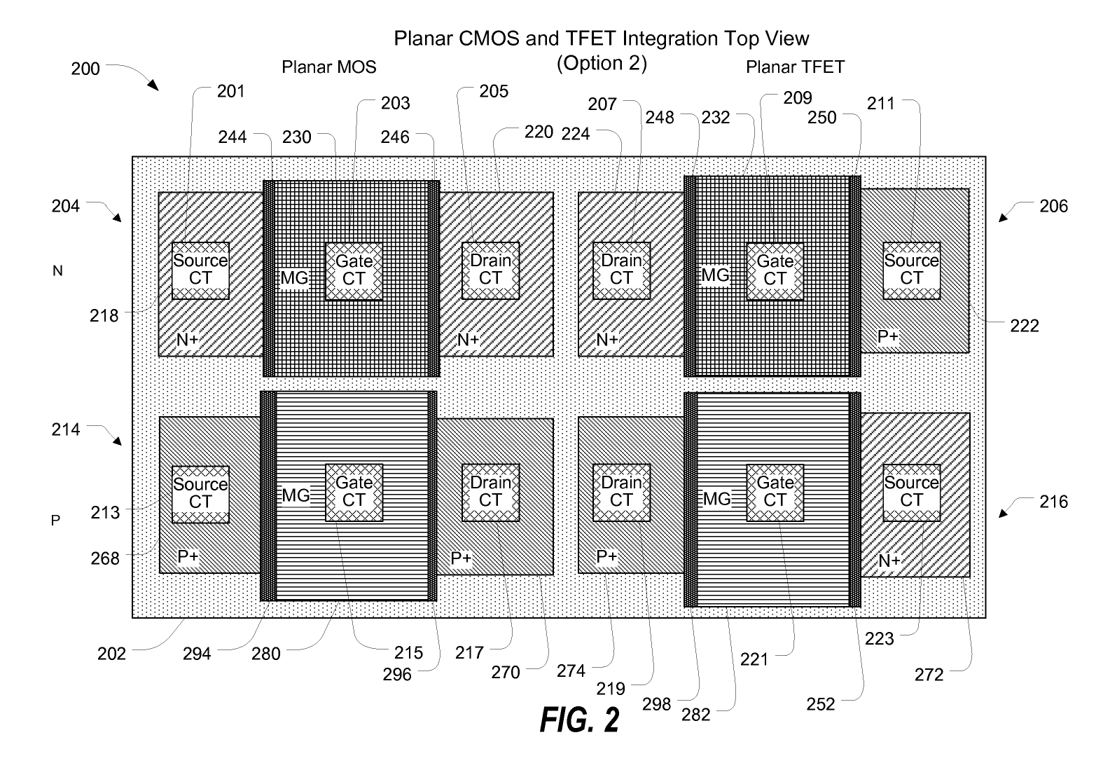

Referring to FIG. 2, an illustrative diagram of a top view of a structure as formed during at least one stage in a process of fabricating an electronic device is disclosed and generally designated 200. The structure 200 may correspond to a semiconductor device, an integrated circuit device, or another electronic device. The structure 200 differs from the structure 100 in that the structure 100 includes a vertical CMOS transistor and a vertical TFET and the structure 200 includes a planar CMOS transistor and a planar TFET. The planar CMOS transistor and the planar TFET may be formed on a single substrate 202. At least one of the planar CMOS transistor or the planar TFET may include a mobility enhancement strength layer, as described herein. The mobility enhancement strength layer may provide compression strength, tensile strength, or both. The planar CMOS transistor may include an n-type metal-oxide semiconductor transistor (nMOS) 204 and a p-type metal-oxide semiconductor transistor (pMOS) 214. The TFET may include an n-type TFET (nTFET) 206 and a p-type TFET (pTFET) 216.

The nMOS 204 may include n-regions 218 and 220 (e.g., N+), an n-metal gate (N MG) 230, and spacers 244 and 246 (e.g., silicon mononitride (SiN)). The nMOS 204 may include a source contact 201, a gate contact 203, and a drain contact 205. The source contact 201 may be coupled to a first n-type source. The drain contact 205 may be coupled to a first n-type drain. The pMOS 214 may include p-regions 268 and 270 (e.g., P+), a p-metal gate (P MG) 280, and spacers 294 and 296 (e.g., SiN). The pMOS 214 may include a source contact 213, a gate contact 215, and a drain contact 217. The source contact 213 may be coupled to a first p-type source. The drain contact 217 may be coupled to a first p-type drain.

The nTFET 206 may include an n-region 224 (e.g., N+), an n-metal gate (N MG) 232, spacers 248 and 250 (e.g., SiN), and a p-region 222 (e.g., P+). The nTFET 206 may include a drain contact 207, a gate contact 209, and a source contact 211. The source contact 211 may be coupled to a second p-type source. The drain contact 207 may be coupled to a second n-type drain. The pTFET 216 may include a p-region 274 (e.g., P+), a p-metal gate (P MG) 282, spacers 252 and 298 (e.g., SiN), and an n-region 272 (e.g., N+). The pTFET 216 may include a drain contact 219, a gate contact 221, and a source contact 223. The drain contact 219 may be coupled to a second p-type drain. The source contact 223 may be coupled to a second n-type source.

The mobility enhancement strength layer may include at least one of the first n-type source, the first n-type drain, the first p-type source, the first p-type drain, the second n-type source, the second p-type drain, the second p-type source, or the second n-type drain. For example, at least one of the first n-type source, the first n-type drain, the second n-type source, or the second n-type drain may include silicon-carbide. As another example, at least one of the first p-type source, the first p-type drain, the second p-type source, or the second p-type drain may include silicon-germanium.

The structure 200 may thus include a CMOS transistor and a TFET on the single substrate 202. At least one of the CMOS transistor or the TFET may include a mobility enhancement strength layer. The mobility enhancement strength layer may provide compression strength, tensile strength, or both. The CMOS transistor may perform higher priority (e.g., critical) operations and the TFET may perform lower priority (e.g., non-critical) operations. For example, higher priority operations may be assigned to the CMOS transistor and lower priority operations may be assigned to the TFET.

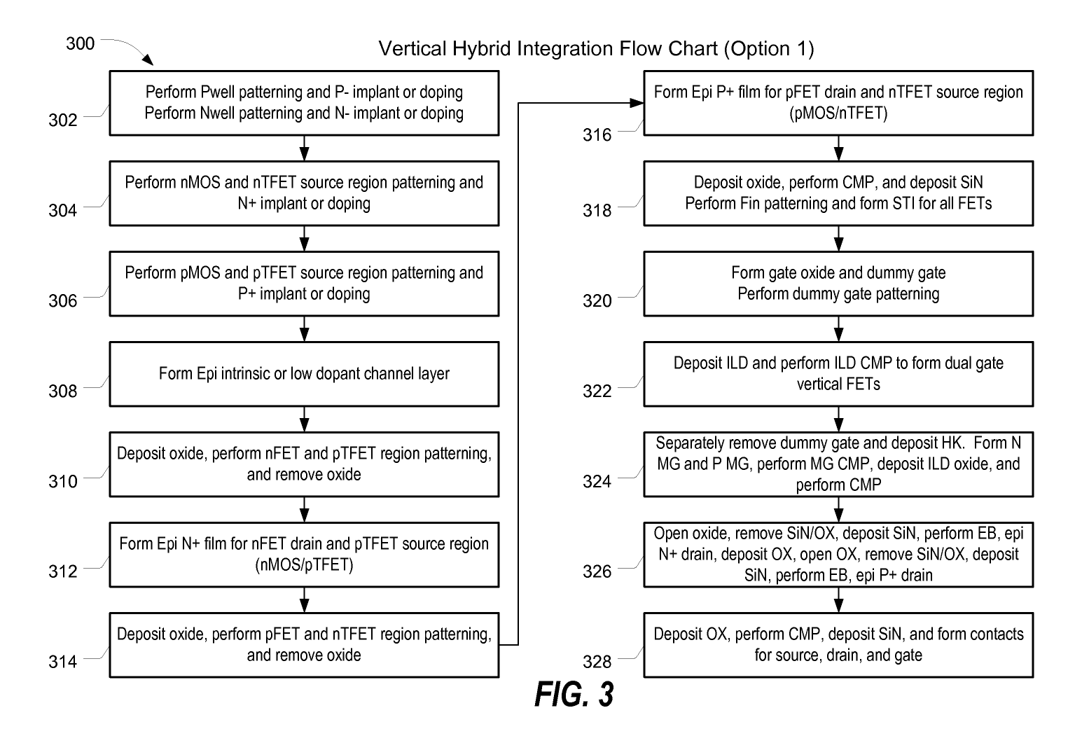

FIG. 3 is a flow chart illustrating a particular embodiment of a method 300 of fabricating a structure (e.g., the structure 100 of FIG. 1). The structure 100 may include a CMOS transistor and a TFET on a single substrate, as described herein. At least one of the CMOS transistor or the TFET may be configured to support a current flow direction between a source and a drain that is perpendicular to the single substrate.

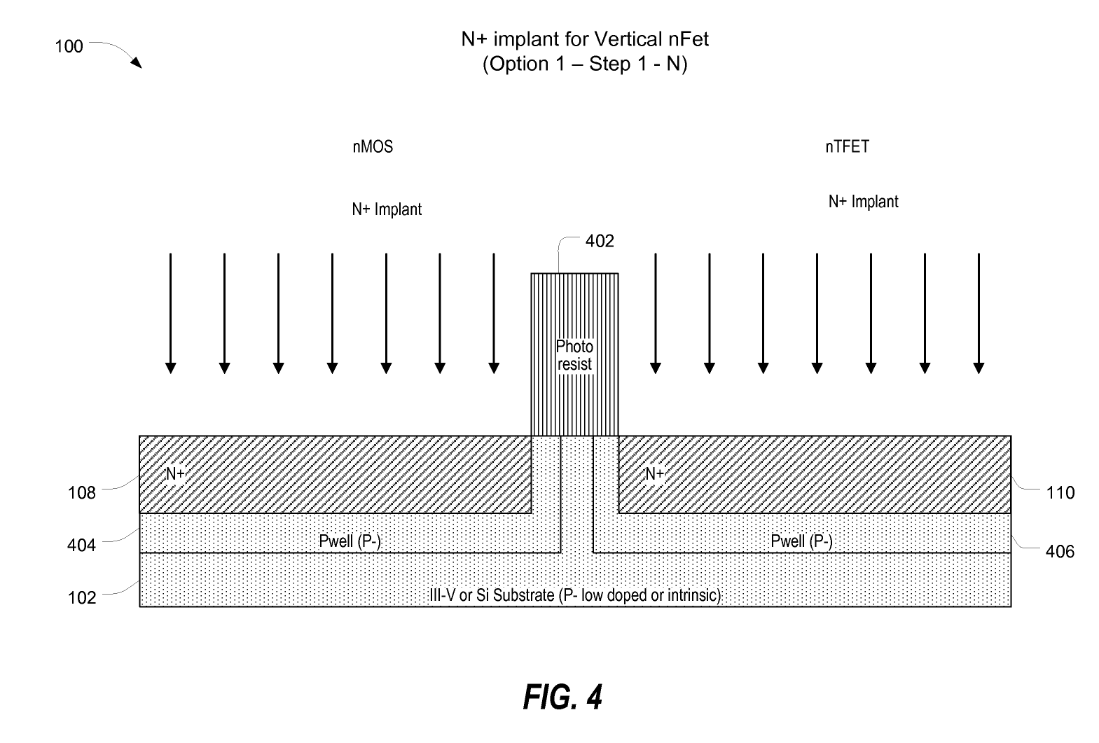

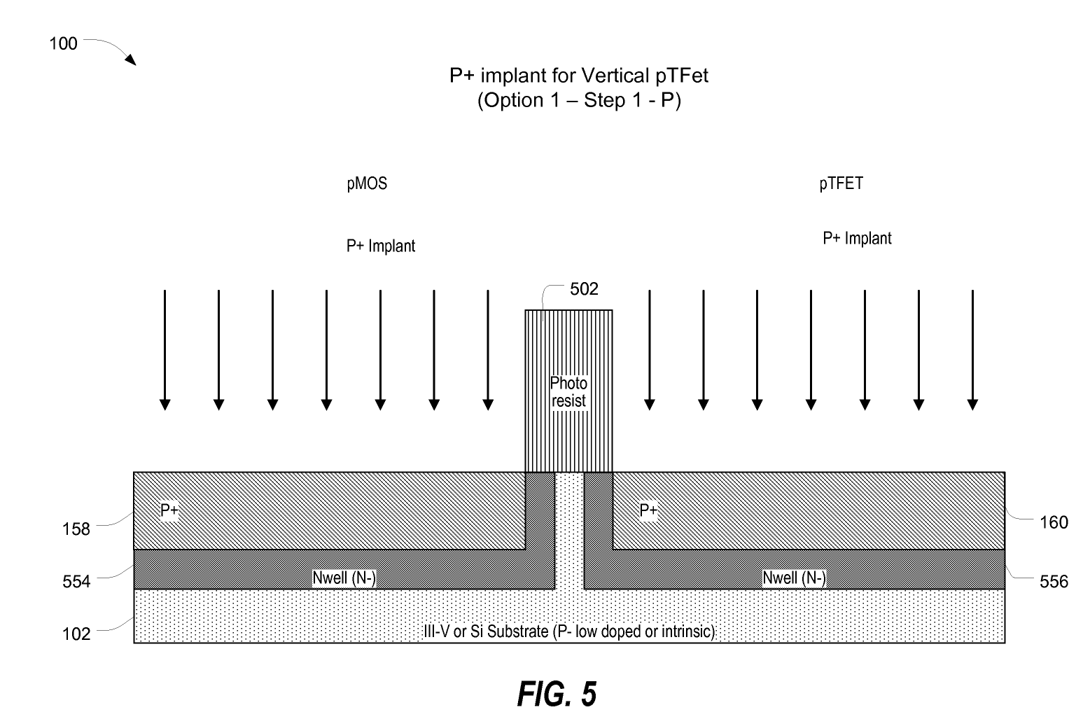

The method 300 includes performing Pwell patterning and P− implant or P− doping and performing Nwell patterning and N− implant or N− doping, at 302. For example, portions of the substrate 102 of FIG. 1 may be patterned and doped to form Pwells and Nwells, as described with reference to FIGS. 4-5. For example, first portions of the substrate 102 may be P− doped to form the Pwells and second portions of the substrate 102 may be N− doped to form the Nwells. In a particular embodiment, the Pwells and the Nwells may be formed by implantation.

The method 300 also includes performing nMOS and nTFET source region patterning and N+ implant or doping, at 304. For example, the n-layers 108 and 110 of the nMOS 104 and the nTFET 106 of FIG. 1 may be formed by patterning the Pwells and performing N+ implantation or doping, as described with reference to FIG. 4. Performing nMOS and nTFET source region patterning and N+ implant or doping may enable a first n-type source of the nMOS 104 and a second n-type drain of the nTFET 106 to be fabricated, as described herein, such that the first n-type source and the second n-type drain are co-planar.

The method 300 further includes performing pMOS and pTFET source region patterning and P+ implant or P+ doping, at 306. For example, the p-layers 158 and 160 of the pMOS 114 and the pTFET 116 of FIG. 1 may be formed by patterning the Nwells and performing P+ implantation or doping, as described with reference to FIG. 5. Performing pMOS and pTFET source region patterning and P+ implant or doping may enable a first p-type source of the pMOS 114 and a second p-type drain of the pTFET 116 to be fabricated, as described herein, such that the first p-type source and the second p-type drain are co-planar.

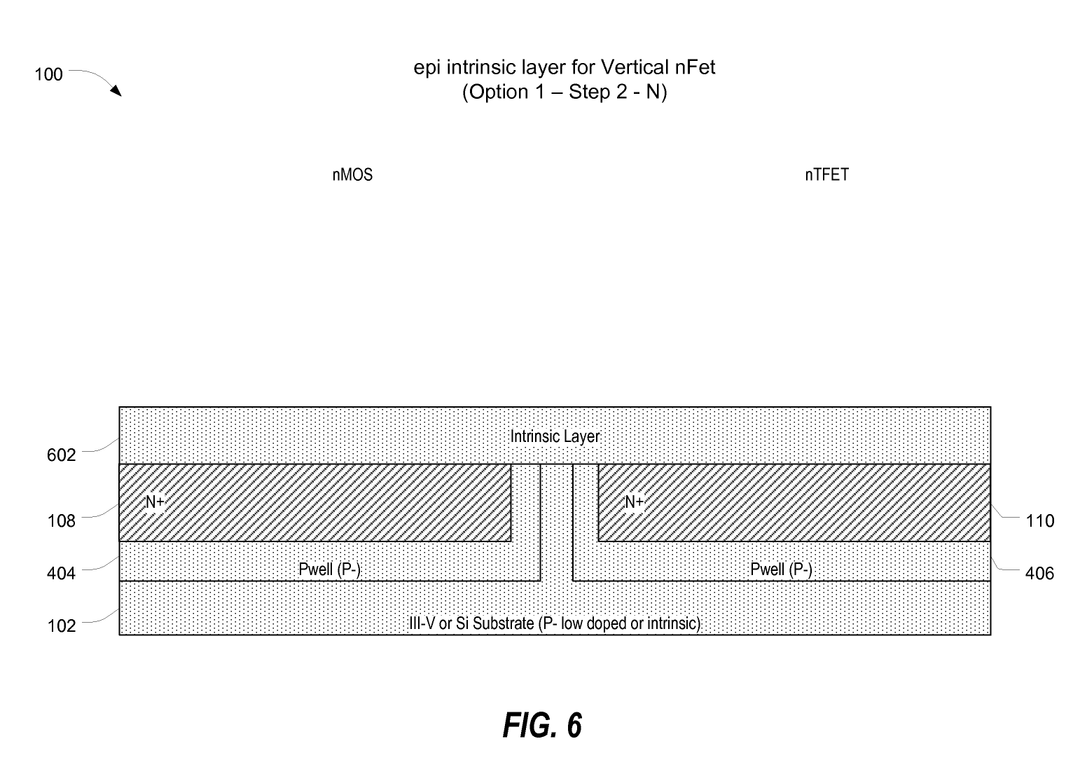

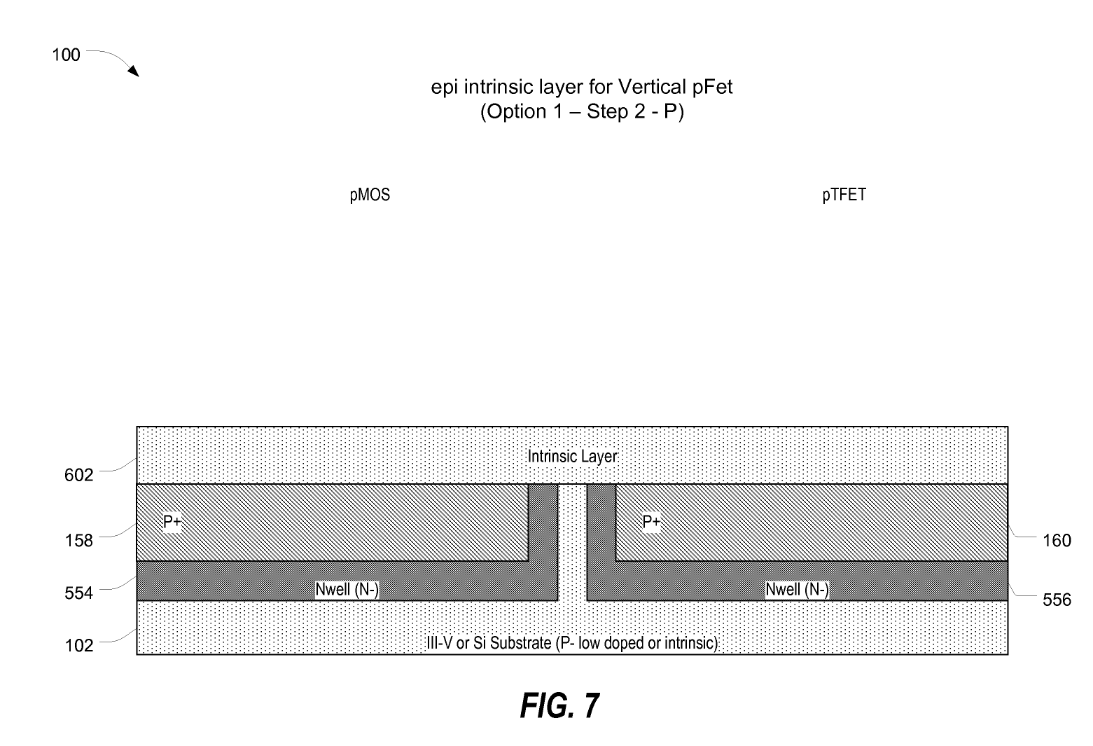

The method 300 also includes forming an epitaxial intrinsic or a low dopant channel layer, at 308. For example, an intrinsic layer (or a low dopant channel layer) may be formed, as described with reference to FIGS. 6-7. To illustrate, the intrinsic (e.g., undoped silicon) layer may be epitaxially grown.

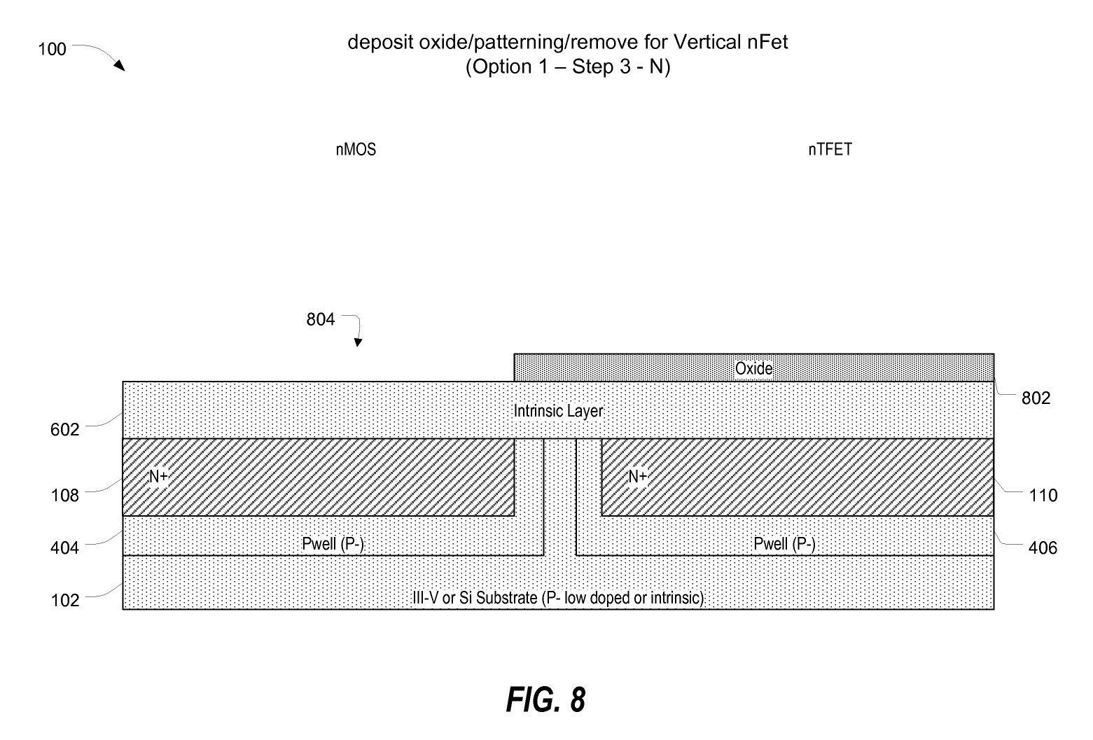

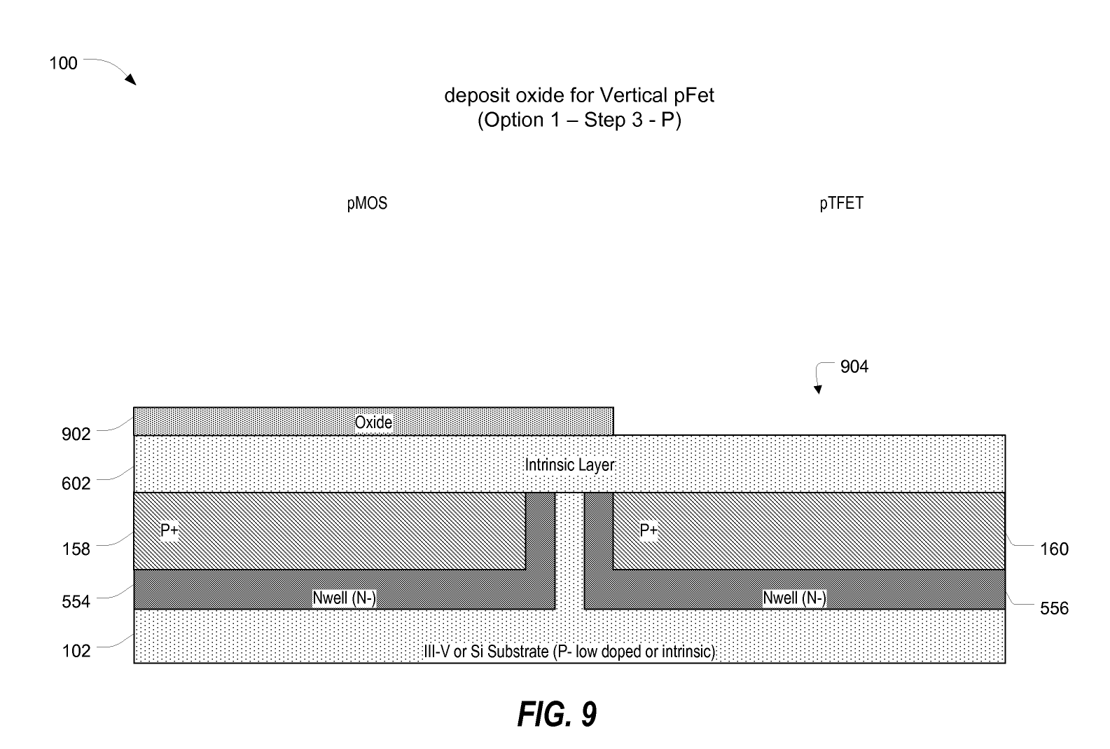

The method 300 further includes depositing oxide, performing nFET and pTFET region patterning, and removing oxide, at 310. For example, an oxide layer may be deposited, the oxide layer may be patterned, and portions of the oxide layer may be removed, as described with reference to FIGS. 8-9.

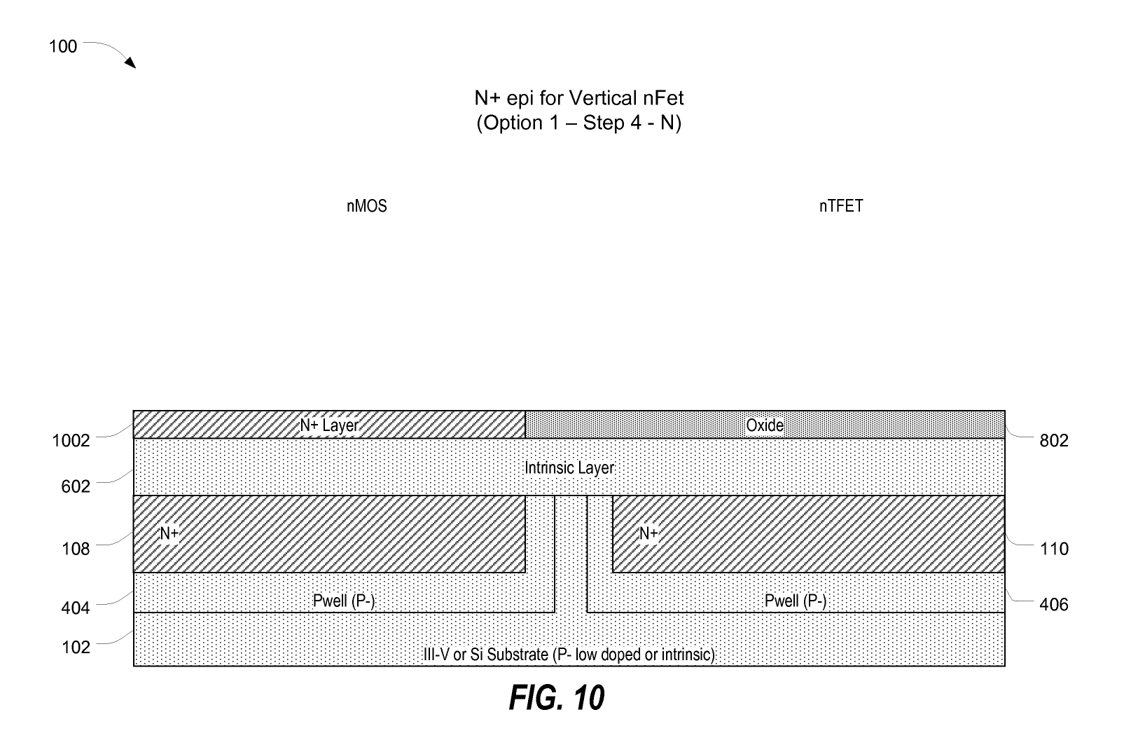

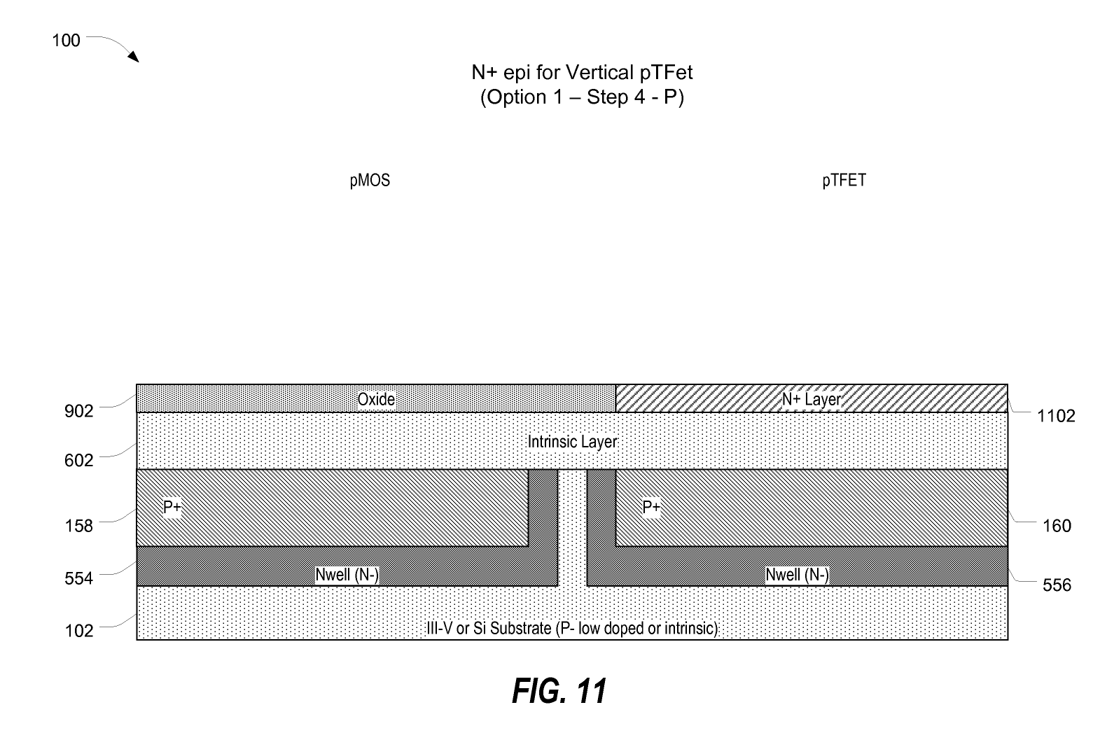

The method 300 also includes forming an Epi N+ film for an nFET drain and a pTFET source region (nMOS/pTFET), at 312. For example, an n-layer of the nMOS 104 of FIG. 1 and an n-layer of the pTFET 116 may be epitaxially grown, as described with reference to FIGS. 10-11. Forming an Epi N+ film for an nFET drain and a pTFET source region may enable a first n-type drain of the nMOS 104 and a second n-type source of the pTFET 116 to be fabricated, as described herein, such that the first n-type drain and the second n-type source are co-planar. The first n-type drain of the nMOS 104 may be aligned with the first n-type source of the nMOS 104 such that the nMOS 104 is configured to support a current flow direction between the first n-type drain and the first n-type source that is perpendicular to the single substrate 102. The second n-type source of the pTFET 116 may be aligned with the second p-type drain of the pTFET 116 such that the pTFET 116 is configured to support a current flow direction between the second n-type source and the second p-type drain that is perpendicular to the single substrate 102.

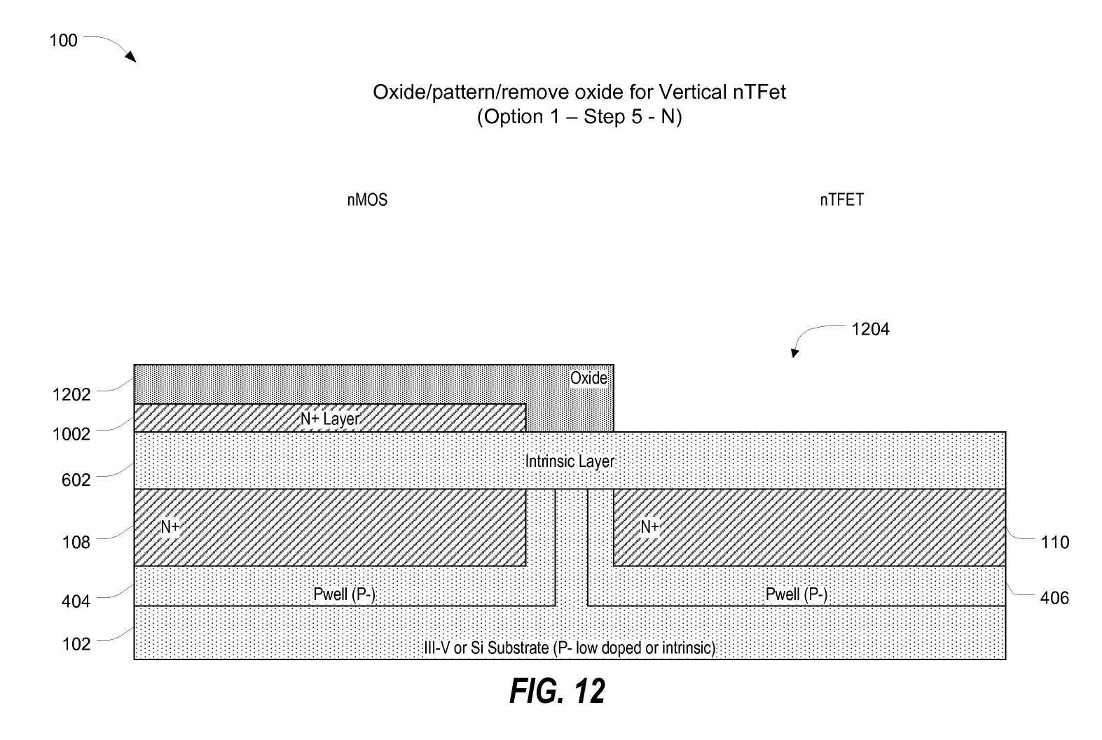

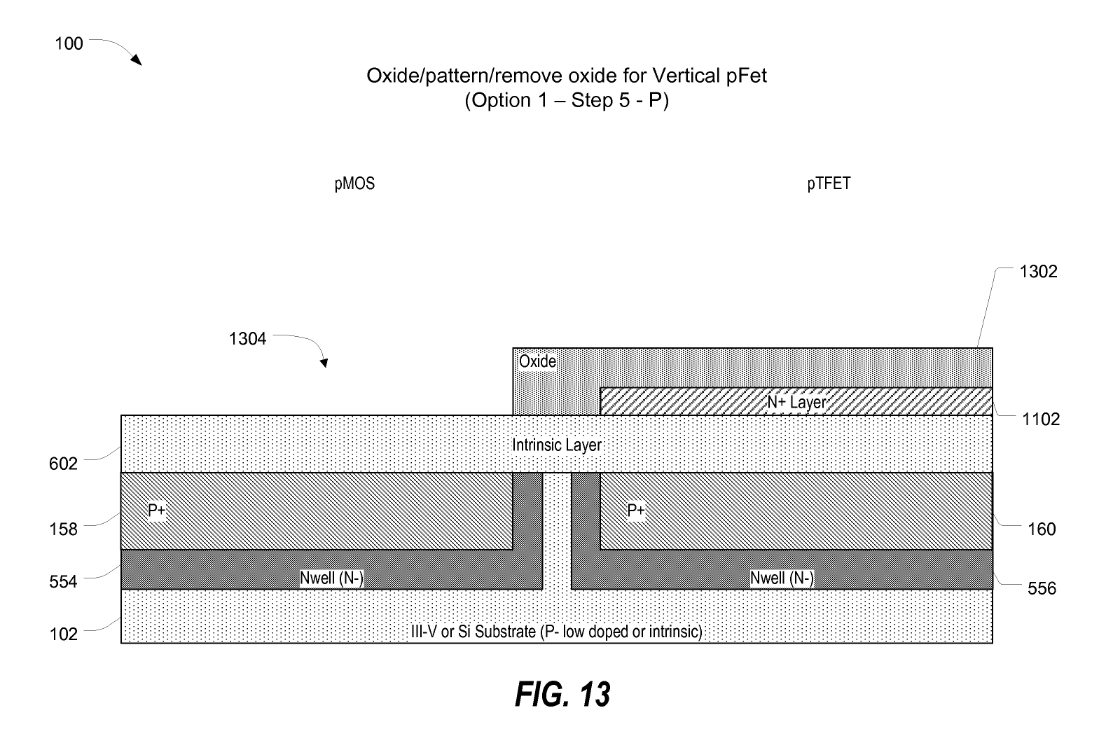

The method 300 further includes depositing oxide, performing pFET and nTFET region patterning, and removing oxide, at 314. For example, an oxide layer may be deposited, the oxide layer may be patterned, and portions of the oxide layer may be removed, as described with reference to FIGS. 12-13.

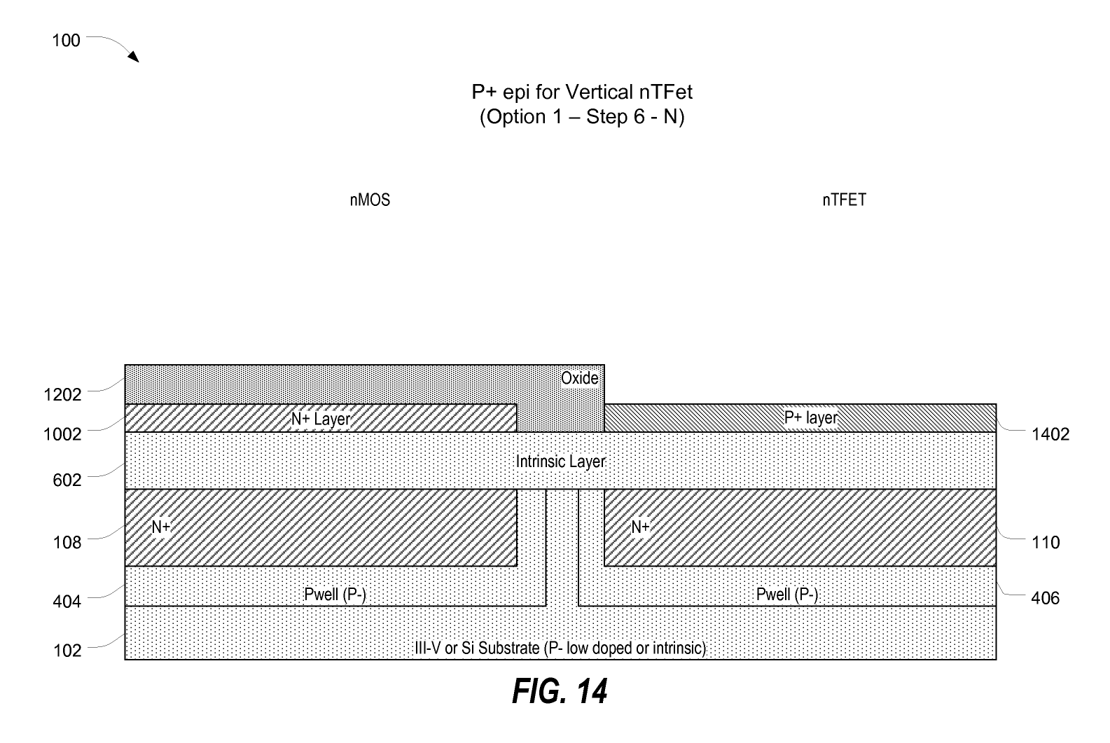

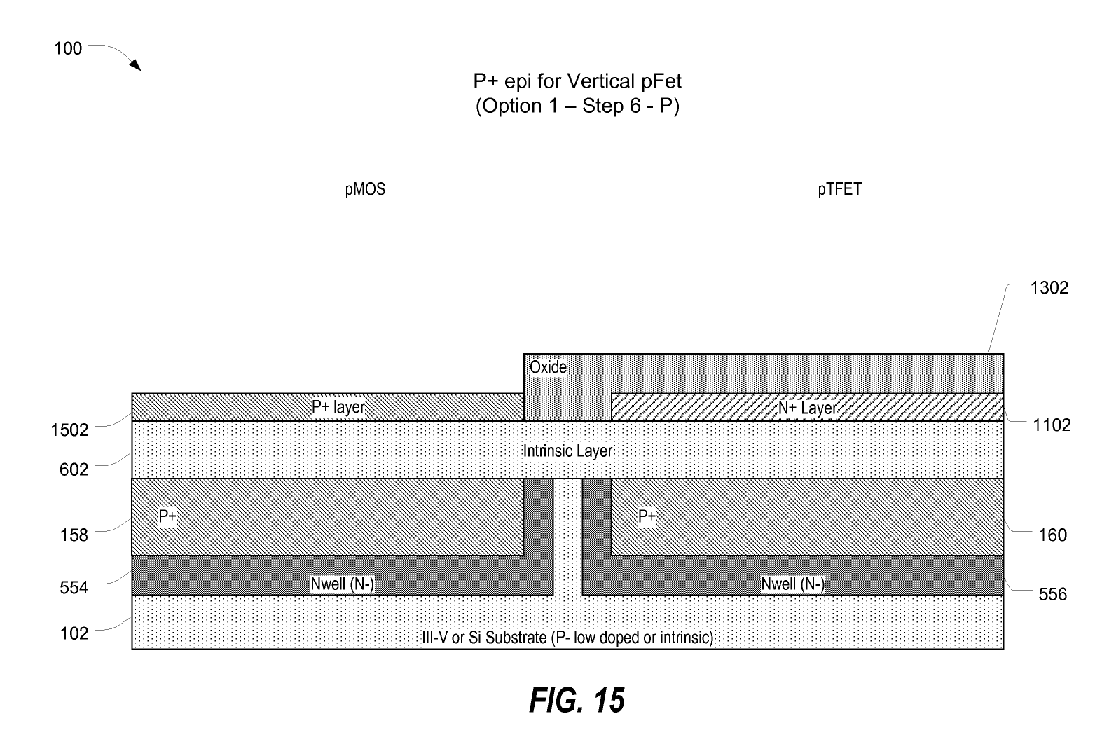

The method 300 also includes forming an Epi P+ film for a pFET drain and an nTFET source region (pMOS/nTFET), at 316. For example, a p-layer of the pMOS 114 of FIG. 1 and a p-layer of the nTFET 106 may be epitaxially grown, as described with reference to FIGS. 14-15. Forming an Epi P+ film for a pFET drain and an nTFET source region may enable a first p-type drain of the pMOS 114 and a second p-type source of the nTFET 106 to be fabricated, as described herein, such that the first p-type drain and the second p-type source are co-planar. The first p-type drain of the pMOS 114 may be aligned with the first p-type drain of the pMOS 114 such that the pMOS 114 is configured to support a current flow direction between the first p-type drain and the first p-type source that is perpendicular to the single substrate 102. The second p-type source of the nTFET 106 may be aligned with the second n-type drain of the nTFET 106 such that the nTFET 106 is configured to support a current flow direction between the second p-type source and the second n-type drain that is perpendicular to the single substrate 102.

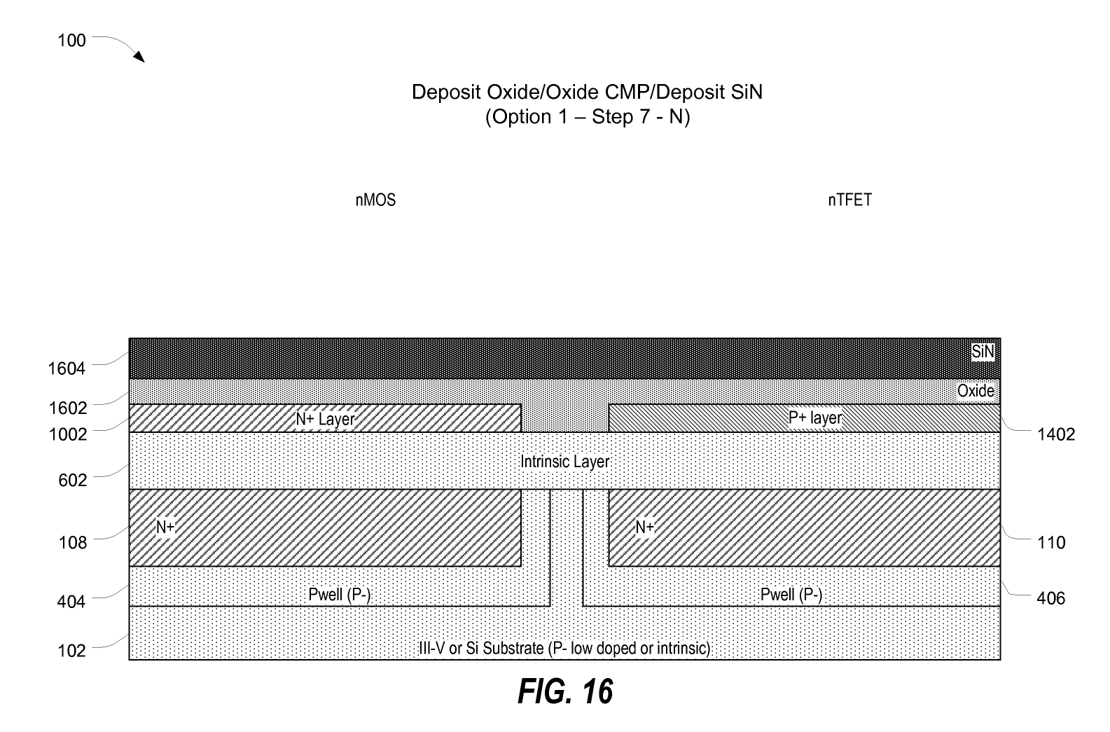

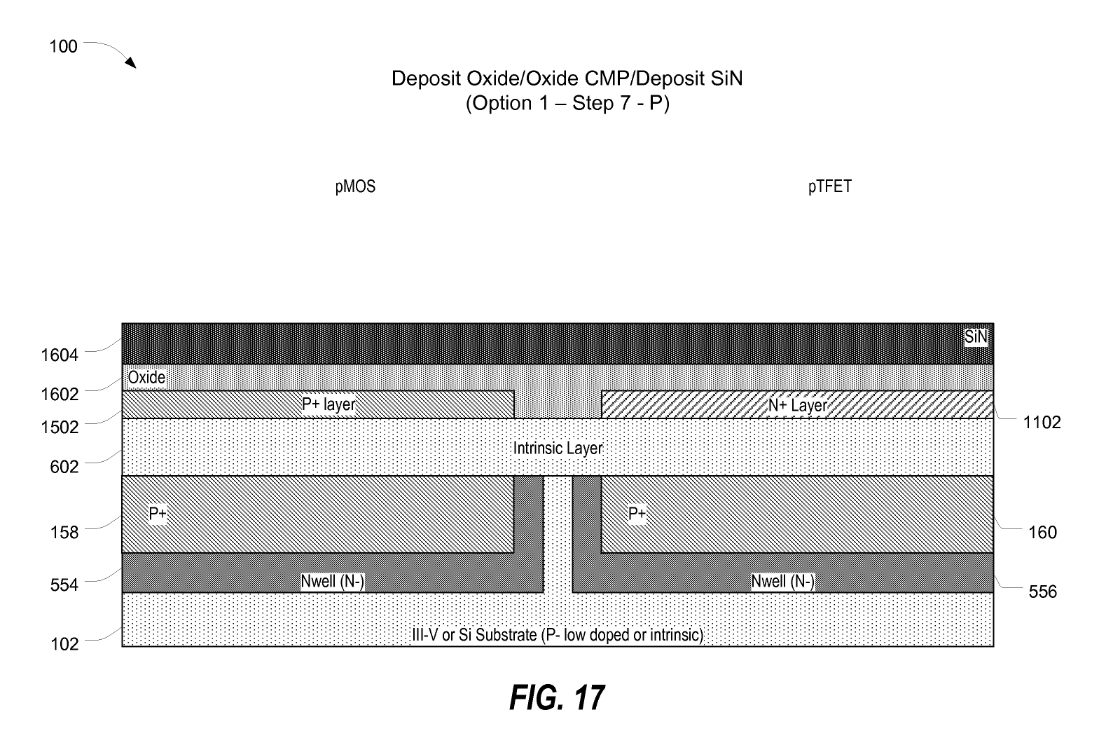

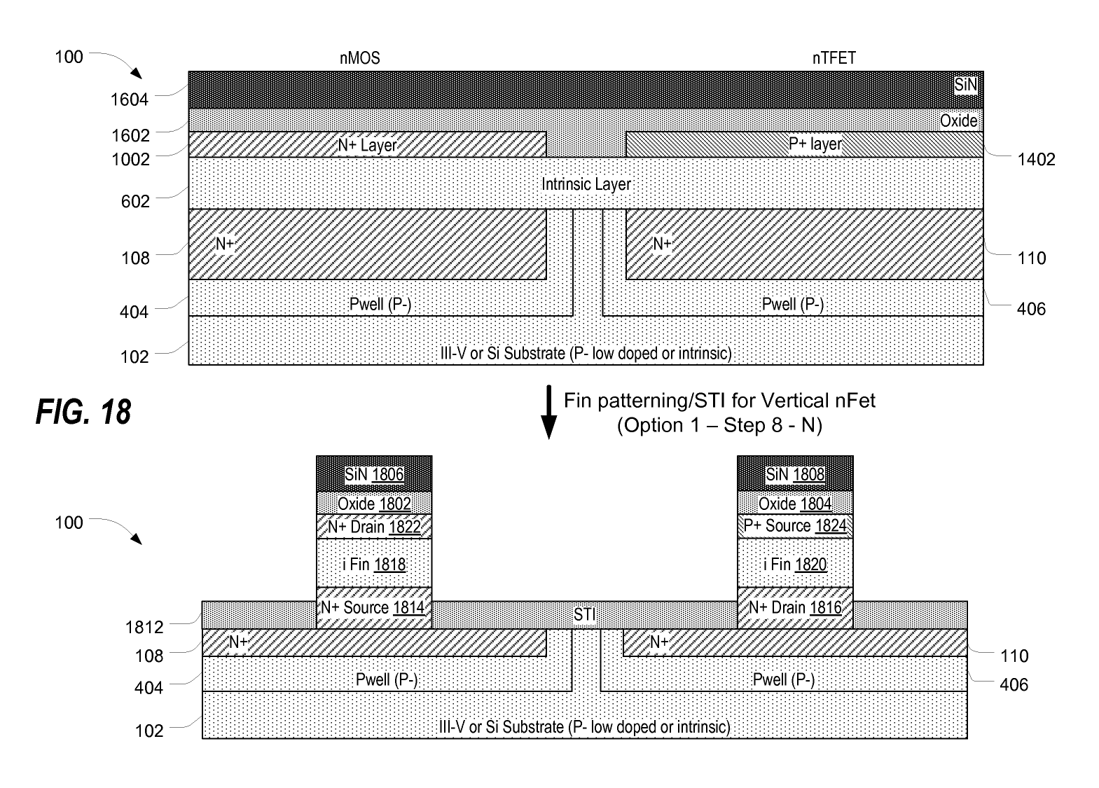

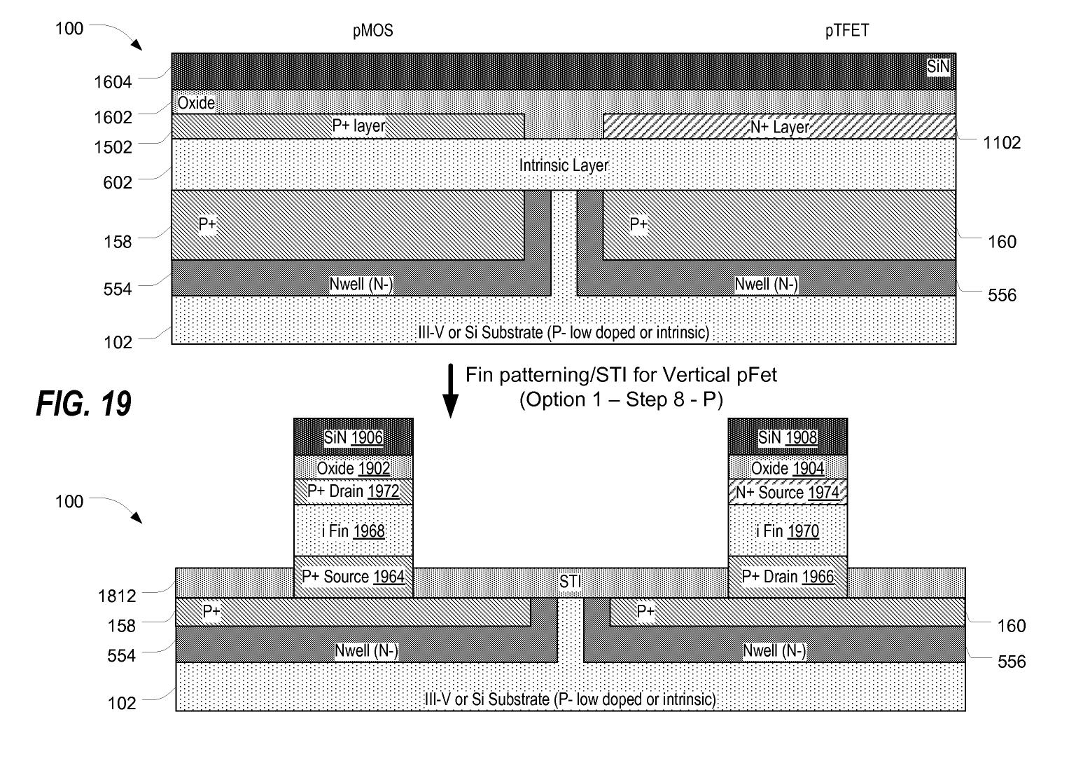

The method 300 further includes depositing oxide, performing chemical-mechanical planarization (CMP), depositing SiN, performing Fin patterning, and forming an STI layer, at 318. For example, an oxide layer may be deposited, CMP may be performed, and an SiN layer may be deposited, as described with reference to FIGS. 16-17. Fin patterning may be performed and a shallow trench isolation (STI) layer may be deposited, as described with reference to FIGS. 18-19. For example, the fin patterning may form the first n-type source, the first n-type drain, the first p-type source, the first p-type drain, the second n-type source, the second n-type drain, the second p-type source, and the second p-type drain.

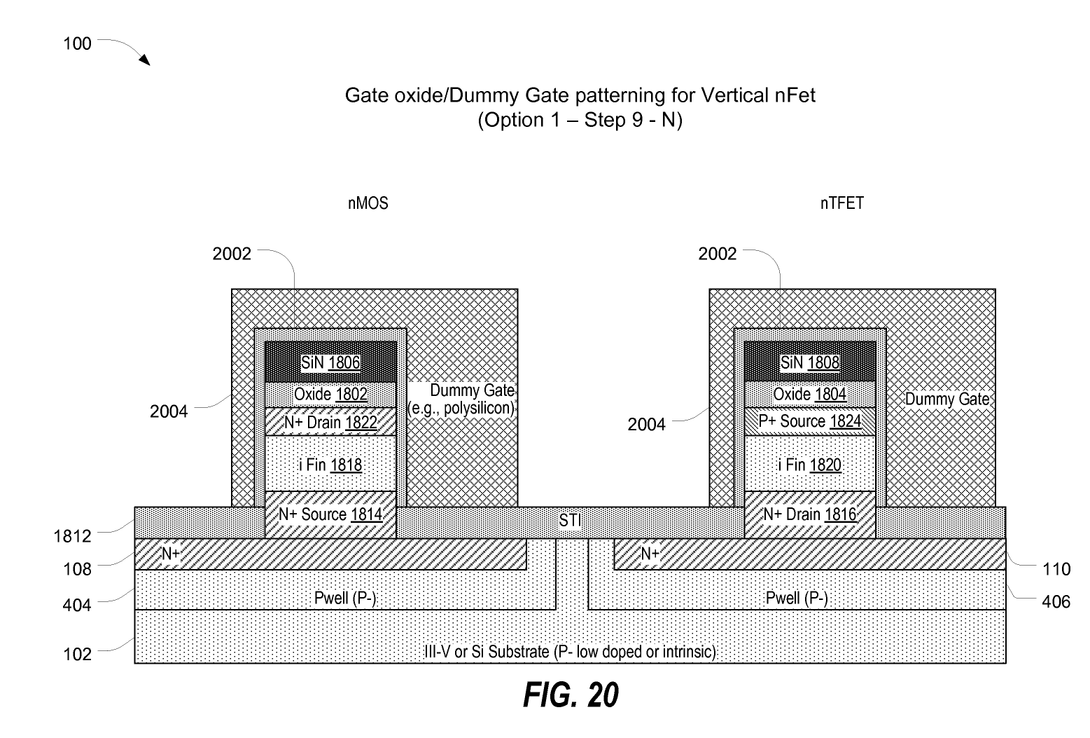

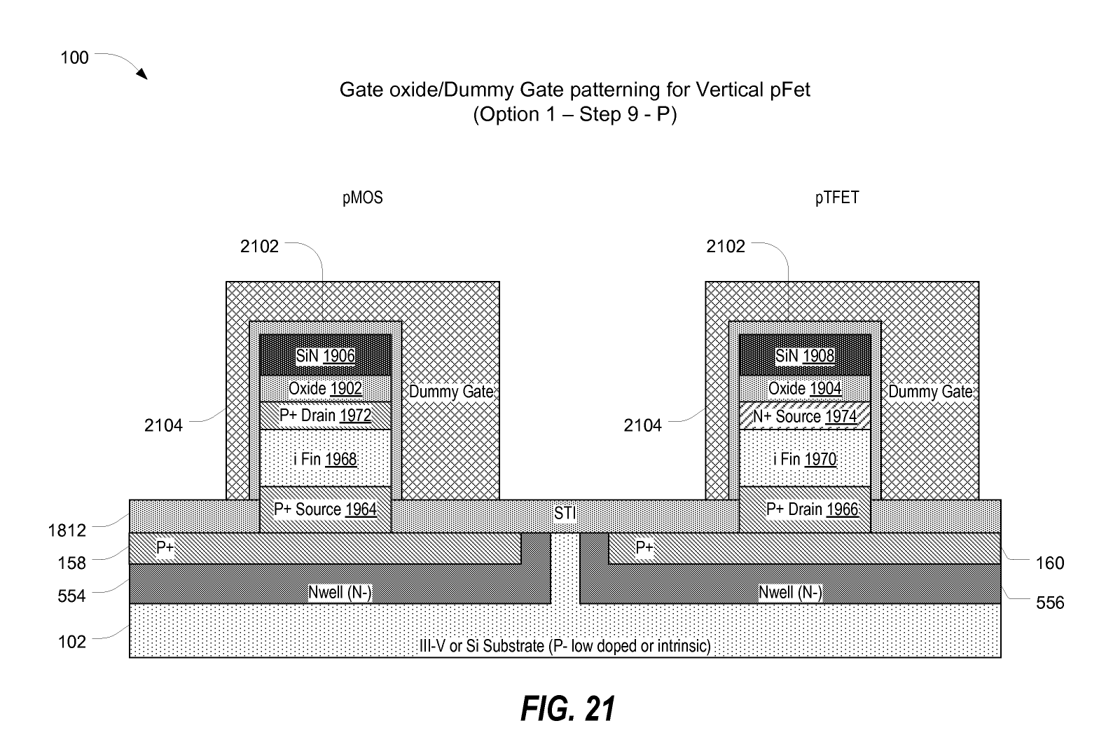

The method 300 also includes forming a gate oxide and a dummy gate and performing dummy gate patterning, at 320. For example, an oxide layer may be deposited, dummy gates may be formed, and dummy gate patterning may be performed, as described with reference to FIGS. 20-21.

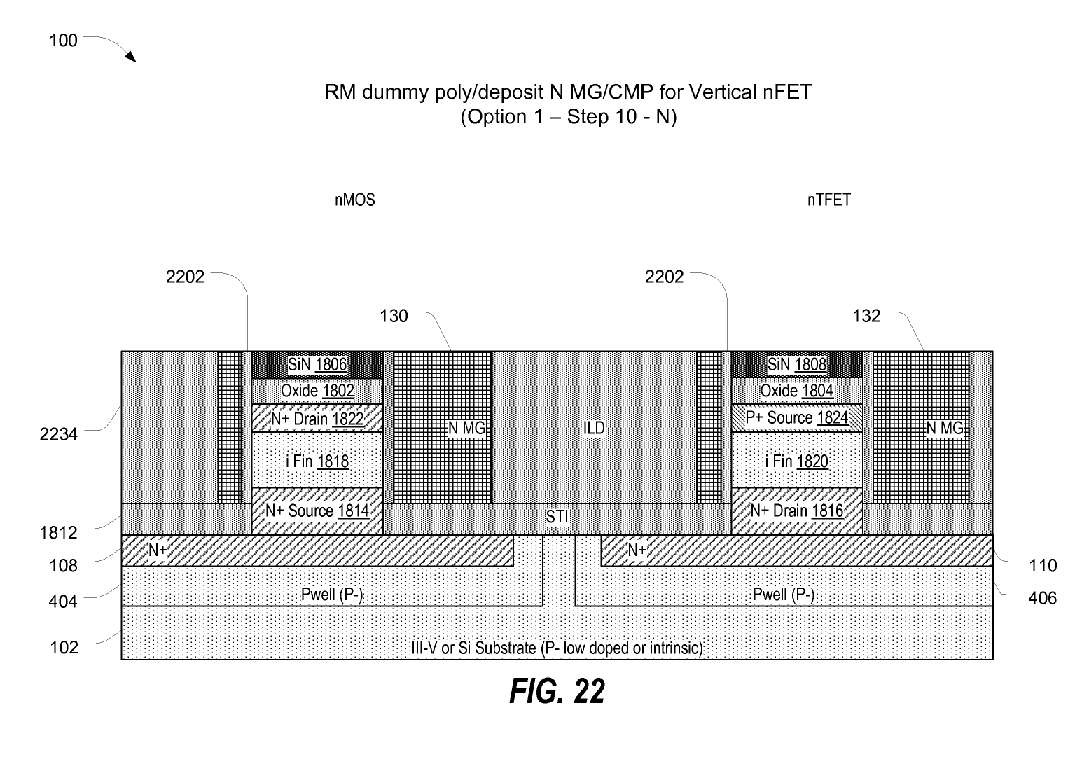

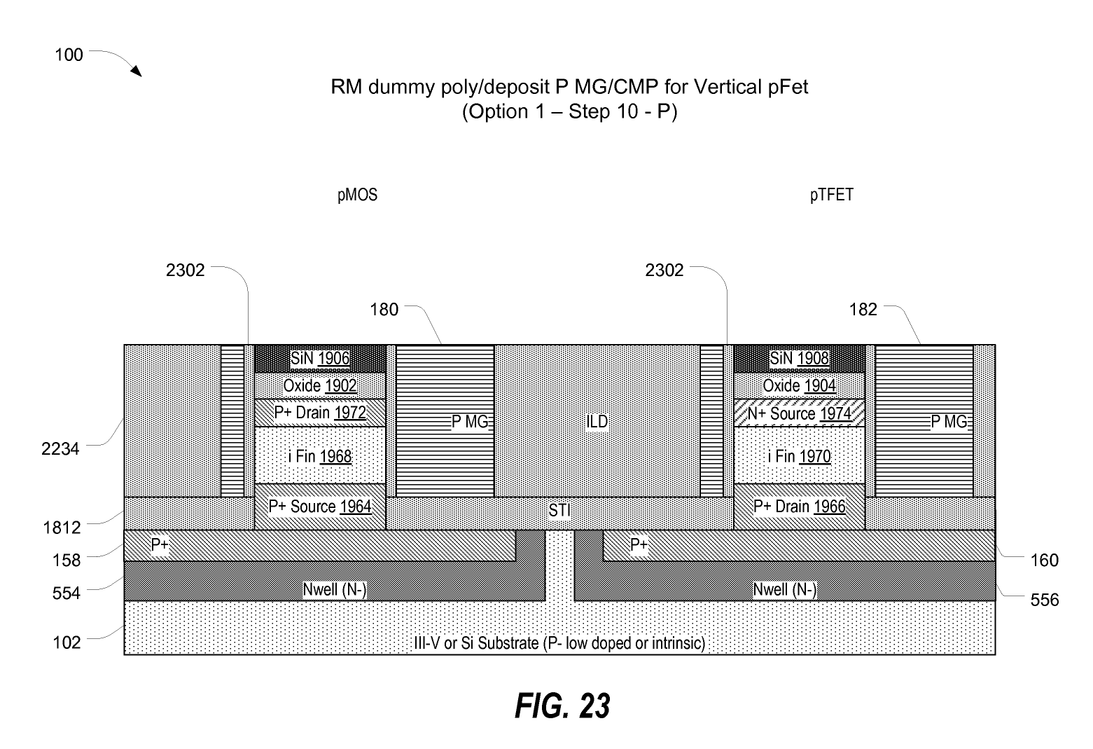

The method 300 further includes depositing an inter-layer dielectric (ILD) and ILD CMP to form dual gate vertical FETs, at 322. For example, an ILD layer may be deposited and CMP may be performed, as described with reference to FIGS. 22-23.

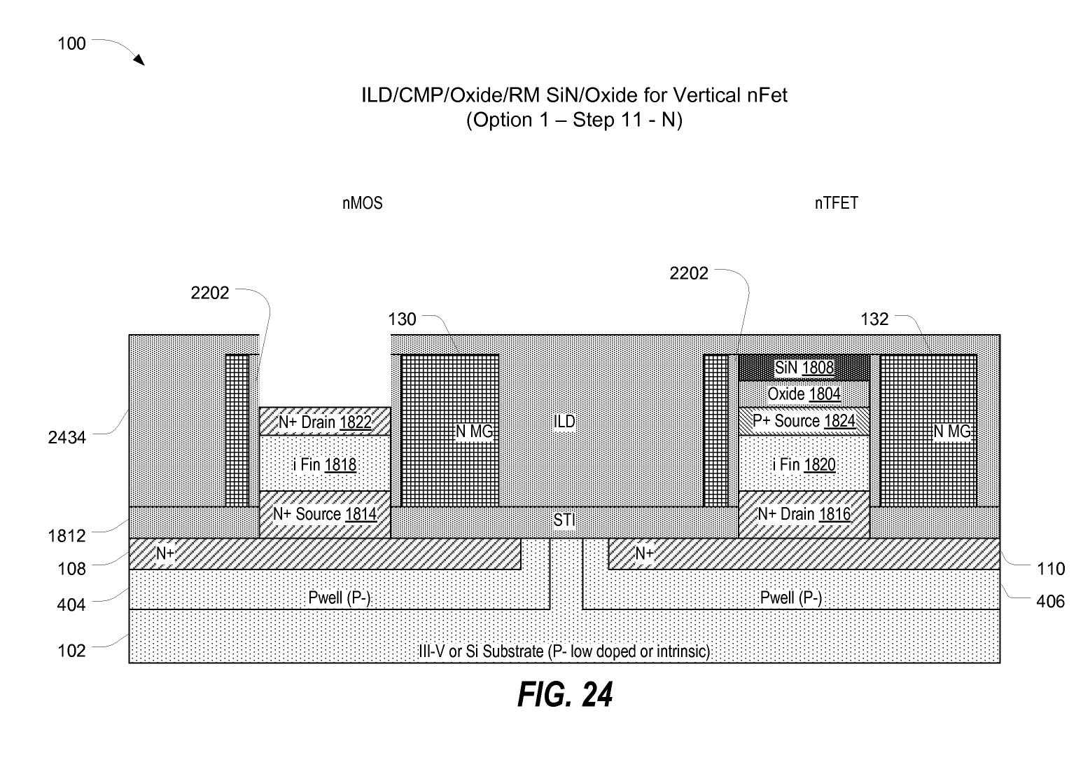

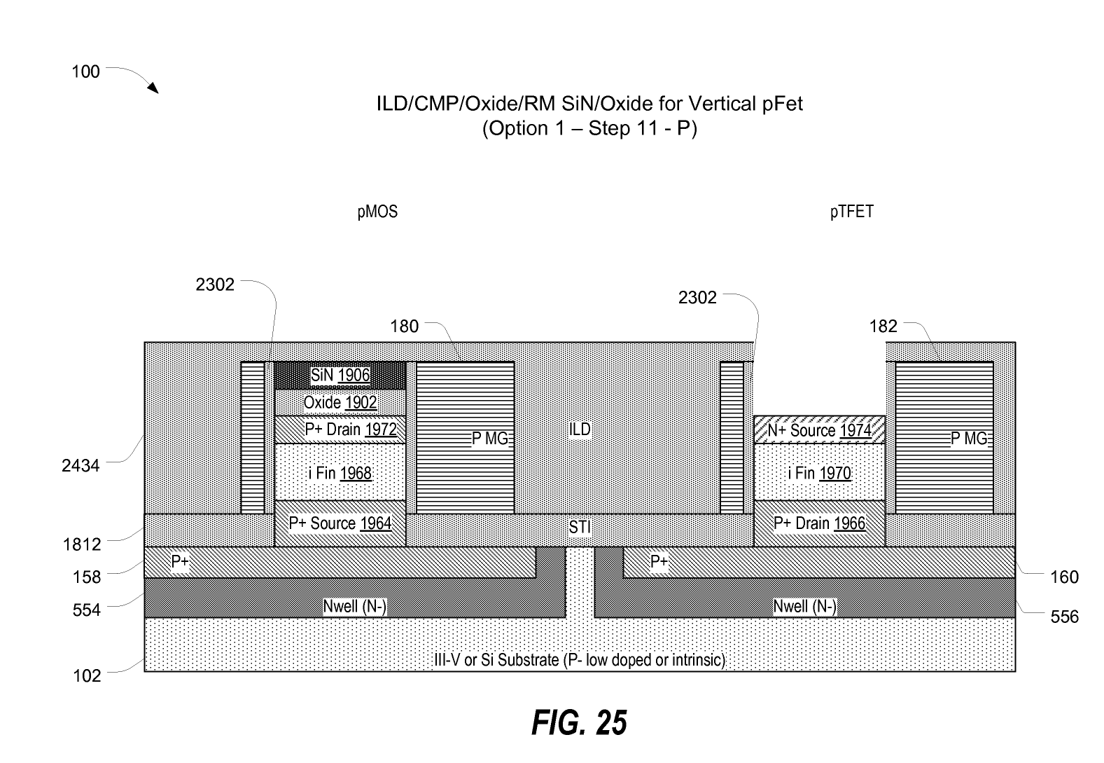

The method 300 also includes removing a dummy gate, depositing a high dielectric constant (HK) layer, forming an n-metal gate (N MG), forming a p-metal gate (P MG), performing metal gate (MG) CMP, depositing an ILD (e.g., oxide) layer, and performing CMP, at 324. For example, dummy gates may be removed, an HK layer may be deposited, an n-metal may be deposited to form the n-metal gates (N MGs) 130 and 132, a p-metal may be deposited to form the p-metal gates (P MGs) 180 and 182, and CMP may be performed, as described with reference to FIGS. 22-23. An ILD layer may be deposited and CMP may be performed, as described with reference to FIGS. 24-25.

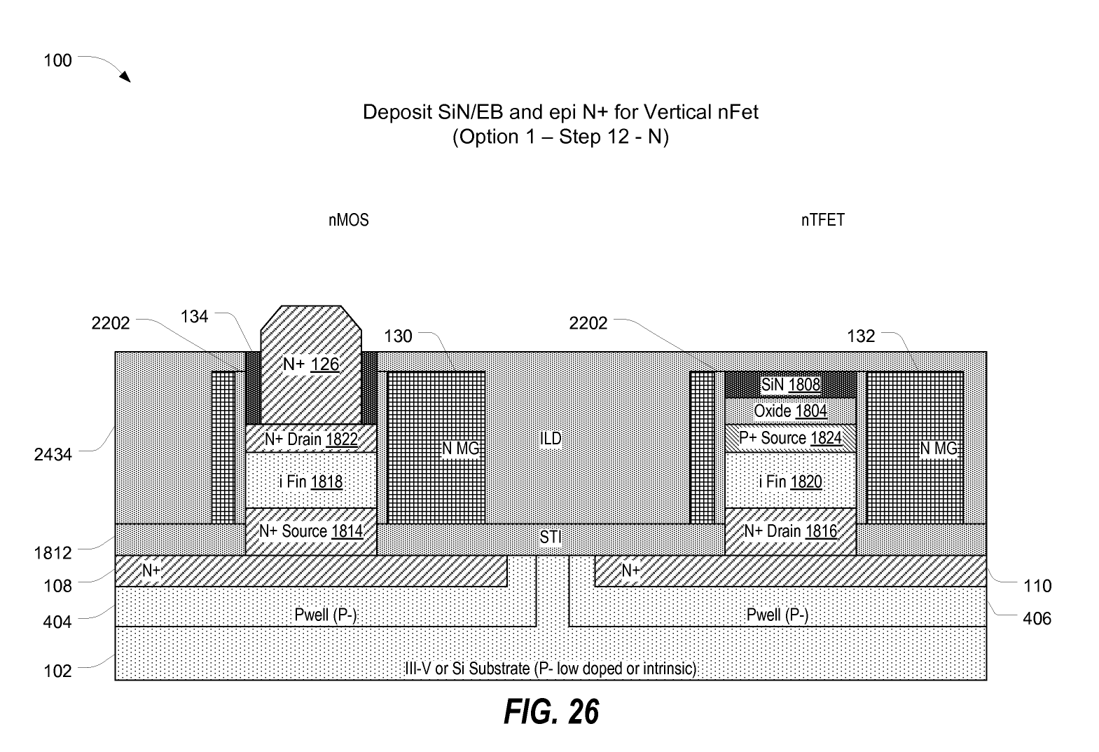

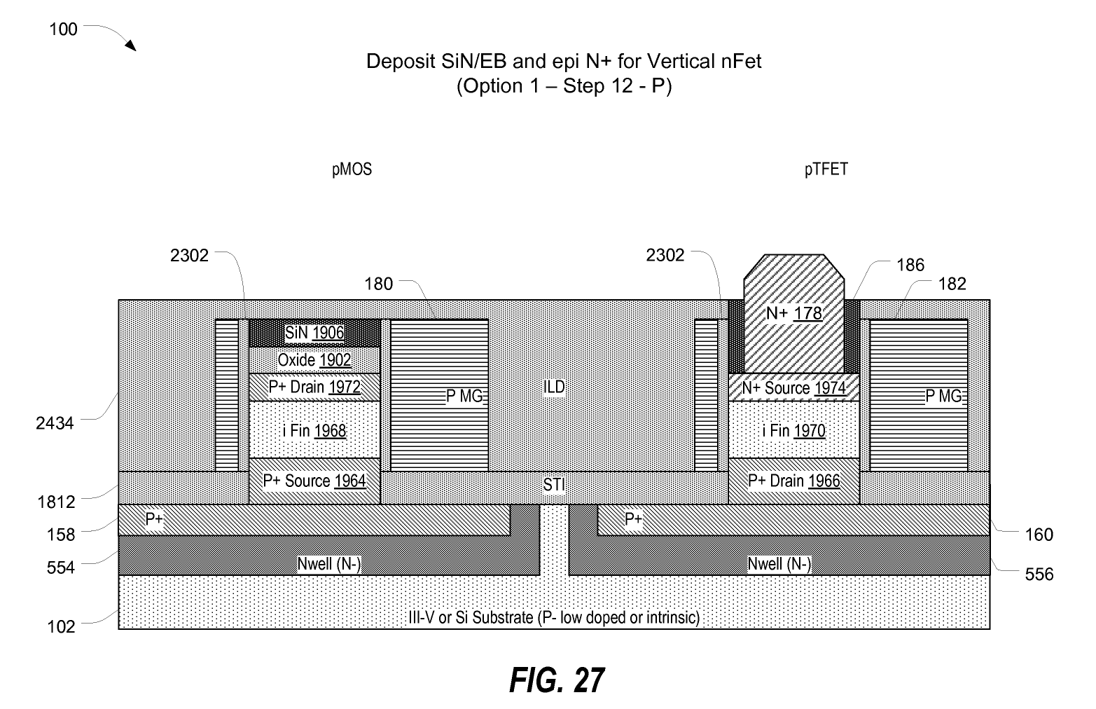

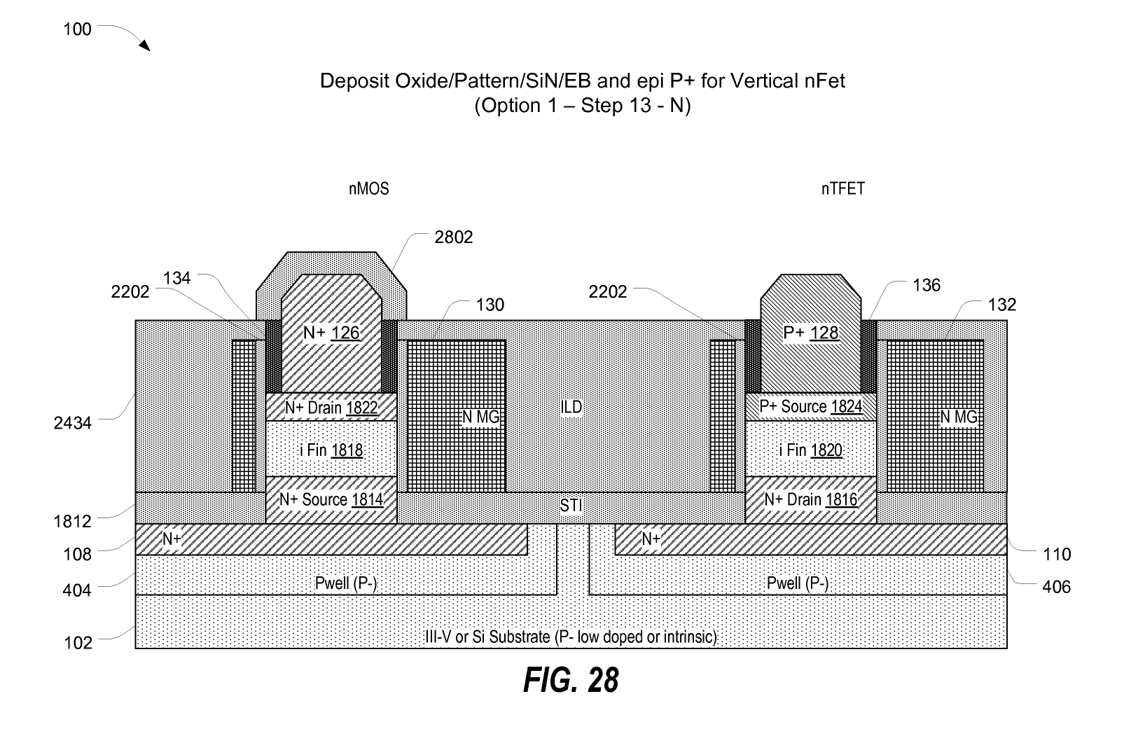

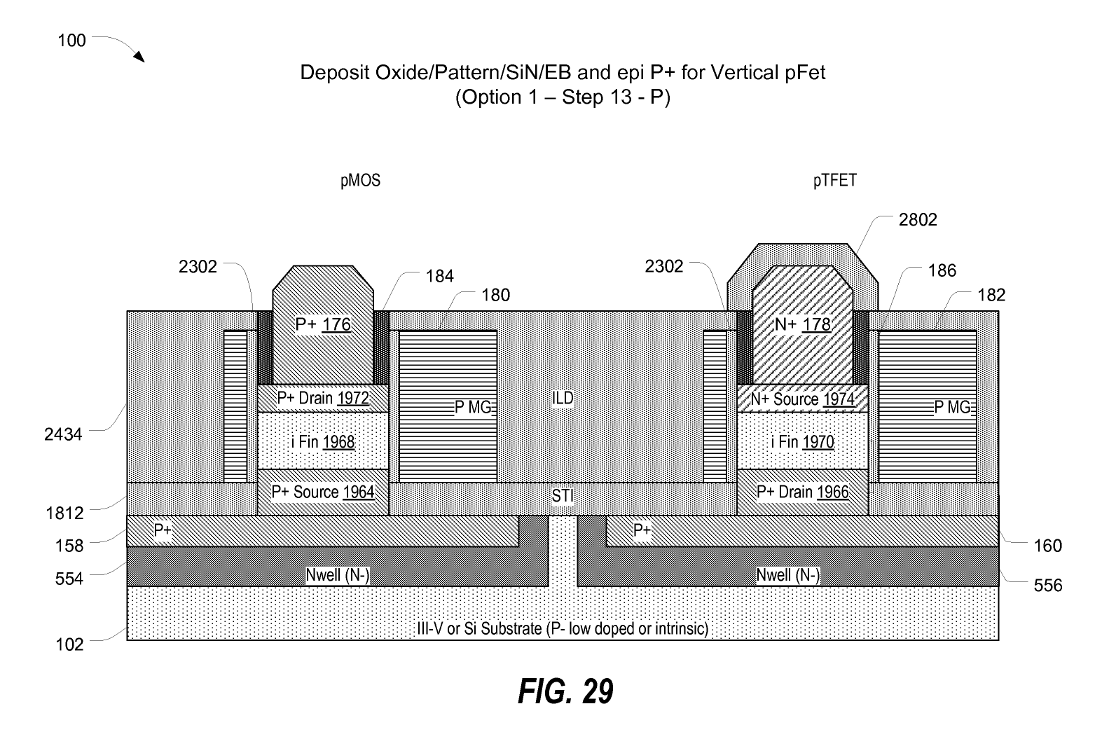

The method 300 further includes opening an ILD (e.g., oxide) layer, removing an SiN layer, removing an oxide layer, depositing a SiN layer, performing an etch back process to form spacers, epitaxially forming an N+ drain, depositing an oxide layer, opening an oxide layer, removing a SiN layer, removing an oxide layer, depositing a SiN layer, performing an etch back process to form spacers, and epitaxially forming a P+ drain, at 326. For example, an oxide etch may be performed to remove portions of the ILD layer, an SIN layer may be removed, and an oxide layer may be removed, as described with reference to FIGS. 24-25. The spacers 134 and 186 (e.g., SiN) of FIG. 1 may be formed, and the n-layers 126 and 178 of FIG. 1 may be epitaxially grown, as described with reference to FIGS. 26-27. An oxide layer may be deposited, an oxide etch may be performed to remove portions of the ILD layer, an SIN layer may be removed, an oxide layer may be removed, the spacers 136 and 184 (e.g., SiN) of FIG. 1 may be formed, and the p-layers 128 and 176 of FIG. 1 may be epitaxially grown, as described with reference to FIGS. 28-29.

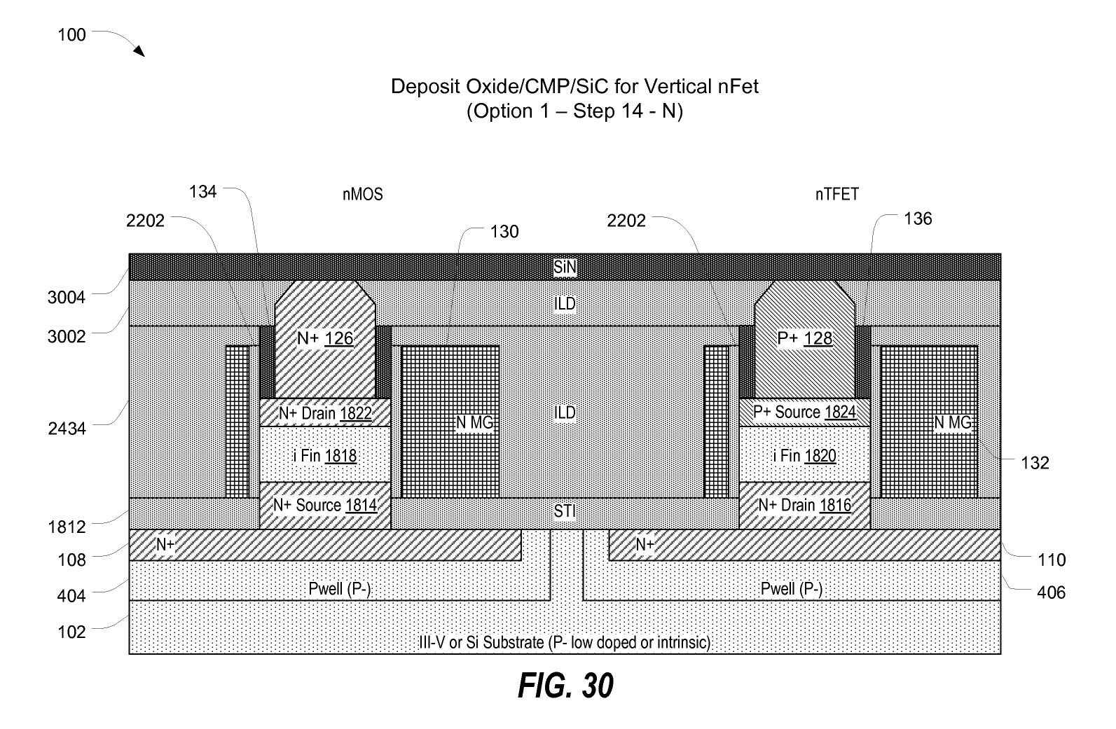

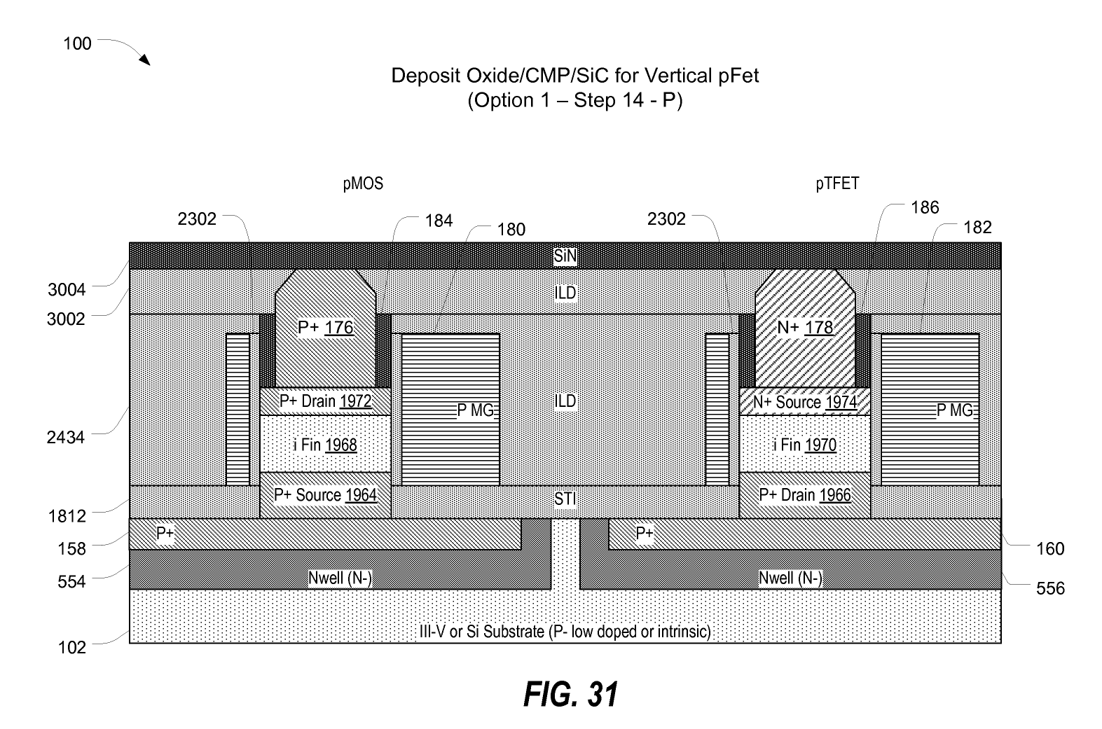

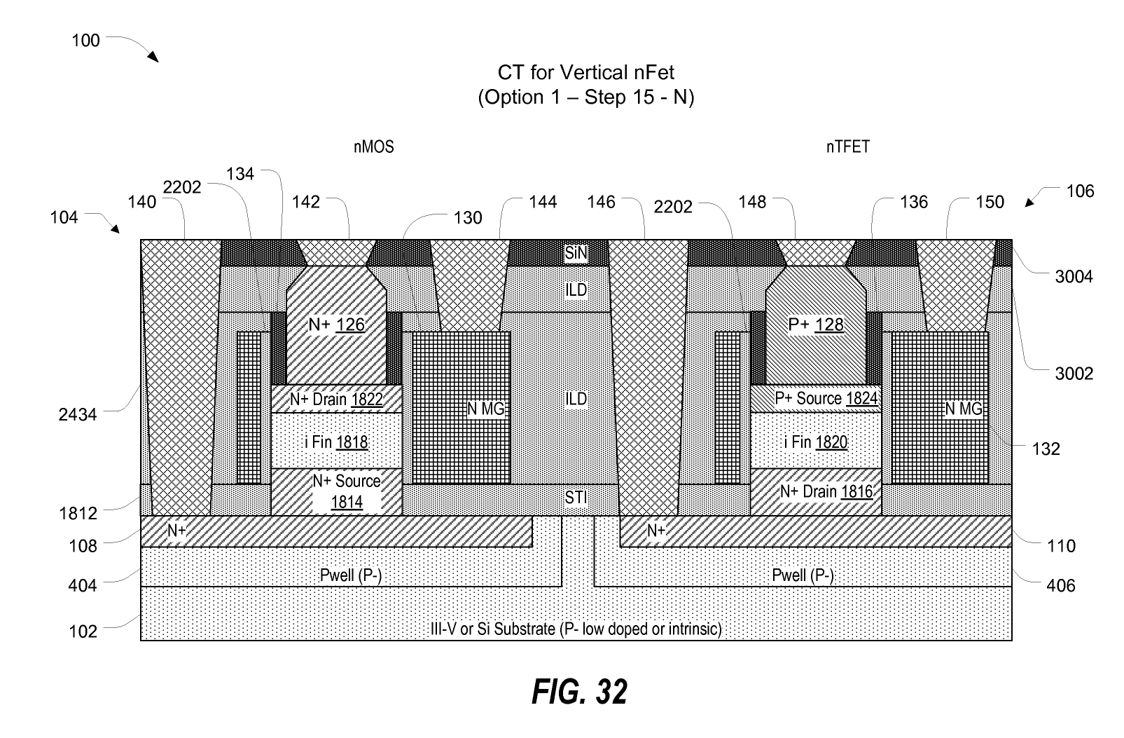

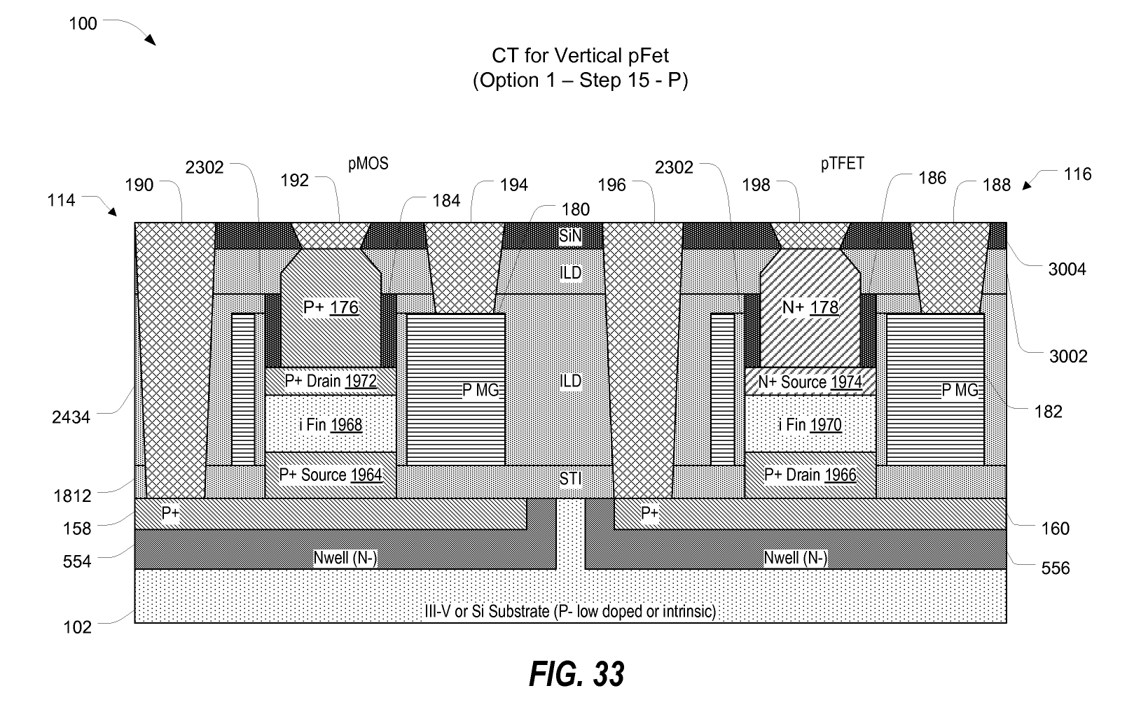

The method 300 also includes depositing an oxide layer, performing CMP, depositing a SiN layer, and forming contacts for a source, a drain, and a gate, at 328. For example, an ILD (e.g., oxide) layer may be deposited, CMP may be performed, and an SiN layer may be deposited, as described with reference to FIGS. 30-31. Contacts 140, 142, 144, 146, 148, 150, 188, 190, 192, 194, 196, and 198 of FIG. 1 may be formed, as described with reference to FIGS. 32-33.

The method 300 may thus enable a vertical CMOS transistor and a vertical TFET to be fabricated on the single substrate such that at least one of the vertical CMOS transistor or the vertical TFET is configured to support a current flow direction between a source and drain that is perpendicular to the single substrate. The vertical CMOS transistor may perform higher priority (e.g., critical) operations and the vertical TFET may perform lower priority (e.g., non-critical) operations. For example, higher priority operations may be assigned to the vertical CMOS transistor and lower priority operations may be assigned to the vertical TFET.

FIGS. 4-33, as described herein, illustrate a side view of the structure 100 of FIG. 1 as formed during multiple stages of a method of fabricating an electronic device (e.g., a semiconductor device, an integrated circuit device, or another electronic device). The structure 100 may include a vertical CMOS transistor and a vertical TFET formed on a single substrate, as described herein. At least one of the vertical CMOS transistor or the vertical TFET may be configured to support a current flow direction between a source and a drain that is perpendicular to the single substrate.

Referring to FIGS. 4-5, diagrams of a side view of the structure 100 of FIG. 1 as formed during a process of fabricating an electronic device are disclosed. The structure 100 includes the substrate 102. The substrate 102 may include a III-V compound layer or a silicon (Si) layer. The substrate 102 may be doped with an impurity of a first conductivity type (e.g., p-type). The substrate 102 may be low doped (e.g., p− low-doped). For example, the substrate 102 may be formed by adding one atom of a p-type dopant (e.g., Boron, Phosphorous, or Arsenic) per a particular number (e.g., 100 million) of atoms of silicon. In a particular embodiment, the substrate 102 may include an intrinsic (e.g., non-doped or low-doped) layer.

The structure 100 includes a Pwell 404, a Pwell 406, an Nwell 554, and an Nwell 556. For example, a first n-region and a second n-region of the substrate 102 may be doped with an impurity of a first conductivity type (e.g., p-type) to form the Pwell 404 and the Pwell 406, respectively. As another example, a first p-region and a second p-region of the substrate 102 may be doped with an impurity of a second conductivity type (e.g., n-type) to form the Nwell 554 and the Nwell 556, respectively.

Patterning and implantation may be used to form the n-layer 108, the n-layer 110, the p-layer 158, and the p-layer 160. For example, a photo resist 402 may be applied to the structure 100 after forming the Pwells 404 and 406 and the Nwells 554 and 556. The photo resist 402 may correspond to (e.g., cover) a portion of the structure 100. The n-layer 108 and the n-layer 110 may be formed by performing a first implantation (e.g., N+ ion implantation) on uncovered portions of the structure 100. The p-layer 158 and the p-layer 160 may be formed by applying a photo resist 502 to the structure 100 and by performing a second implantation (e.g., P+ ion implantation) subsequent to applying the photo resist 502.

Referring to FIGS. 6-7, diagrams of a side view of the structure 100 of FIG. 1 as formed during a process of fabricating an electronic device are disclosed. An intrinsic layer 602 (e.g., a silicon (Si) layer, a III-V compound layer, or a II-VI compound layer) may be formed on the structure 100. For example, the intrinsic layer 602 may be epitaxially grown subsequent to forming the n-layer 108, the n-layer 110, the p-layer 158, and the p-layer 160.

Referring to FIGS. 8-9, diagrams of a side view of the structure 100 of FIG. 1 as formed during a process of fabricating an electronic device are disclosed. An oxide layer may be deposited on the intrinsic layer 602. A first portion and a second portion of the oxide layer may be etched using patterning. For example, a mask may be applied to the oxide layer. The mask may leave the first portion and the second portion of the oxide layer uncovered. The uncovered portions (e.g., the first portion and the second portion) may be etched. For example, the first portion may be etched to form an etched portion 804 and an oxide layer 802. As another example, the second portion may be etched to form an etched portion 904 and an oxide layer 902. The oxide layer 802 and the oxide layer 902 may be remaining portions subsequent to etching. The oxide layer 802 may align with the n-layer 108. The oxide layer 902 may align with the p-layer 160.

Referring to FIGS. 10-11, diagrams of a side view of the structure 100 of FIG. 1 as formed during a process of fabricating an electronic device are disclosed. An n-layer 1002 (e.g., an N+ layer) and an n-layer 1102 (e.g., an N+ layer) may be formed on the intrinsic layer 602 in the etched portions 804 and 904. For example, epitaxy may be used to grow the n-layer 1002 in the etched portion 804. As another example, epitaxy may be used to grow the n-layer 1102 in the etched portion 904. The n-layer 1002 may, align with the n-layer 108 and the n-layer 1102 may align with the p-layer 160.

Having the n-layer 1002 align with the n-layer 108 may enable formation of a first n-type drain aligned with a first n-type source, as described with reference to FIG. 18, such that a current flow direction between the first n-type drain and the first n-type source is perpendicular to the substrate 102. Having the n-layer 1102 align with the p-layer 160 may enable formation of a second n-type source aligned with a second p-type drain, as described with reference to FIG. 19, such that a current flow direction between the second n-type source and the second p-type drain is perpendicular to the substrate 102.

Referring to FIGS. 12-13, diagrams of a side view of the structure 100 of FIG. 1 as formed during a process of fabricating an electronic device are disclosed. An oxide layer may be deposited subsequent to forming the n-layer 1002 and the n-layer 1102. For example, a first oxide layer may be deposited on the oxide layer 802, the oxide layer 902, the n-layer 1002, and the n-layer 1102 to form a second oxide layer. The second oxide layer may include the first oxide layer, the oxide layer 802, and the oxide layer 902. A first portion and a second portion of the second oxide layer may be etched using patterning. For example, a first portion of the second oxide layer may be etched to form an etched portion 1204 and an oxide layer 1202. As another example, a second portion of the second oxide layer may be etched to form an etched portion 1304 and an oxide layer 1302. The oxide layer 1202 and the oxide layer 1302 may be remaining portions of the second oxide layer subsequent to etching. The etched portion 1204 may align with the n-layer 110 and the etched portion 1304 may align with the p-layer 158.

Referring to FIGS. 14-15, diagrams of a side view of the structure 100 of FIG. 1 as formed during a process of fabricating an electronic device are disclosed. A p-layer 1402 (e.g., a P+ layer) and a p-layer 1502 (e.g., a P+ layer) may be formed on the intrinsic layer 602 in the etched portions 1204 and 1304. For example, epitaxy may be used to grow the p-layer 1402 in the etched portion 1204. As another example, epitaxy may be used to grow the p-layer 1502 in the etched portion 1304. The p-layer 1402 may align with the n-layer 110 and the p-layer 1502 may align with the p-layer 158. In a particular embodiment, the p-layer 1402, the p-layer 1502, or both, may include a silicon (Si) layer, a III-V compound layer, or a II-VI compound layer.

Having the p-layer 1402 align with the n-layer 110 may enable formation of a second p-type source aligned with a second n-type drain, as described with reference to FIG. 18, such that a current flow direction between the second p-type source and the second n-type drain is perpendicular to the substrate 102. Having the p-layer 1502 align with the p-layer 158 may enable formation of a first p-type drain aligned with a first p-type source, as described with reference to FIG. 19, such that a current flow direction between the first p-type drain and the first p-type source is perpendicular to the substrate 102.

Referring to FIGS. 16-17, diagrams of a side view of the structure 100 of FIG. 1 as formed during a process of fabricating an electronic device are disclosed. An oxide layer may be deposited subsequent to forming the p-layer 1402 and the p-layer 1502. For example, a first oxide layer may be deposited on the oxide layer 1202, the oxide layer 1302, the p-layer 1402, and the p-layer 1502 to form an oxide layer 1602. The oxide layer 1602 may include the first oxide layer, the oxide layer 1202, and the oxide layer 1302. The oxide layer 1602 may be etched, polished, or both. For example, chemical mechanical planarization (CMP) may be performed on the oxide layer 1602. A silicon (e.g., silicon mononitride (SiN)) layer 1604 may be deposited on the oxide layer 1602 subsequent to performing the CMP.

Referring to FIGS. 18-19, diagrams of a side view of the structure 100 as formed during a process of fabricating an electronic device are disclosed. Semiconductor fins may be formed by patterning. A shallow trench isolation (STI) layer may be formed subsequent to forming the semiconductor fins. The semiconductor fins may be formed by applying a mask to the SiN layer 1604 and performing an etch process (e.g., an anisotropic etch process). The etch process may be timed for a particular duration, such that portions of the SiN layer 1604, the oxide layer 1602, the p-layer 1402, the p-layer 1502, the n-layer 1002, the n-layer 1102, the intrinsic layer 602, the n-layer 108, the p-layer 110, the p-layer 158, and the p-layer 160 are etched. For example, a portion of the n-layer 108 may be etched to form an n-type source 1814 (e.g., N+ source), and a portion of the n-layer 110 may be etched to form an n-type drain 1816 (e.g., N+ drain). A portion of the p-layer 158 may be etched to form a p-type source 1964 (e.g., P+ source), and a portion of the p-layer 160 may be etched to form a p-type drain 1966 (e.g., P+ drain). The n-type source 1814, the n-type drain 1816, the p-type source 1964, and the p-type drain 1966 may be co-planar.

The intrinsic layer 602 may be etched to form intrinsic layers (i-Fins) 1818, 1820, 1968, and 1970. The i-Fins 1818, 1820, 1968, and 1970 may be co-planar. The n-layer 1002 may be etched to form an n-type drain 1822 (e.g., N+ drain), the n-layer 1102 may be etched to form an n-type source 1974 (e.g., N+ source), the p-layer 1502 may be etched to form a p-type drain 1972 (e.g., P+ drain), and the p-layer 1402 may be etched to form a p-type source 1824 (e.g., P+ source). The n-type drain 1822, the n-type source 1974, the p-type drain 1972, and the p-type source 1824 may be co-planar.

The i-Fin 1818 may be between the n-type source 1814 and the n-type drain 1822. The i-Fin 1820 may be between the n-type drain 1816 and the p-type source 1824. The i-Fin 1968 may be between the p-type source 1964 and the p-type drain 1972. The i-Fin 1970 may be between the p-type drain 1966 and the n-type source 1974.

The oxide layer 1602 may be etched to form an oxide layer 1802, an oxide layer 1804, an oxide layer 1902, and an oxide layer 1904. The SiN layer 1604 may be etched to form a SiN layer 1806, a SiN layer 1808, a SiN layer 1906, and a SiN layer 1908. The oxide layer 1802 may be between the n-type drain 1822 and the SiN layer 1806. The oxide layer 1804 may be between the p-type source 1824 and the SiN layer 1808. The oxide layer 1902 may be between the p-type drain 1972 and the SiN layer 1906. The oxide layer 1904 may be between the n-type source 1974 and the SiN layer 1908.

A first n-type semiconductor fin may include the n-type source 1814, the i-Fin 1818, the n-type drain 1822, the oxide layer 1802, and the SiN layer 1806. A second n-type semiconductor fin may include the n-type drain 1816, the i-Fin 1820, the p-type source 1824, the oxide layer 1804, and the SiN layer 1808. A first p-type semiconductor fin may include the p-type source 1964, the i-Fin 1968, the p-type drain 1972, the oxide layer 1902, and the SiN layer 1906. A second p-type semiconductor fin may include the p-type drain 1966, the i-Fin 1970, the n-type source 1974, the oxide layer 1904, and the SiN layer 1908.

An STI layer 1812 may be created subsequent to forming the semiconductor fins (e.g., the first n-type semiconductor fin, the second n-type semiconductor fin, the first p-type semiconductor fin, and the second p-type semiconductor fin). For example, an oxide layer may be deposited on the substrate 102 to form the STI layer 1812. In a particular embodiment, CMP may be performed to expose the SiN layers 1806, 1808, 1906, and 1908 subsequent to depositing the STI layer 1812 and the STI layer 1812 may be etched (e.g., dry-etched or wet-etched) to expose sides of the SiN layers 1806, 1808, 1906, and 1908, the oxide layers 1802, 1804, 1902, and 1904, the n-type drain 1822, the n-type source 1974, the p-type source 1824, and the p-type drain 1972, and the i-Fins 1818, 1820, 1968, and 1970. The STI layer 1812 may be etched (e.g., dry-etched or wet-etched) to expose a portion of the sides of the n-type source 1814, the n-type drain 1816, the p-type source 1964, and the p-type drain 1966. The exposed portions of the semiconductor fins (e.g., the first n-type semiconductor fin, the second n-type semiconductor fin, the first p-type semiconductor fin, and the second p-type semiconductor fin) may be cleaned.

Referring to FIGS. 20-21, diagrams of a side view of the structure 100 of FIG. 1 as formed during a process of fabricating an electronic device are disclosed. Oxide layers 2002 may be formed (e.g., deposited) on the first n-type semiconductor fin and the second n-type semiconductor fin and oxide layers 2102 may be formed on the first p-type semiconductor fin and the second p-type semiconductor fin. Patterning may be used to form a dummy gate on the oxide layers 2002 and 2102. For example, a poly silicon layer may be deposited on the oxide layers 2002, patterned, and etched to form dummy gates 2004 on the first n-type semiconductor fin and the second n-type semiconductor fin. The dummy gates 2004 may be remaining portions of the poly silicon layer subsequent to etching. As another example, the poly silicon layer may be deposited on the oxide layers 2102, patterned, and etched to form dummy gates 2104 on the first p-type semiconductor fin and the second p-type semiconductor fin. The dummy gates 2104 may be remaining portions of the poly silicon layer subsequent to etching.

Referring to FIGS. 22-23, diagrams of a side view of the structure 100 of FIG. 1 as formed during a process of fabricating an electronic device are disclosed. An inter-layer dielectric (ILD) layer 2234 (e.g., an oxide layer) may be deposited on portions of the STI layer 1812 that are not covered by the dummy gates 2004 and 2104. CMP may be performed to expose the dummy gates 2004 and 2104. The dummy gates 2004 and the oxide layers 2002 may be removed (e.g., etched) to form n-trenches.

Oxide layers 2202 may be formed in the n-trenches on the first n-type semiconductor fin and the second n-type semiconductor fin. The oxide layers 2202 may include a high dielectric constant (high-k) material. For example, depositing the oxide layer 2202 may include depositing a silicon (Si) oxide on each of the first n-type semiconductor fin and the second n-type semiconductor fin and depositing a hafnium (Hf) oxide on the silicon oxide. The n-trenches may be filled with a first metal (e.g., an n-metal) to form the n-metal gates (N MGs) 130 and 132. The first metal may include titanium nitride (TiN), titanium aluminide (TiAl), or both. The first metal may also include tungsten (W), aluminum (Al), or both.

The dummy gates 2104 and the oxide layers 2102 may be removed (e.g., etched) to form p-trenches. Oxide layers 2302 may be formed in the p-trenches on the first p-type semiconductor fin and the second p-type semiconductor fin. The oxide layers 2302 may include a high dielectric constant (high-k) material. For example, depositing the oxide layer 2302 may include depositing a silicon (Si) oxide on each of the first p-type semiconductor fin and the second p-type semiconductor fin and depositing a hafnium (Hf) oxide on the silicon oxide.

The p-trenches may be filled with a second metal (e.g., a p-metal) to form the p-metal gates (P MGs) 180 and 182. The second metal may include titanium nitride (TiN). The second metal may also include tungsten (W), aluminum (Al), or both. An ILD layer (e.g., an oxide layer) may be deposited subsequent to forming the n-metal gates 130 and 132 and the p-metal gates 180 and 182. Chemical mechanical planarization (CMP) may be performed, e.g., to etch and/or to polish the first metal and the second metal.

Referring to FIGS. 24-25, diagrams of a side view of the structure 100 of FIG. 1 as formed during a process of fabricating an electronic device are disclosed. An ILD layer 2434 may be deposited on the structure 100. A portion of the ILD layer 2434 on the SIN layer 1806, the SiN layer 1806, and the oxide layer 1802 may be removed (e.g., etched) to form a first n-recess that exposes the n-type drain 1822. A portion of the ILD layer 2434 on the SIN layer 1908, the SiN layer 1908, and the oxide layer 1904 may be removed (e.g., etched) to form a second p-recess that exposes the n-type source 1974.

Referring to FIGS. 26-27, diagrams of a side view of the structure 100 of FIG. 1 as formed during a process of fabricating an electronic device are disclosed. The spacer 134 may be formed on side-walls of the first n-recess and the spacer 186 may be formed on side-walls of the second p-recess. For example, a first SiN layer may be formed (e.g., deposited) in the first n-recess on the n-type drain 1822 and a second SiN layer may be formed (e.g., deposited) in the second p-recess on the n-type source 1974. A portion of the first SiN layer may be removed (e.g., etched) to form the spacer 134 and a portion of the second SiN layer may be removed (e.g., etched) to form the spacer 186.

The n-layer 126 (e.g., N+) may be formed between the spacer 134 on the n-type drain 1822 and the n-layer 178 (e.g., N+) may be formed between the spacer 186 on the n-type source 1974. For example, the n-layers 126 and 178 may be grown using electron-beam (EB) lithography, epitaxy, or both.

Referring to FIGS. 28-29, diagrams of a side view of the structure 100 of FIG. 1 as formed during a process of fabricating an electronic device are disclosed. An oxide layer 2802 may be deposited subsequent to forming the n-layers 126 and 178. The oxide layer 2802 may be patterned to cover the n-layer 126 and the n-layer 178. For example, a mask may be applied to portions of the oxide layer 2802 covering the n-layer 126 and the n-layer 178 and a remaining portion of the oxide layer 2802 may be removed (e.g., etched).

A first portion of the ILD layer 2434 that is on the SiN layer 1808, the SiN layer 1808, and the oxide layer 1804 may be removed to form a first n-recess that exposes the p-type source 1824. A second portion of the ILD layer 2434 that is on the SiN layer 1906, the SiN layer 1906, and the oxide layer 1902 may be removed (e.g., etched) to form a second p-recess that exposes the p-type drain 1972.

The spacer 136 may be formed on side-walls of the first n-recess and the spacers 184 may be formed on side-walls of the first p-recess. For example, a first SiN layer may be formed (e.g., deposited) in the first n-recess on the p-type source 1824 and a second SiN layer may be formed (e.g., deposited) in the second p-recess on the p-type drain 1972. A portion of the first SiN layer may be removed (e.g., etched) to form the spacer 136 and a portion of the second SiN layer may be removed (e.g., etched) to form the spacer 184.

The p-layer 128 (e.g., P+) may be formed between the spacer 136 on the p-type source 1824 and the p-layer 176 (e.g., P+) may be formed between the spacer 184 on the p-type drain 1972. For example, the p-layers 128 and 176 may be grown using electron-beam (EB) lithography, epitaxy, or both.

Referring to FIGS. 30-31, diagrams of a side view of the structure 100 of FIG. 1 as formed during a process of fabricating an electronic device are disclosed. An ILD layer 3002 (e.g., an oxide layer) may be deposited subsequent to forming the p-layers 128 and 176. CMP may be performed on the ILD layer 3002 to expose the p-layers 128 and 176 and to expose the n-layers 126 and 178. A SiN layer 3004 may be deposited subsequent to performing the CMP.

Referring to FIGS. 32-33, diagrams of a side view of the structure 100 of FIG. 1 as formed during a process of fabricating an electronic device are disclosed. Contacts 140, 142, 144, 146, 148, 150, 190, 192, 194, 196, 198, and 188 may be formed. For example, recesses may be formed in the structure 100 using etching. In a particular embodiment, a mask may be applied to the SiN layer 3004 leaving portions of the SiN layer 3004 uncovered. Etching may be performed on the uncovered portions to form the recesses. The recesses may be filled with conducting material (e.g., metal, poly-silicon, or silicide) to form the contacts 140, 142, 144, 146, 148, 150, 190, 192, 194, 196, 198, and 188. CMP may be performed subsequent to filling the recesses.

The contact 140 may be a source contact for the n-type source 1814, the contact 142 may be a drain contact for the n-type drain 1822, and the contact 144 may be a gate contact for the n-metal gate 130. The n-type source 1814, the n-type drain 1822, and the n-metal gate 130 may form the nMOS 104. The nMOS 104 may correspond to an n-type fin-shaped field-effect transistor (nFinFET). The contact 190 may be a source contact for the p-type source 1964, the contact 192 may be a drain contact for the p-type drain 1972, and the contact 194 may be a gate contact for the p-metal gate 180. The p-type source 1964, the p-type drain 1972, and the p-metal gate 180 may form the pMOS 114. The pMOS 114 may correspond to a p-type fin-shaped field-effect transistor (pFinFET).

The contact 148 may be a source contact for the p-type source 1824, the contact 146 may be a drain contact for the n-type drain 1816, and the contact 150 may be a gate contact for the n-metal gate 132. The p-type source 1824, the n-type drain 1816, and the n-metal gate 132 may form the nTFET 106. The contact 198 may be a source contact for the n-type source 1974, the contact 196 may be a drain contact for the p-type drain 1966, and the contact 188 may be a contact for the p-metal gate 182. The n-type source 1974, the p-type drain 1966, and the p-metal gate 182 may form the pTFET 116.

The nMOS 104 may be configured to support a current flow direction between the n-type source 1814 and the n-type drain 1822 that is perpendicular to the substrate 102. The pMOS 114 may be configured to support a current flow direction between the p-type source 1964 and the p-type drain 1972 that is perpendicular to the substrate 102.

The nTFET 106 may be configured to support a current flow direction between the p-type source 1824 and the n-type drain 1816 that is perpendicular to the substrate 102. The pTFET 116 may be configured to support a current flow direction between the n-type source 1974 and the p-type drain 1966 that is perpendicular to the substrate 102.

The structure 100 may thus include a CMOS transistor (e.g., the nMOS 104 and the pMOS 114) and a TFET (e.g., the nTFET 106 and the pTFET 116). At least one of the nMOS 104, the pMOS 114, the nTFET 106, or the pTFET 116 may be configured to support a current flow direction between a source and a drain that is perpendicular to the single substrate. The CMOS transistor may perform operations faster than the TFET and the TFET may consume less power than the CMOS transistor. For example, higher priority operations may be assigned to the CMOS transistor and lower priority operations may be assigned to the TFET. A balance between performance and power consumption may be reached by assigning higher priority (e.g., critical) operations to the CMOS transistor and assigning lower priority (e.g., non-critical) operations to the TFET.

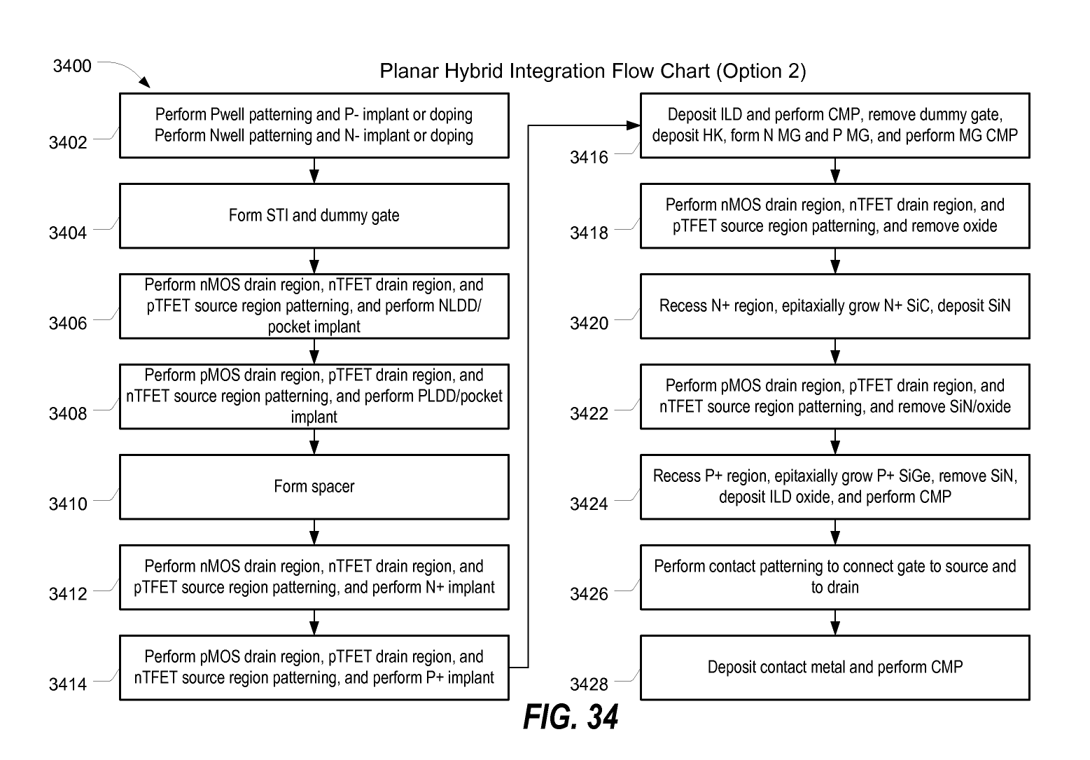

FIG. 34 is a flow chart illustrating a particular embodiment of a method 3400 of fabricating a structure (e.g., the structure 200 of FIG. 2). The structure 200 may include a mobility enhancement strength layer, as described herein.

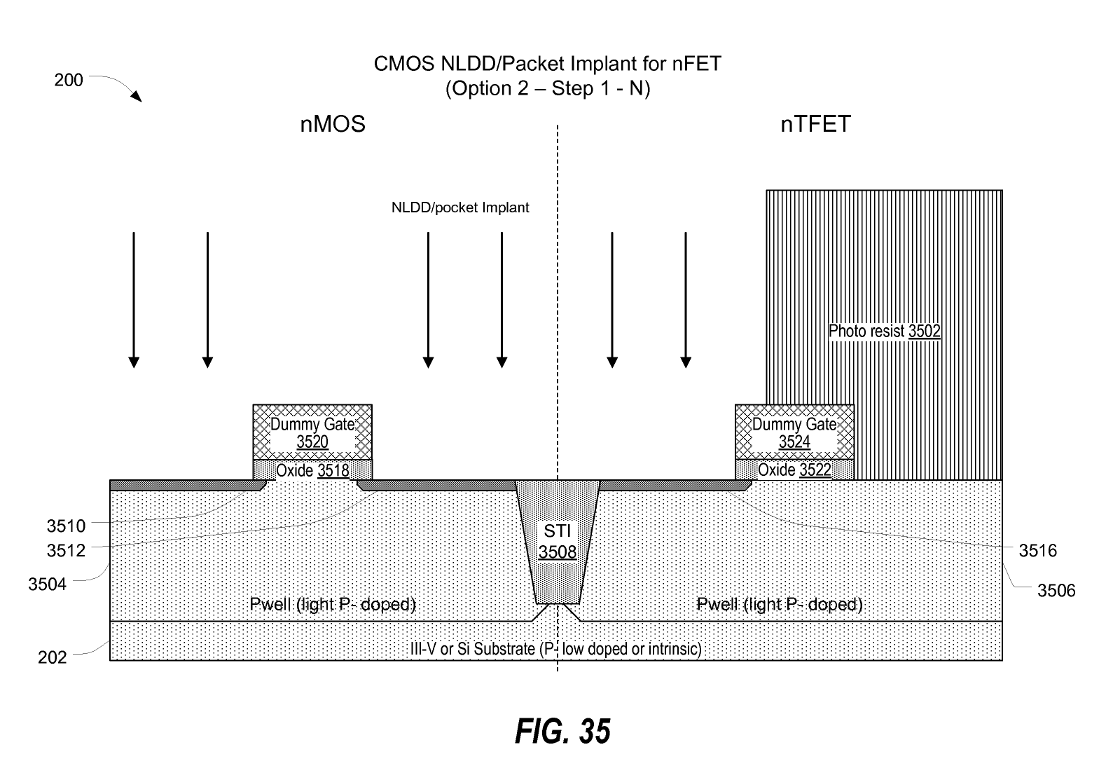

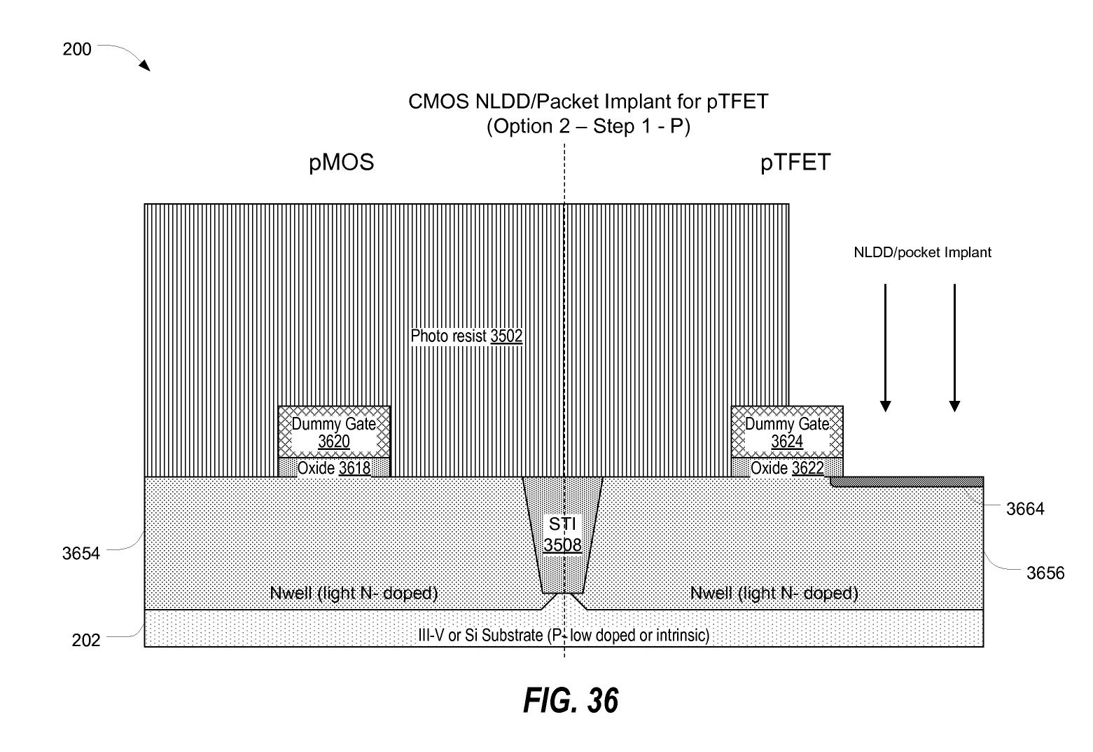

The method 3400 includes performing Pwell patterning and P− implant or P− doping, and performing Nwell patterning and N− implant or N− doping, at 3402. For example, portions of the substrate 202 of FIG. 2 may be patterned and doped to form Pwells and Nwells, as described with reference to FIGS. 35-36. For example, first portions of the substrate 202 may be P− doped to form the Pwells and second portions of the substrate 202 may be N− doped to form the Nwells. In a particular embodiment, the Pwells and the Nwells may be formed by implantation.

The method 3400 also includes forming an STI layer and forming a dummy gate, at 3404. For example, an STI layer may be formed on the substrate 202 of FIG. 2, as described with reference to FIGS. 35-36. First dummy gates may be formed on first portions of the Pwells, as described with reference to FIG. 35. Second dummy gates may be formed on second portions of the Nwells, as described with reference to FIG. 36.

The method 3400 further includes performing nMOS drain region, nTFET drain region, and pTFET source region patterning, and performing NLDD/pocket implant, at 3406. For example, a photoresist may be applied to the structure 200 of FIG. 2 and n-regions may be formed by n-type lightly doped source and drain (LDD) implantation or by n-type pocket implantation, as described with reference to FIGS. 35-36.

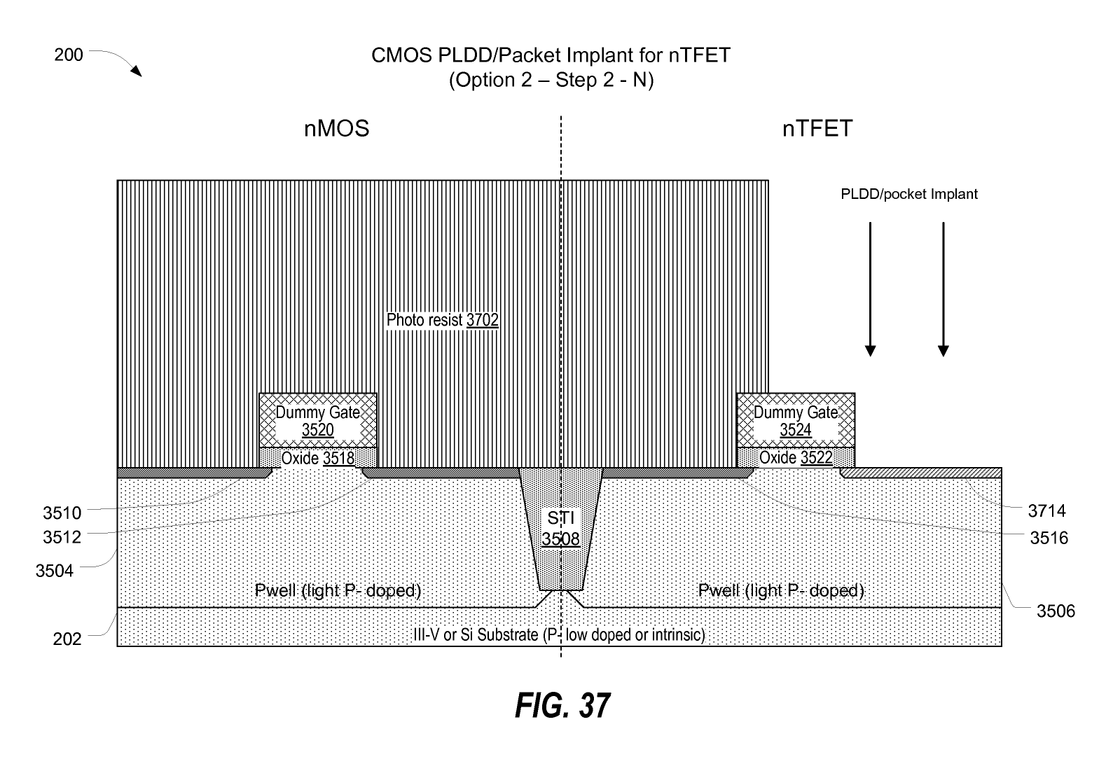

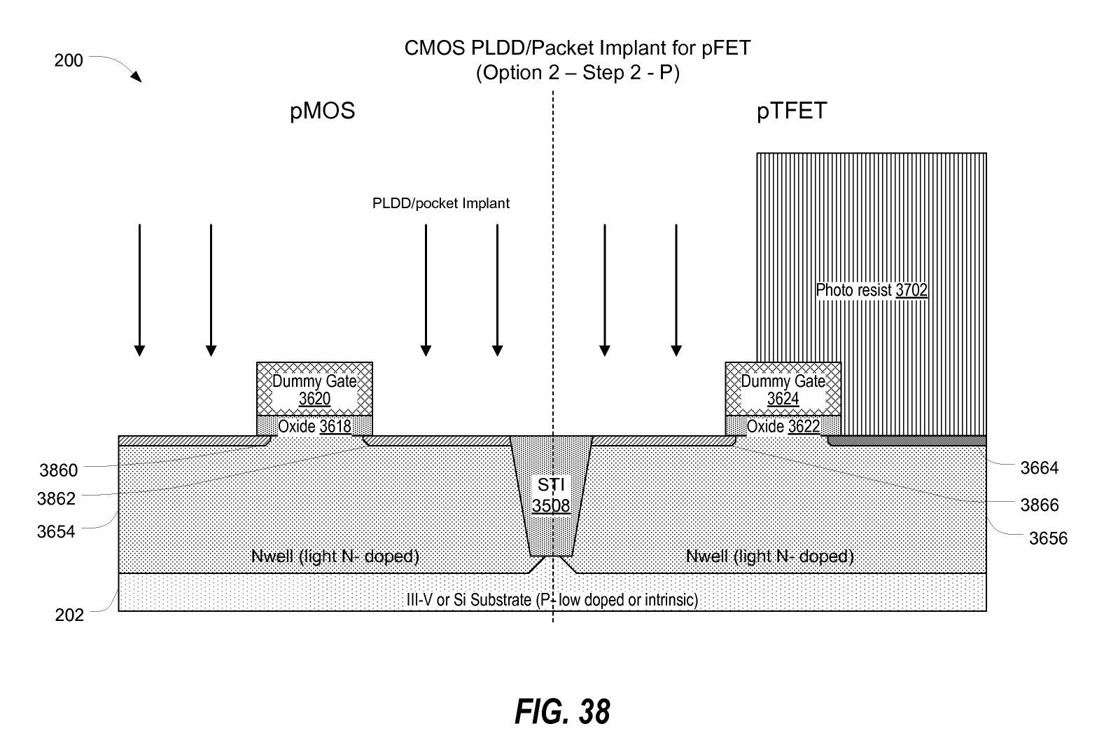

The method 3400 also includes performing pMOS drain region, pTFET drain region, and nTFET source region patterning, and performing PLDD/pocket implant, at 3408. For example, a photoresist may be applied to the structure 200 of FIG. 2 and p-regions may be formed by p-type lightly doped source and drain (LDD) implantation or by p-type pocket implantation, as described with reference to FIGS. 37-38.

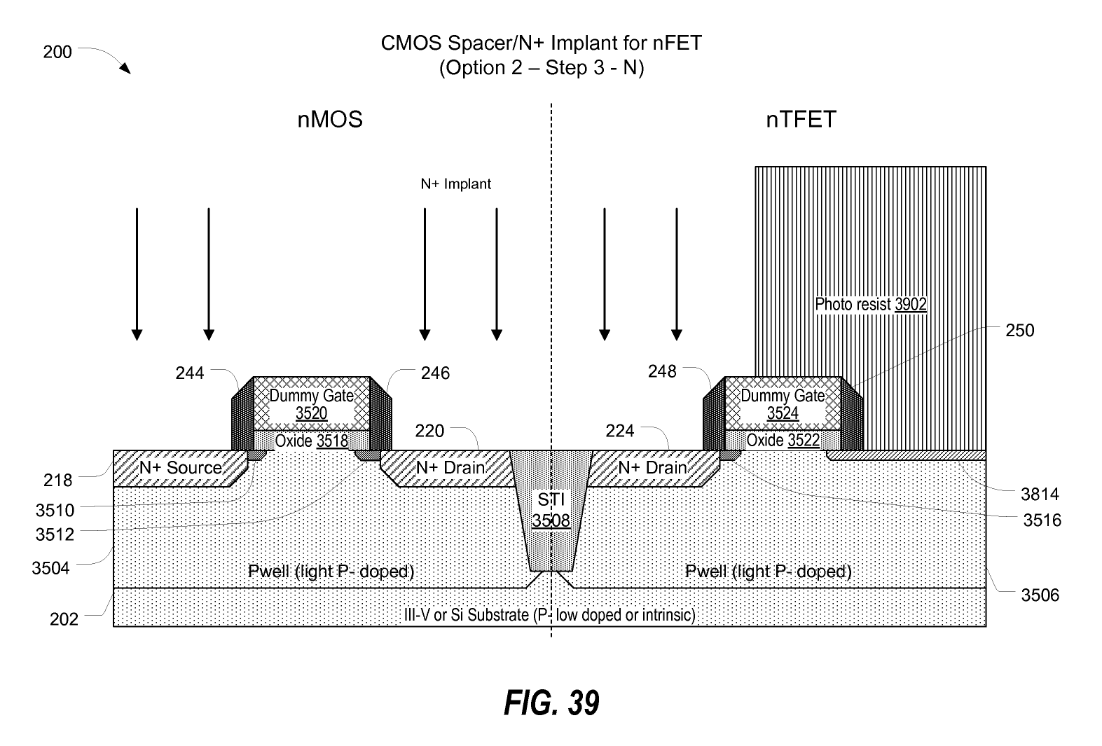

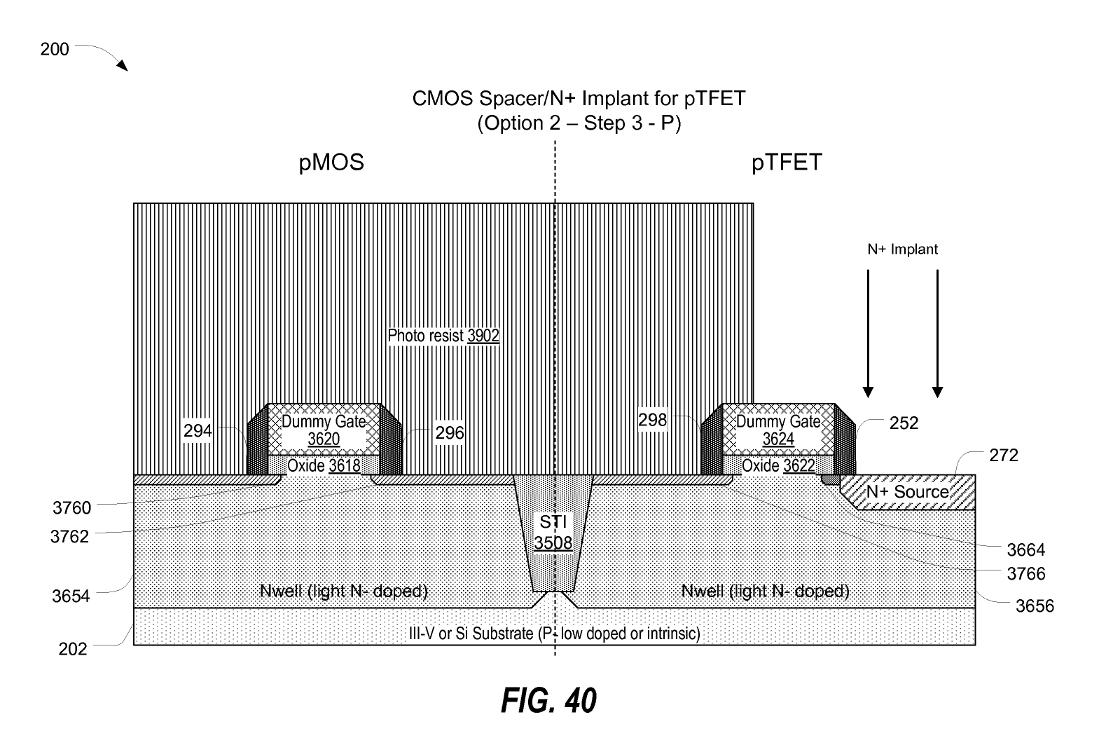

The method 3400 further includes forming spacer, at 3410. For example, the spacers 244, 246, 248, 250, 294, 296, 298, and 252 of FIG. 2 may be formed, as described with reference to FIGS. 39-40.

The method 3400 also includes performing nMOS drain region, nTFET drain region, and pTFET source region patterning, and performing N+ implant, at 3412. For example, the n-regions 218, 220, 224, and 272 of FIG. 2 may be formed by patterning and performing N+ implantation or doping, as described with reference to FIGS. 39-40.

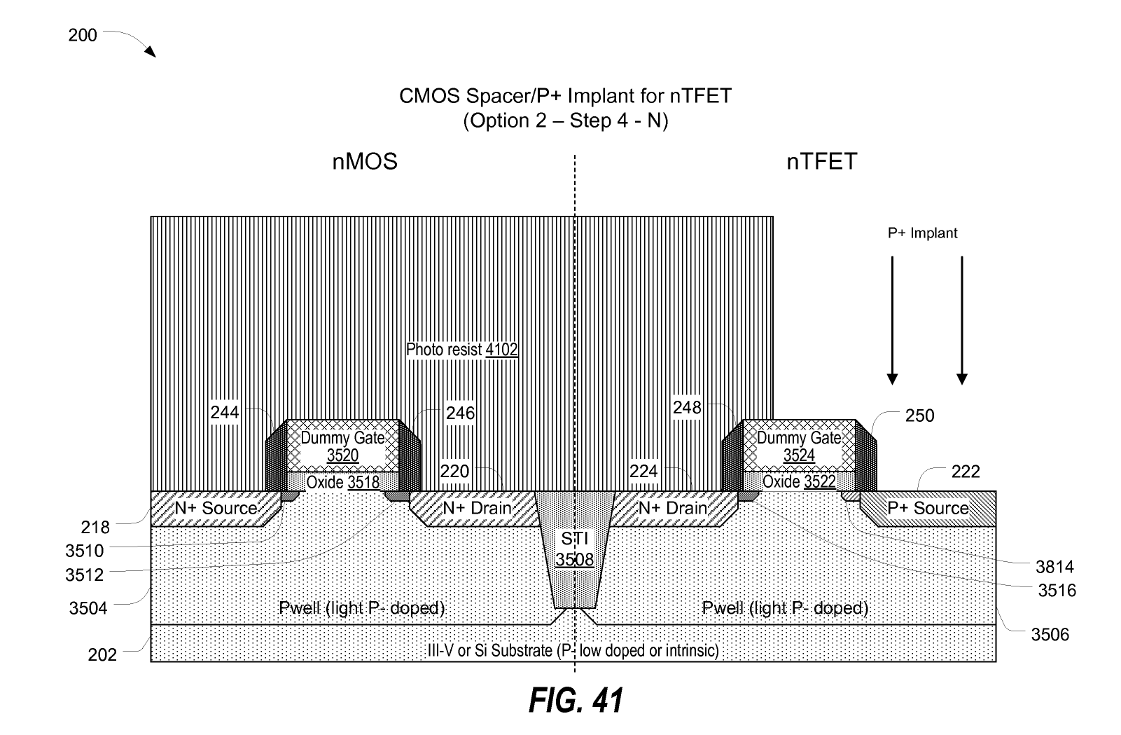

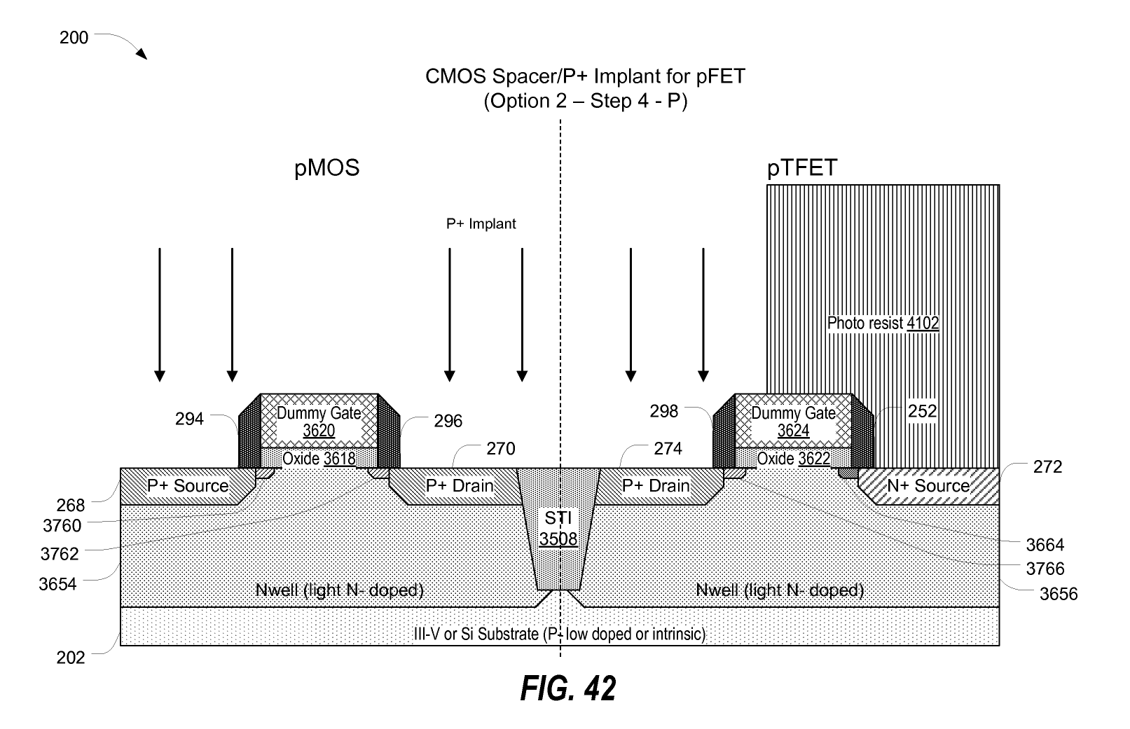

The method 3400 further includes performing pMOS drain region, pTFET drain region, and nTFET source region patterning and performing P+ implant, at 3414. For example, the p-layers 222, 268, 270, and 274 of FIG. 2 may be formed by patterning and performing P+ implantation or doping, as described with reference to FIGS. 41-42.

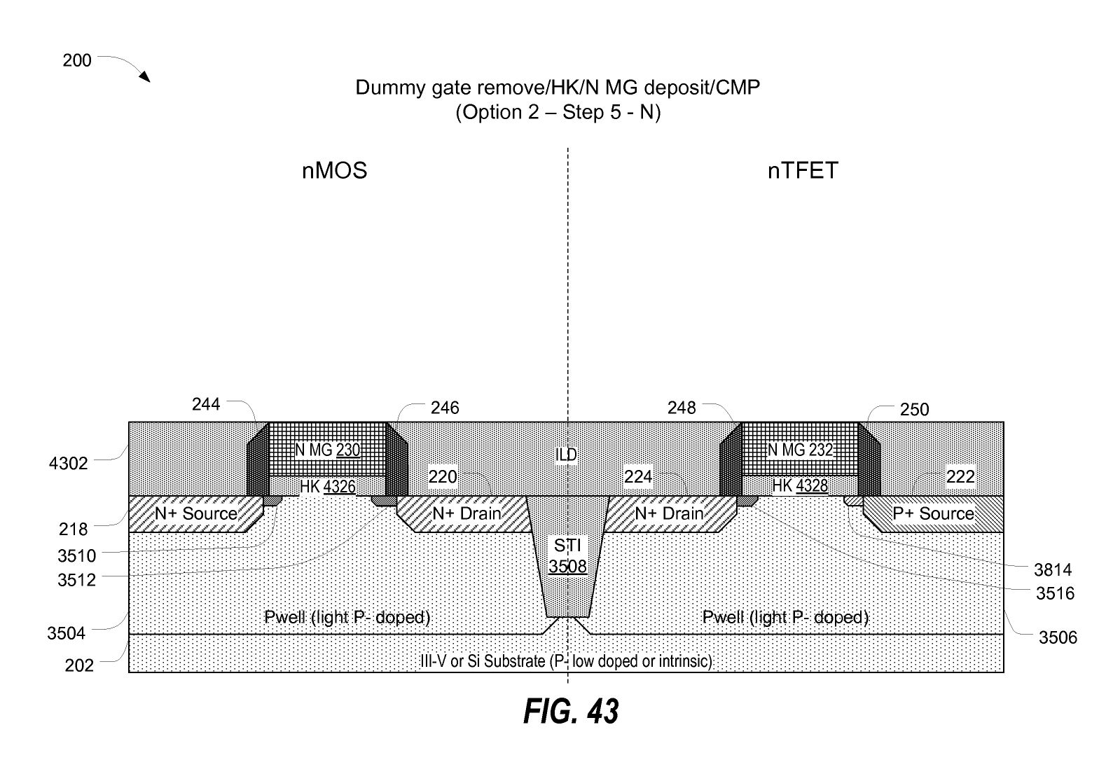

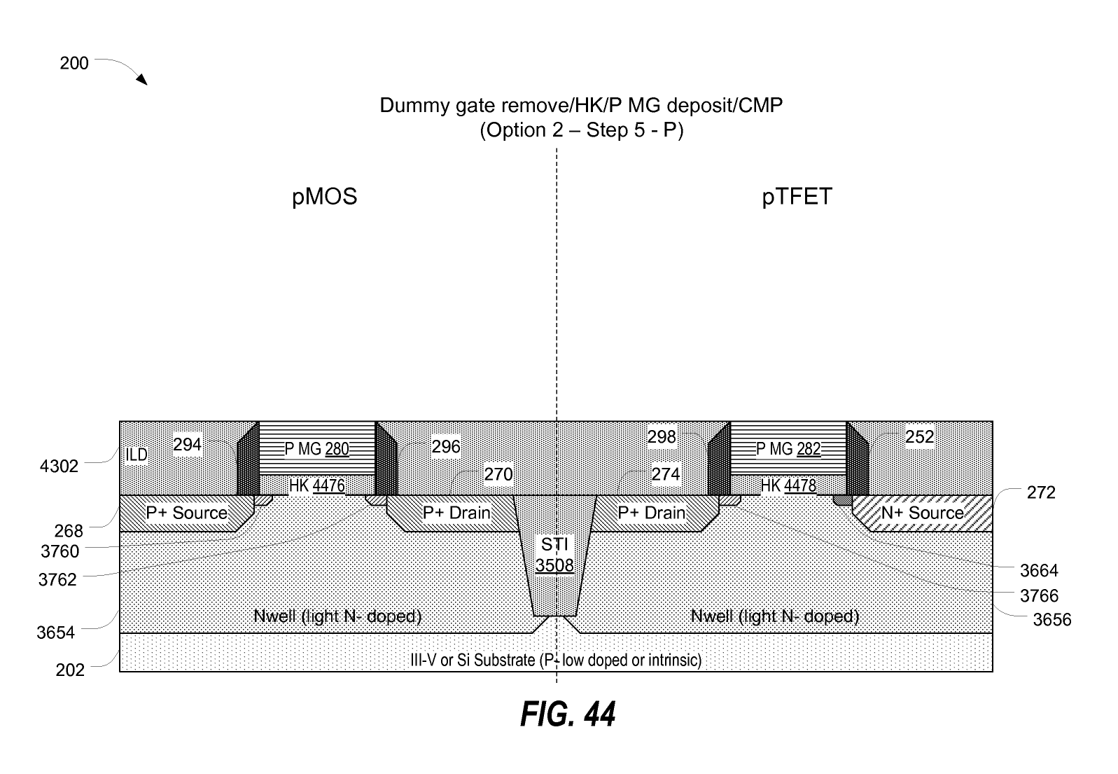

The method 3400 also includes depositing an ILD layer, performing CMP, removing a dummy gate, depositing a high-k (HK) layer, forming n-metal gates (N MG) and p-metal gates (P MG), and performing metal gate (MG) CMP, at 3416. For example, an ILD layer may be deposited on the structure 200 of FIG. 2 and CMP may be performed, as described with reference to FIGS. 43-44. Dummy gates may be removed and a high-k layer may be deposited, as described with reference to FIGS. 43-44. The n-metal gates (N MGs) 230 and 232, and the p-metal gates (P MGs) 280 and 282 may be formed, as described with reference to FIGS. 43-44. CMP may be performed, as described with reference to FIGS. 43-44.

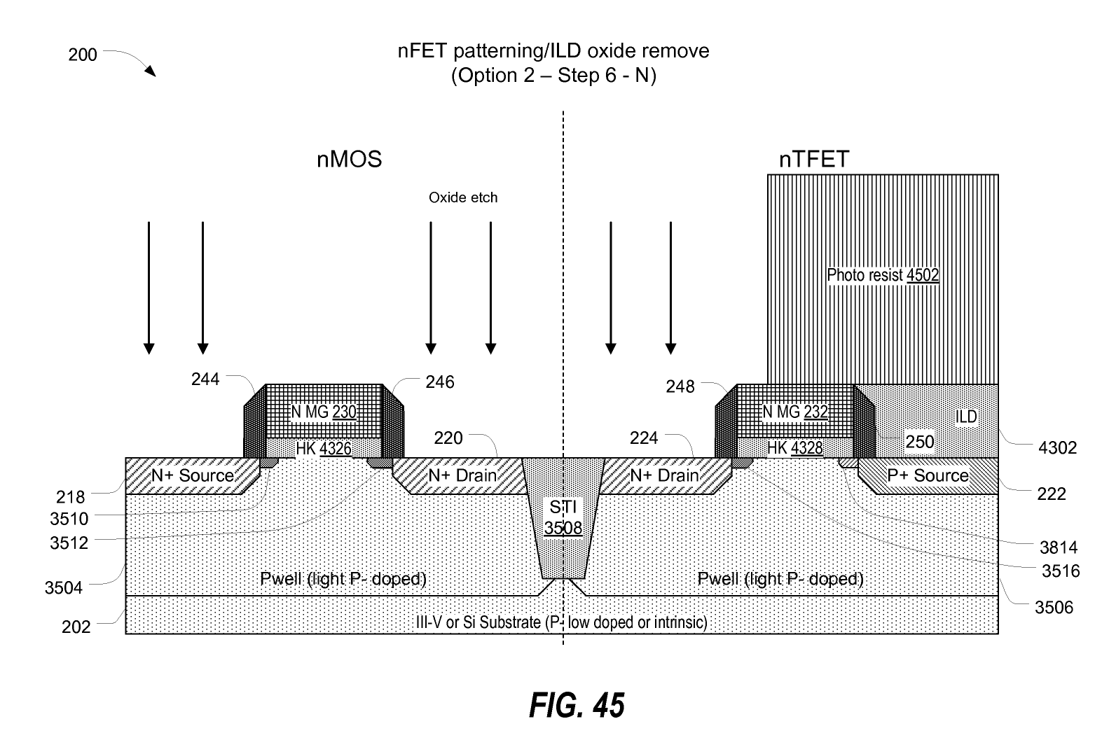

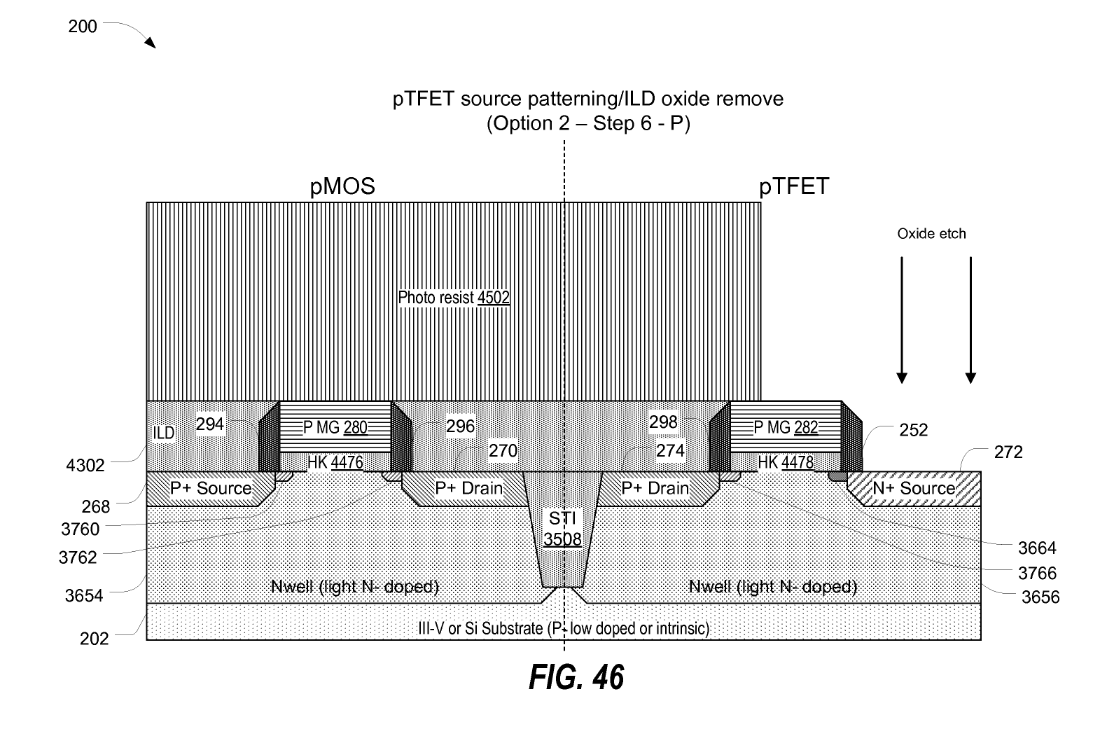

The method 3400 further includes performing nMOS drain region, nTFET drain region, and pTFET source region patterning, and removing a portion of an oxide layer, at 3418. For example, a photo resist may applied to the structure 200 of FIG. 2 and an oxide etch may be performed on a portion of the ILD layer not covered by the photo resist, as described with reference to FIGS. 45-46.

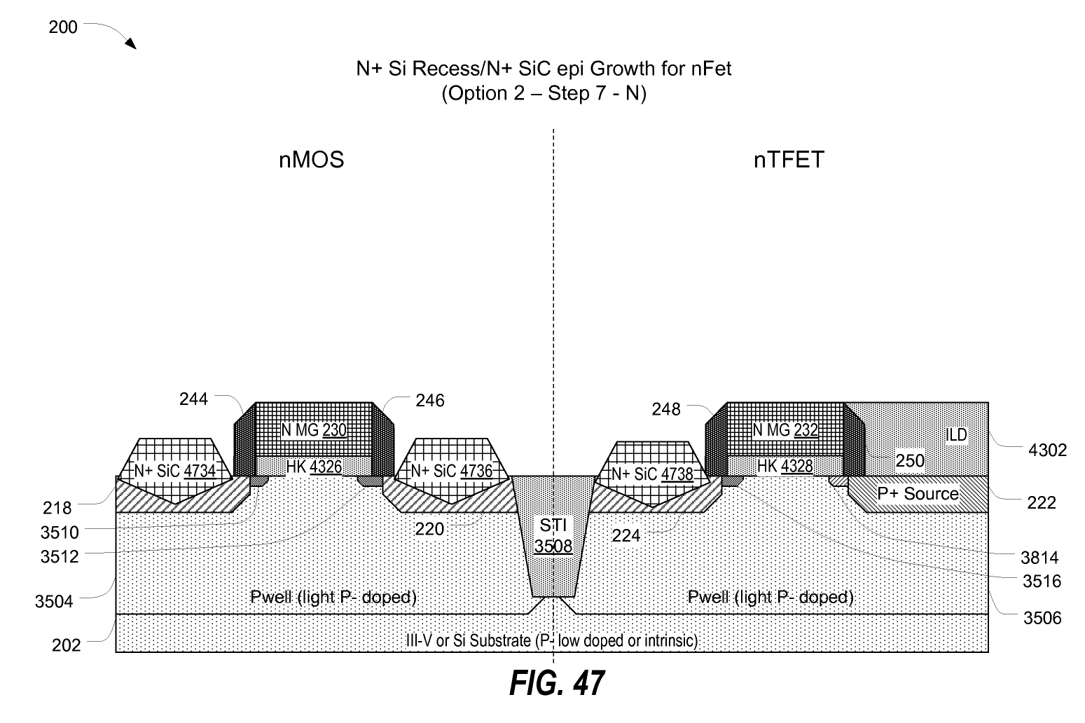

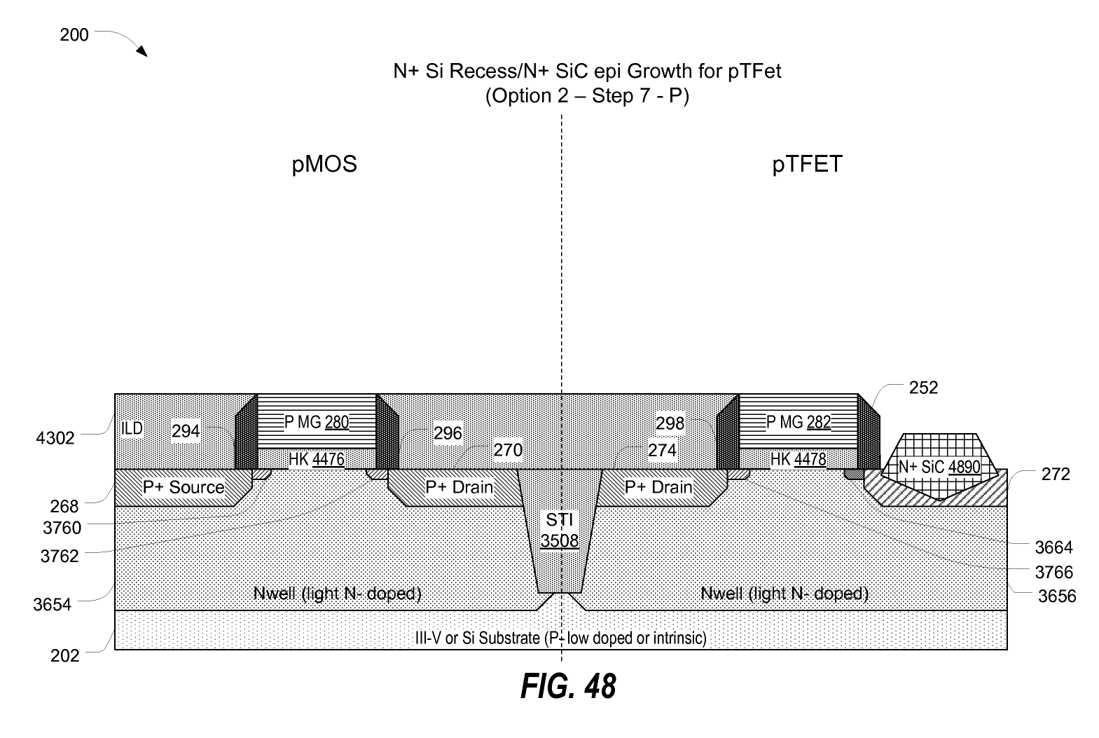

The method 3400 also includes forming a recess in an N+ region, epitaxially growing N+SiC regions, and depositing a SiN layer, at 3420. For example, recesses may be formed in the n-regions 218, 220, 224, and 272 of FIG. 2, as described with reference to FIGS. 47-48. N-type (e.g., N+) silicon carbide (SiC) regions may be epitaxially grown in the recesses, as described with reference to FIGS. 47-48. The mobility enhancement strength layer may include the N-type silicon carbide regions.

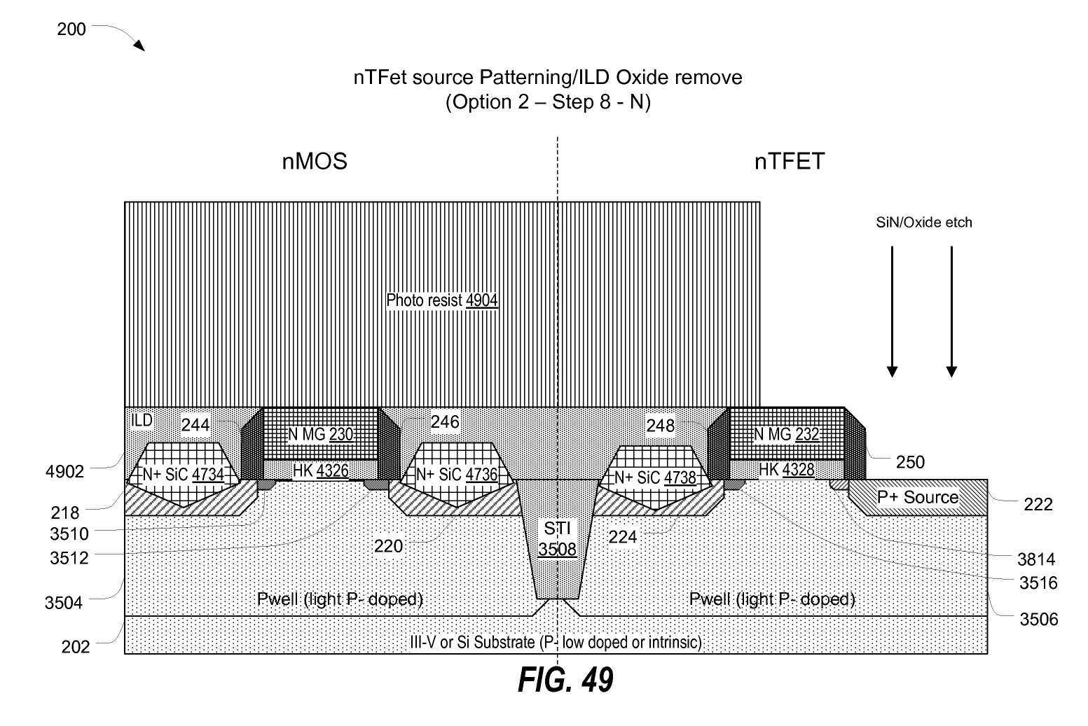

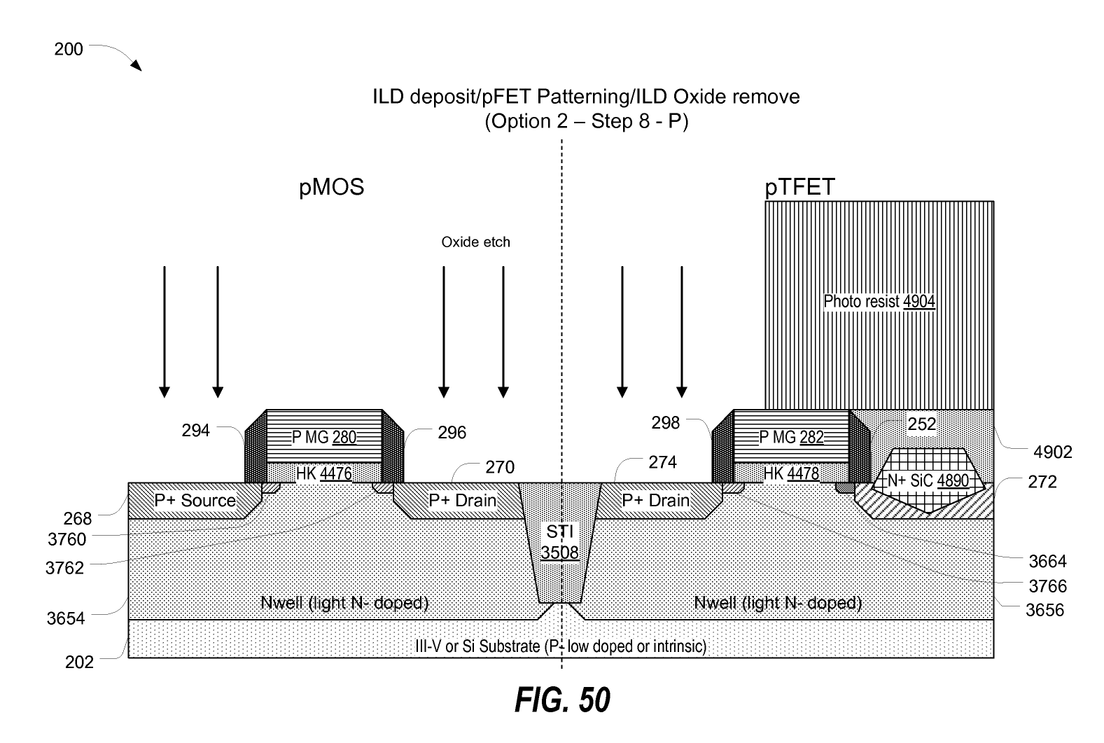

The method 3400 further includes performing pMOS drain region, pTFET drain region, and nTFET source region patterning and removing an ILD (e.g., SiN/oxide) layer, at 3422. For example, an ILD layer (e.g., a silicon mononitride (SiN) layer or an oxide layer) may be applied to the structure 200 of FIG. 2 subsequent to forming the n-type SiC regions, as described with reference to FIGS. 49-50. A photo resist may be applied to the structure 200 of FIG. 2 subsequent to applying the ILD layer, as described with reference to FIGS. 49-50. An etch may be performed to remove portions of the ILD layer not covered by the photo resist, as described with reference to FIGS. 49-50.

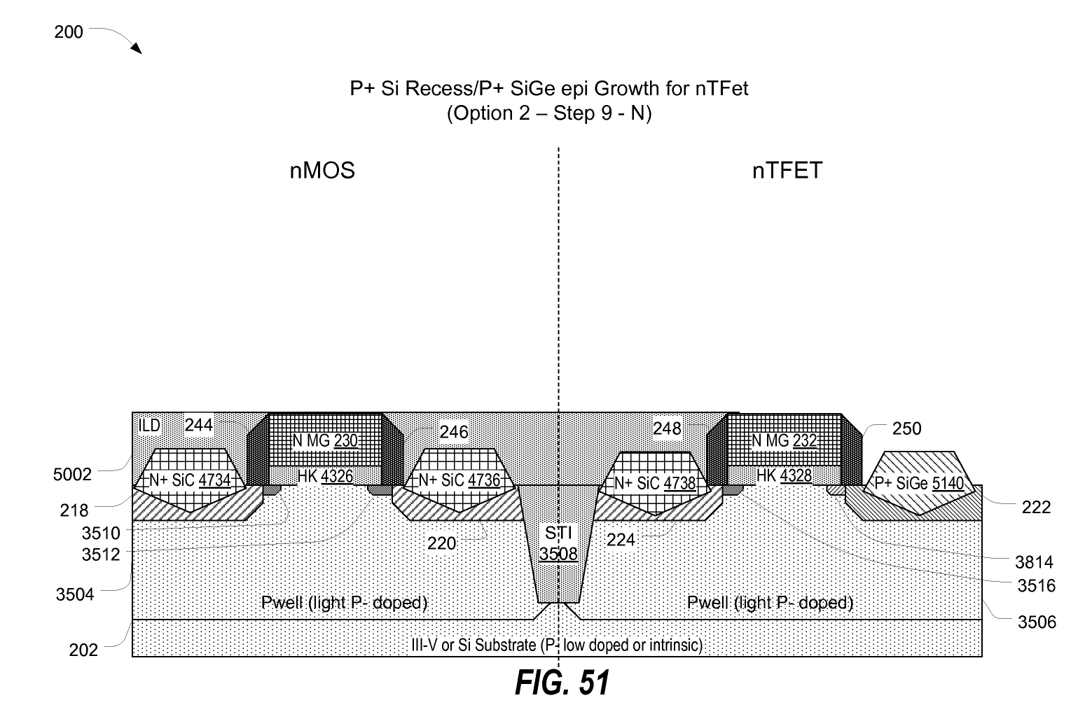

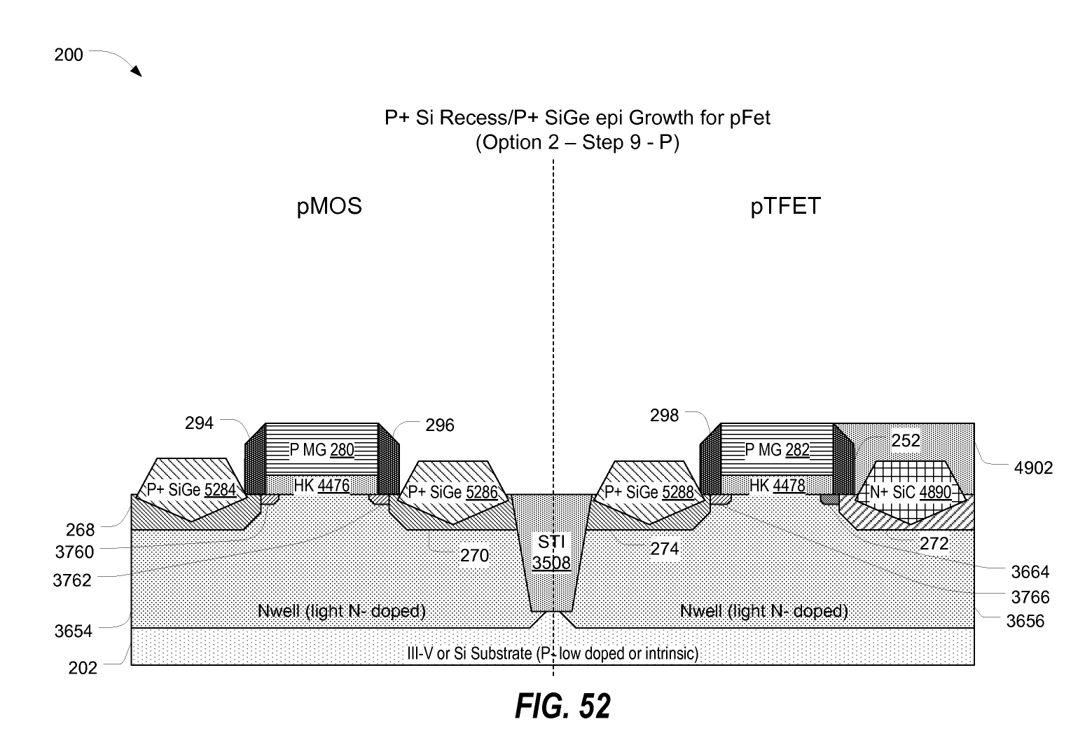

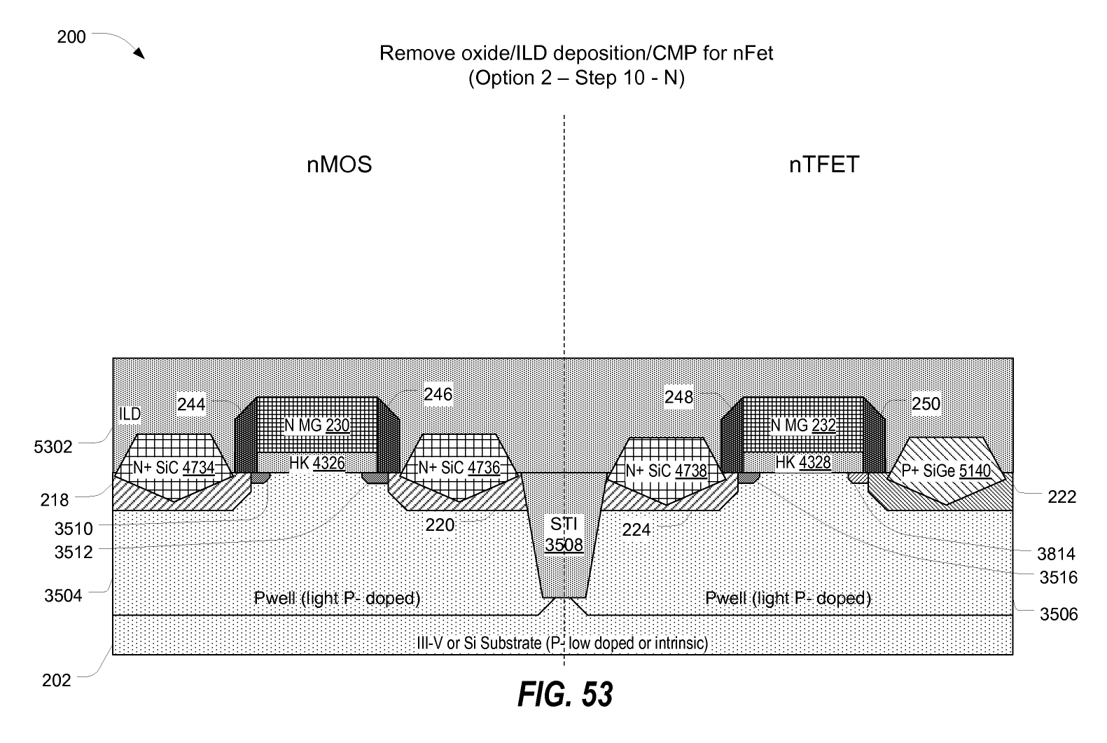

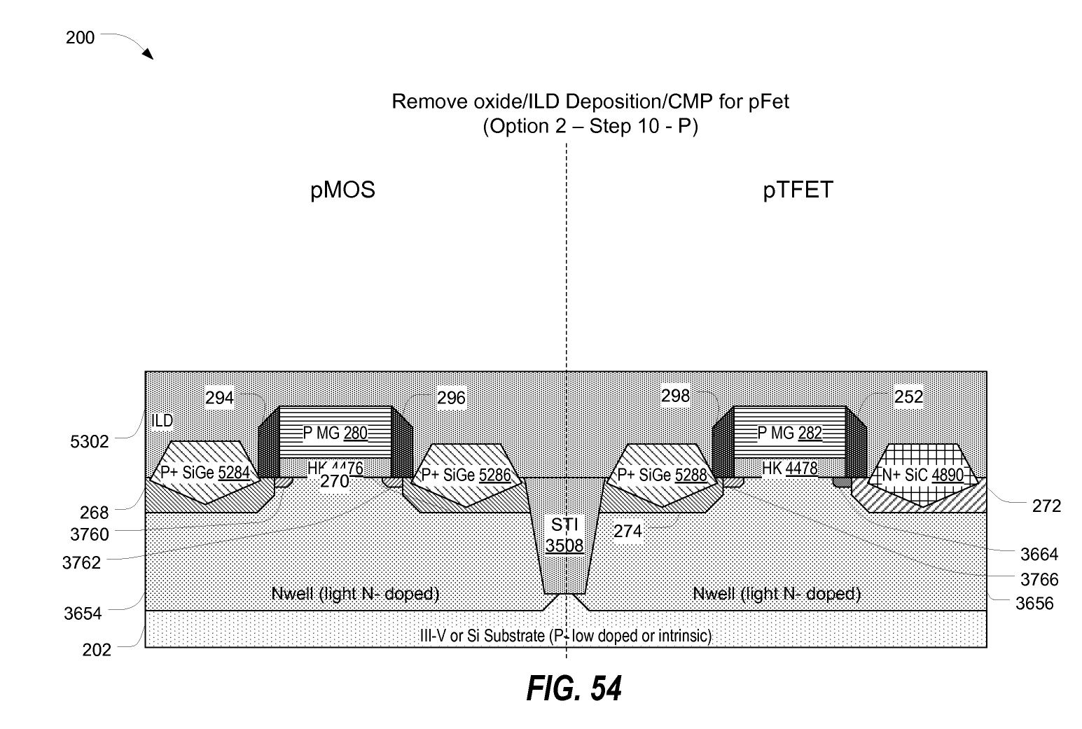

The method 3400 also includes forming a recess in a P+ region, epitaxially growing P+SiGe regions, removing an ILD (e.g., SiN/oxide) layer, depositing an ILD (e.g., oxide) layer, and performing CMP, at 3424. For example, recesses may be formed in the p-regions 222, 268, 270, and 274 of FIG. 2, as described with reference to FIGS. 51-52. P-type (e.g., P+) silicon germanium (SiGe) regions may be epitaxially grown in the recesses, as described with reference to FIGS. 51-52. The mobility enhancement strength layer may include the P-type silicon germanium regions. An ILD layer may be deposited on the structure 200 subsequent to forming the p-type SiGe regions and CMP may be performed, as described with reference to FIGS. 53-54.

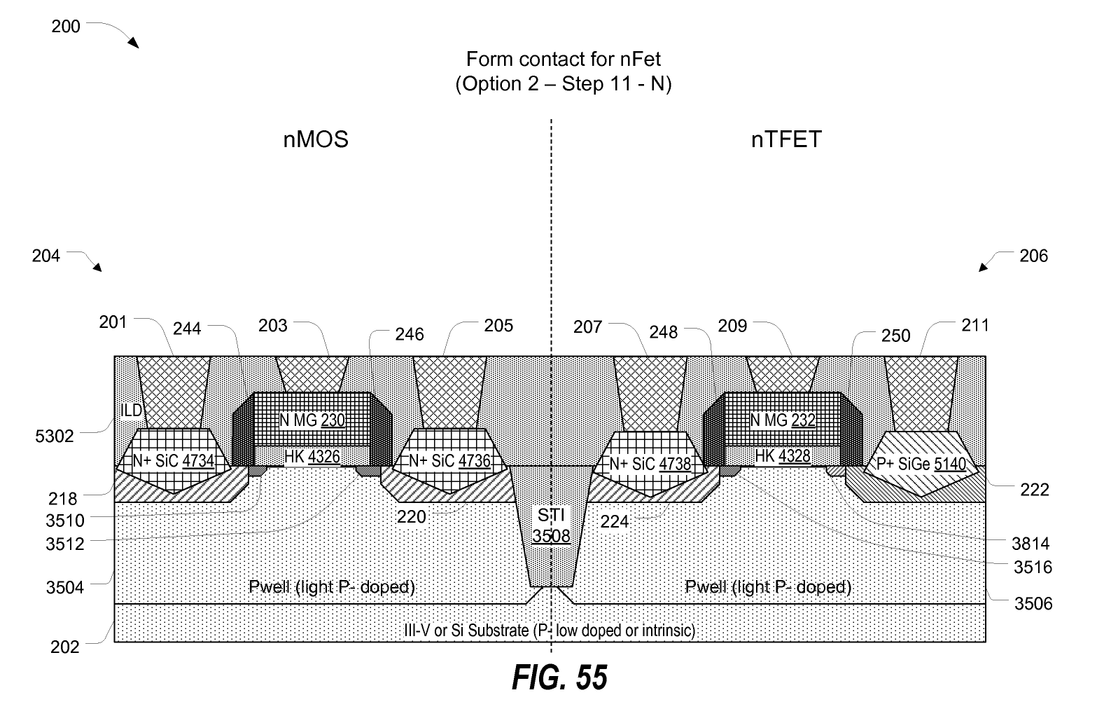

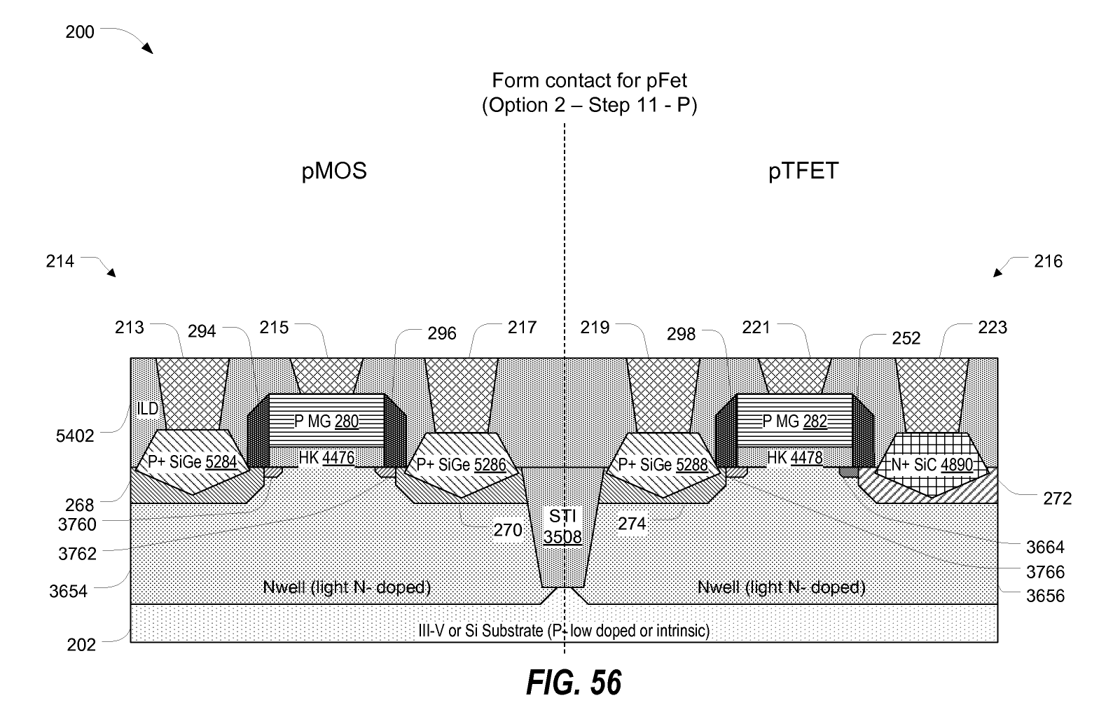

The method 3400 further includes performing contact patterning to connect a gate to a source and to a drain, at 3426. Recesses for contacts 201, 203, 205, 207, 209, 211, 213, 215, 217, 219, 221, and 223 of FIG. 2 may be formed in the structure 200, as described with reference to FIGS. 55-56.

The method 3400 also includes depositing contact metal and performing CMP, at 3428. The recesses may be filled with a conducting material (e.g., metal) to form the contacts 201, 203, 205, 207, 209, 211, 213, 215, 217, 219, 221, and 223 of FIG. 2, as described with reference to FIGS. 55-56. CMP may be performed.

The n-type source 4734, the n-type drain 4736, and the n-metal gate 230 may form the nMOS 204 of FIG. 2. The nMOS 204 may correspond to a planar nMOS. The p-type source 5284, the p-type drain 5286, and the p-metal gate 280 may form the pMOS 214. The pMOS 214 may correspond to a planar pMOS.

The p-type source 5140, the n-type drain 4738, and the n-metal gate 232 may form the nTFET 206 of FIG. 2. The n-type source 4890, the p-type drain 5288, and the p-metal gate 282 may form the pTFET 216 of FIG. 2.

The method 3400 may thus enable a CMOS transistor (e.g., the nMOS 204 and the pMOS 214) and a TFET (e.g., the nTFET 206 and the pTFET 216) to be fabricated on a single substrate. At least one of the nMOS 204, the pMOS 214, the nTFET 206, or the pTFET 216 may include a mobility enhancement strength layer. For example, the mobility enhancement strength layer may include at least one of silicon-carbide or silicon germanium. The mobility enhancement strength layer may provide compression strength, tensile strength, or both. The CMOS transistor may perform higher priority (e.g., critical) operations and the TFET may perform lower priority (e.g., non-critical) operations. For example, higher priority operations may be assigned to the CMOS transistor and lower priority operations may be assigned to the TFET.

FIGS. 35-56, as described herein, illustrate a side view of the structure 200 of FIG. 2 as formed during multiple stages of a method of fabricating an electronic device (e.g., a semiconductor device, an integrated circuit device, or another electronic device). The structure 200 may include a planar CMOS transistor and a planar TFET formed on a single substrate. At least one of the planar CMOS transistor or the planar TFET may include a mobility enhancement strength layer. The mobility enhancement strength layer may provide compression strength, tensile strength, or both.

Referring to FIGS. 35-36, diagrams of a side view of the structure 200 of FIG. 2 as formed during a process of fabricating an electronic device are disclosed. The structure 200 includes the substrate 202. The substrate 202 may include a III-V compound layer or a silicon (Si) layer. The substrate 202 may be doped with an impurity of a first conductivity type (e.g., p-type). The substrate 202 may be low doped (e.g., p− low-doped). For example, the substrate 202 may be formed by adding one atom of a p-type dopant (e.g., Boron, Phosphorous, or Arsenic) per a particular number (e.g., 100 million) of atoms of silicon. In a particular embodiment, the substrate 202 may include an intrinsic (e.g., non-doped or low-doped) layer.

The substrate 202 includes a Pwell 3504, a Pwell 3506, an Nwell 3654, and an Nwell 3656. For example, a first n-region and a second n-region of the substrate 202 may be doped with an impurity of a first conductivity type (e.g., light p-type) to form the Pwell 3504 and the Pwell 3506, respectively. As another example, a first p-region and a second p-region of the substrate 102 may be doped with an impurity of a second conductivity type (e.g., light n-type) to form the Nwell 3654 and the Nwell 3656, respectively.

An STI layer 3508 may be formed on the structure 200. For example, a recess may be formed in the structure 200 using patterning. The recess may be filled with oxide to form the STI layer 3508.

An oxide layer may be applied to the structure 200. The oxide layer may be patterned. For example, a mask may be applied to the oxide layer leaving portions of the oxide layer uncovered. The uncovered portions of the oxide layer may be etched to form oxide layers 3518, 3522, 3618, and 3622.

Dummy gates 3520, 3524, 3620, and 3624 may be formed on the oxide layers 3518, 3522, 3618, and 3622, respectively. Patterning may be used to form the dummy gates 3520, 3524, 3620, and 3624. For example, a poly silicon layer may be deposited on the structure 200 subsequent to forming the oxide layers 3518, 3522, 3618, and 3622. The poly silicon layer may be patterned and etched to form the dummy gates 3520, 3524, 3620, and 3624.

A photo resist 3502 may be applied to the structure 200 subsequent to forming the dummy gates 3520, 3524, 3620, and 3624. The photo resist 3502 may cover a portion of the dummy gate 3524 and a portion of the Pwell 3506. The photo resist 3502 may also cover the dummy gate 3620, a portion of the dummy gate 3624, the n-well 3654, and a portion of the n-well 3656. The structure 200 may include n-regions 3510, 3512, 3516, and 3664. The n-regions 3510, 3512, 3516, and 3664 may be formed by n-type lightly doped source and drain (LDD) implantation or by n-type pocket implantation. The n-regions 3510, 3512, 3516, and 3664 may be formed on the portions of the Pwell 3504, the Pwell 3506, and the Pwell 3656 that are exposed (e.g., not covered by the photo resist 3502). The photo resist 3502 may be removed (e.g., etched) subsequent to forming the n-regions 3510, 3512, 3516, and 3664.

Referring to FIGS. 37-38, diagrams of a side view of the structure 200 of FIG. 2 as formed during a process of fabricating an electronic device are disclosed. A photo resist 3702 may be applied to the structure 200. The photo resist 3702 may cover the Pwell 3504, the dummy gate 3520, a portion of the Pwell 3506, a portion of the dummy gate 3524. The photo resist 3702 may also cover a portion of the dummy gate 3624 and a portion of the Nwell 3656. The structure 200 may include p-regions 3714, 3860, 3862, and 3866. The p-regions 3714, 3860, 3862, and 3866 may be formed by p-type LDD implantation or by p-type pocket implantation. The p-regions 3714, 3860, 3862, and 3866 may be formed on the portions of the Pwell 3506, the Nwell 3654, and the Nwell 3656 that are exposed (e.g., not covered by the photo resist 3702). The photo resist 3702 may be removed (e.g., etched) subsequent to forming the p-regions 3714, 3860, 3862, and 3866.

Referring to FIGS. 39-40, diagrams of a side view of the structure 200 of FIG. 2 as formed during a process of fabricating an electronic device are disclosed. The structure 200 may include spacers 244, 246, 248, 250, 294, 296, 298, and 252. For example, a SiN layer may be formed (e.g., deposited) on the structure 200 beside the dummy gates 3520, 3524, 3620, and 3624. Portions of the SiN layer may be removed (e.g., etched) to form the spacers 244, 246, 248, 250, 294, 296, 298, and 252.

A photo resist 3902 may be applied to the structure 200 subsequent to forming the spacers 244, 246, 248, 250, 294, 296, 298, and 252. The photo resist 3902 may cover a portion of the Pwell 3506 and a portion of the dummy gate 3524. The photo resist 3902 may also cover the Nwell 3654, the dummy gate 3620, a portion of the dummy gate 3624, and a portion of the Nwell 3656. The structure 200 may include the n-regions 218 (e.g., N+ source), 220 (e.g., N+ drain), 224 (e.g., N+ drain), and 272 (e.g., N+ source). For example, the n-regions 218, 220, 224, and 272 may be formed by performing n-type (e.g., N+) implantation subsequent to forming the photo resist 3902. The photo resist 3902 may be removed (e.g., etched) subsequent to forming the n-regions 218, 220, 224, and 272.

Referring to FIGS. 41-42, diagrams of a side view of the structure 200 of FIG. 2 as formed during a process of fabricating an electronic device are disclosed. A photo resist 4102 may be applied to the structure 200 subsequent to removing the photo resist 3902. The photo resist 4102 may cover the Pwell 3504, the dummy gate 3520, a portion of the Pwell 3506, and a portion of the dummy gate 3524. The photo resist 4102 may also cover a portion of the dummy gate 3624 and a portion of the Nwell 3656. The structure 200 may include p-regions 222 (e.g., P+ source), 268 (e.g., P+ drain), 270 (e.g., P+ drain), and 274 (e.g., P+ source). For example, the p-regions 222, 268, 270, and 274 may be formed by performing p-type (e.g., P+) implantation subsequent to forming the photo resist 4102. The photo resist 4102 may be removed (e.g., etched) subsequent to forming the p-regions 222, 268, 270, and 274.

Referring to FIGS. 43-44, diagrams of a side view of the structure 200 of FIG. 2 as formed during a process of fabricating an electronic device are disclosed. An ILD layer 4302 may be applied to the structure 200. The ILD layer may be etched or polished to expose the dummy gates 3520, 3524, 3620, and 3624. The dummy gates 3520, 3524, 3620, and 3624, and the oxide layers 3518, 3522, 3618, and 3622 may be removed (e.g., etched) to form recesses between each pair of the spacers 244, 246, 248, 250, 294, 296, 298, and 252. A high dielectric constant (a high-k) layer may be applied in the recesses. The high-k layer may include a hafnium oxide layer and another (e.g., silicon) oxide layer. A high dielectric constant (HK) layer 4326 may be applied in the recess between the spacers 244 and 246, an HK layer 4328 may be applied in the recess between the spacers 248 and 250, an HK layer 4476 may be applied in the recess between the spacers 294 and 296, and an HK layer 4478 may be applied in the recess between the spacers 298 and 252.

The recess between the spacers 244 and 246 and the recess between the spacers 248 and 250 may be filled with a first metal (e.g., an n-metal) to form the n-metal gates 230 and 232, respectively. The recess between the spacers 294 and 296 and the recess between the spacers 298 and 252 may be filled with a second metal (e.g., a p-metal) to form the p-metal gates 280 and 282, respectively. Chemical mechanical planarization (CMP) may be performed, e.g., to etch and/or to polish the first metal and the second metal.

Referring to FIGS. 45-46, diagrams of a side view of the structure 200 of FIG. 2 as formed during a process of fabricating an electronic device are disclosed. A photo resist 4502 may be applied to the structure 200. The photo resist 4502 may cover a portion of the n-metal gate 232. The photo resist 4502 may also cover a portion of the ILD layer 4302 corresponding to (e.g., covering) the p-region 222 and the spacer 250. For example, the photo resist 4502 may not be applied to (e.g., may be etched from) a portion of the ILD layer 4302 corresponding to (e.g., covering) at least the spacers 244, 246, and 248, the n-regions 218, 220, and 224, and a first portion of the STI layer 3508. As another example, the photo resist 4502 may not be applied to (e.g., may be etched from) the n-metal gate 230 and a portion of the n-metal gate 232.

The photo resist 4502 may cover the p-metal gate 280, a portion of the p-metal gate 282, and a second portion of the STI layer 3508. The photo resist 4502 may also cover a portion of the ILD layer 4302 corresponding to (e.g., covering) the p-regions 268, 270, and 274 and the spacers 294, 296, and 298. For example, the photo resist 4502 may not be applied to (e.g., may be etched from) a portion of the ILD layer 4302 corresponding to at least the n-region 272 and the spacer 252. As another example, the photo resist 4502 may not be applied to (e.g., may be etched from) a portion of the p-metal gate 282.

An oxide etch may be performed subsequent to applying the photo resist 4502. The oxide etch may remove the portions of the ILD layer 4302 that are not covered by the photo resist 4502. For example, the oxide etch may remove the portions of the ILD layer 4302 corresponding to at least the n-regions 218, 220, 224, and 272, the spacers 244, 246, 248, and 252, and the first portion of the STI layer 3508. The photo resist 4502 may be removed subsequent to performing the oxide etch.

Referring to FIGS. 47-48, diagrams of a side view of the structure 200 of FIG. 2 as formed during a process of fabricating an electronic device are disclosed. Recesses may be formed (e.g., by wet/dry etching) in the n-regions 218, 220, 224, and 272. Each of the n-regions 218, 220, 224, and 272 may include a mobility enhancement strength layer. For example, silicon carbide (SiC) regions may be epitaxially grown in the recesses. Each of the SiC regions may be an n-type (e.g., N+) region. For example, the structure 200 may include an n-type source 4734 (e.g., an N+SiC region) in a recess formed in the n-region 218, an n-type drain 4736 (e.g., an N+SiC region) in a recess formed in the n-region 220, an n-type drain 4738 (e.g., an N+SiC region) in a recess formed in the n-region 224, and an n-type source 4890 (e.g., an N+SiC region) in a recess formed in the n-region 272. At least one of the n-type source 4734, the n-type drain 4736, the n-type drain 4738, or the n-type source 4890 may be a mobility enhancement strength layer (e.g., a SiC region). The mobility enhancement strength layer may provide compression strength, tensile strength, or both.

Referring to FIGS. 49-50, diagrams of a side view of the structure 200 of FIG. 2 as formed during a process of fabricating an electronic device are disclosed. An ILD layer 4902 (e.g., an oxide layer or a silicon mononitride (SiN) layer) may be applied to the structure 200 subsequent to forming the n-type sources 4734 and 4890 and the n-type drains 4736 and 4738. A photo resist 4904 may be applied to the structure 200. For example, the photo resist 4904 may cover a portion of the ILD layer 4902 corresponding to (e.g., covering) at least the n-type sources 4734 and 4890, the n-type drains 4736 and 4738, the spacers 244, 246, 248, and 252, and the first portion of the STI layer 3508. The photo resist 4904 may also cover the n-metal gate 230, a portion of the n-metal gate 232, and a portion of the p-metal gate 282. The photo resist 4904 may not be applied to (e.g., may be etched from) a portion of the ILD layer 4902 corresponding to at least the p-regions 222, 268, 270, and 274, and the spacers 250, 294, 296, and 298. The photo resist 4904 may not be applied to (e.g., may be etched from) a portion of the n-metal gate 232, the p-metal gate 280, and a portion of the p-metal gate 282.

An etch (e.g., an oxide etch or a SiN etch) may be performed on the structure 200 subsequent to applying the photo resist 4904. The etch may remove a portion of the ILD layer 4902 that is not covered by the photo resist 4904. For example, the etch may remove the portion of the ILD layer 4902 corresponding to (e.g., covering) at least the p-regions 222, 268, 270, and 274, and the spacers 250, 294, 296, and 298. The photo resist 4904 may be removed (e.g., etched) subsequent to etching the ILD layer 4902.

Referring to FIGS. 51-52, diagrams of a side view of the structure 200 of FIG. 2 as formed during a process of fabricating an electronic device are disclosed. Recesses may be formed (e.g., by wet/dry etching) in each of the p-regions 222, 268, 270, and 274. Each of the p-regions 222, 268, 270, and 274 may include a mobility enhancement strength layer. For example, SiGe regions may be epitaxially grown in the recesses. Each of the SiGe regions may be a p-type (e.g., P+) region. For example, the structure 200 may include a p-type source 5140 (e.g., a P+SiGe region) in a recess formed in the p-region 222, a p-type source 5284 (e.g., a P+SiGe region) in a recess formed in the p-region 268, a p-type drain 5286 (e.g., a P+SiGe region) in a recess formed in the p-region 270, and a p-type drain 5288 (e.g., a P+SiGe region) in a recess formed in a p-region 274. At least one of the p-type source 5140, the p-type source 5284, the p-type drain 5286, or the p-type drain 5288 may include a mobility enhancement strength layer (e.g., a SiGe region). The mobility enhancement strength layer may provide compression strength, tensile strength, or both.

Referring to FIGS. 53-54, diagrams of a side view of the structure 200 of FIG. 2 as formed during a process of fabricating an electronic device are disclosed. An etch (e.g., an oxide etch or a SiN etch) may be performed on the structure 200 subsequent to forming the p-type sources 5140 and 5284, and the p-type drains 5286 and 5288. The etch may be performed to remove the remaining portions of the ILD layer 4902. An ILD layer 5302 may be applied to the structure 200 subsequent to removing the ILD layer 4902. Chemical mechanical planarization (CMP) may be performed on the ILD layer 5302.

Referring to FIGS. 55-56, diagrams of a side view of the structure 200 of FIG. 2 as formed during a process of fabricating an electronic device are disclosed. Contacts 201, 203, 205, 207, 209, 211, 213, 215, 217, 219, 221, and 223 may be formed. For example, recesses may be formed in the structure 200 using etching. In a particular embodiment, a mask may be applied to the ILD layer 5302 leaving portions of the ILD layer 5302 uncovered. Etching may be performed on the uncovered portions to form the recesses. The recesses may be filled with conducting material (e.g., metal, poly-silicon, or silicide) to form the contacts 201, 203, 205, 207, 209, 211, 213, 215, 217, 219, 221, and 223.

The contact 201 may be a source contact for the n-type source 4734, the contact 205 may be a drain contact for the n-type drain 4736, and the contact 203 may be a gate contact for the n-metal gate 230. The n-type source 4734, the n-type drain 4736, and the n-metal gate 230 may form the nMOS 204. The nMOS 204 may correspond to a planar nMOS. The contact 213 may be a source contact for the p-type source 5284, the contact 217 may be a drain contact for the p-type drain 5286, and the contact 215 may be a gate contact for the p-metal gate 280. The p-type source 5284, the p-type drain 5286, and the p-metal gate 280 may form the pMOS 214. The pMOS 214 may correspond to a planar pMOS.

The contact 211 may be a source contact for the p-type source 5140, the contact 207 may be a drain contact for the n-type drain 4738, and the contact 209 may be a gate contact for the n-metal gate 232. The p-type source 5140, the n-type drain 4738, and the n-metal gate 232 may form the nTFET 206. The contact 223 may be a source contact for the n-type source 4890, the contact 219 may be a drain contact for the p-type drain 5288, and the contact 221 may be a gate contact for the p-metal gate 282. The n-type source 4890, the p-type drain 5288, and the p-metal gate 282 may form the pTFET 216.

The structure 200 may thus include a CMOS transistor (e.g., the nMOS 204 and the pMOS 214) and a TFET (e.g., the nTFET 206 and the pTFET 216). At least one of the nMOS 204, the pMOS 214, the nTFET 206, or the pTFET 216 may include a mobility enhancement strength layer. The mobility enhancement strength layer may provide compression strength, tensile strength, or both.

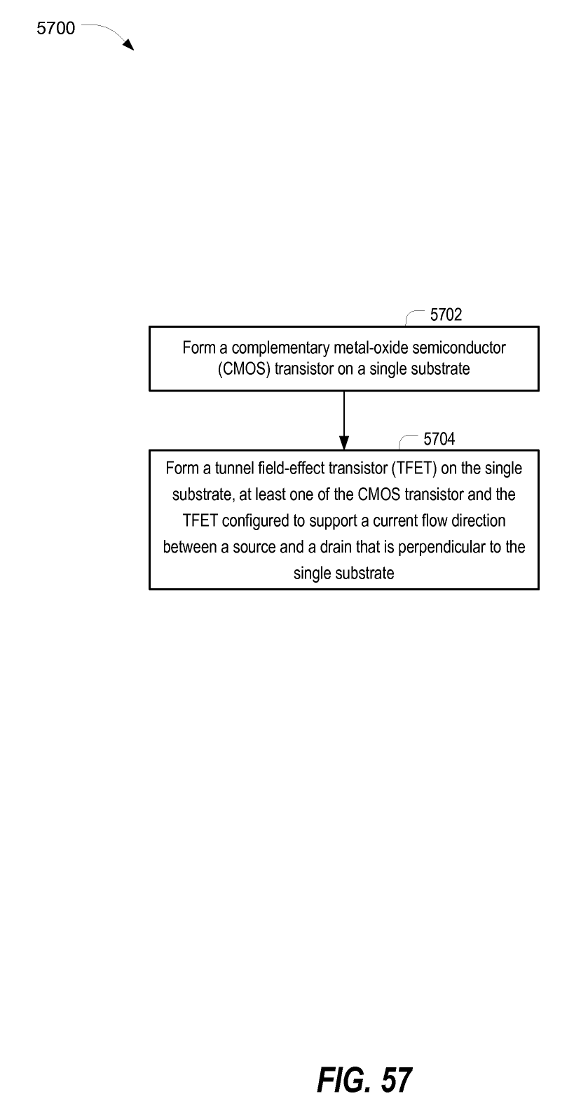

FIG. 57 is a flow chart illustrating a particular embodiment of a method 5700 of fabricating a structure (e.g., the structure 100 of FIG. 1). The method 5700 includes forming a complementary metal-oxide semiconductor (CMOS) transistor on a single substrate, at 5702. For example, a CMOS transistor including the nMOS 104 and the pMOS 114 of FIG. 1 may be formed on the substrate 102, as described with reference to FIGS. 3-33.

The method 5700 also includes forming a tunnel field-effect transistor (TFET) on the single substrate, at 5704. For example, a TFET transistor including the nTFET 106 and the pTFET 116 of FIG. 1 may be formed on the substrate 102, as described with reference to FIGS. 3-33. At least one of the CMOS transistor or the TFET transistor may be configured to support a current flow direction between a source and a drain that is perpendicular to the single substrate. For example, the nMOS 104 may support a current flow direction between the n-type source 1814 and the n-type drain 1822 that is perpendicular to the substrate 102. As another example, the pMOS 114 may support a current flow direction between the p-type source 1964 and the p-type drain 1972 that is perpendicular to the substrate 102. As a further example, the nTFET 106 may support a current flow direction between the p-type source 1824 and the n-type drain 1816. As an additional example, the pTFET 116 may support a current flow direction between the n-type source 1974 and the p-type drain 1966.

The method 5700 may enable fabrication of a structure (e.g., the structure 100 of FIG. 1) that includes a CMOS transistor and a TFET on a single substrate. The CMOS transistor may perform higher priority (e.g., critical) operations and the TFET may perform lower priority (e.g., non-critical) operations. For example, higher priority operations may be assigned to the CMOS transistor and lower priority operations may be assigned to the TFET.

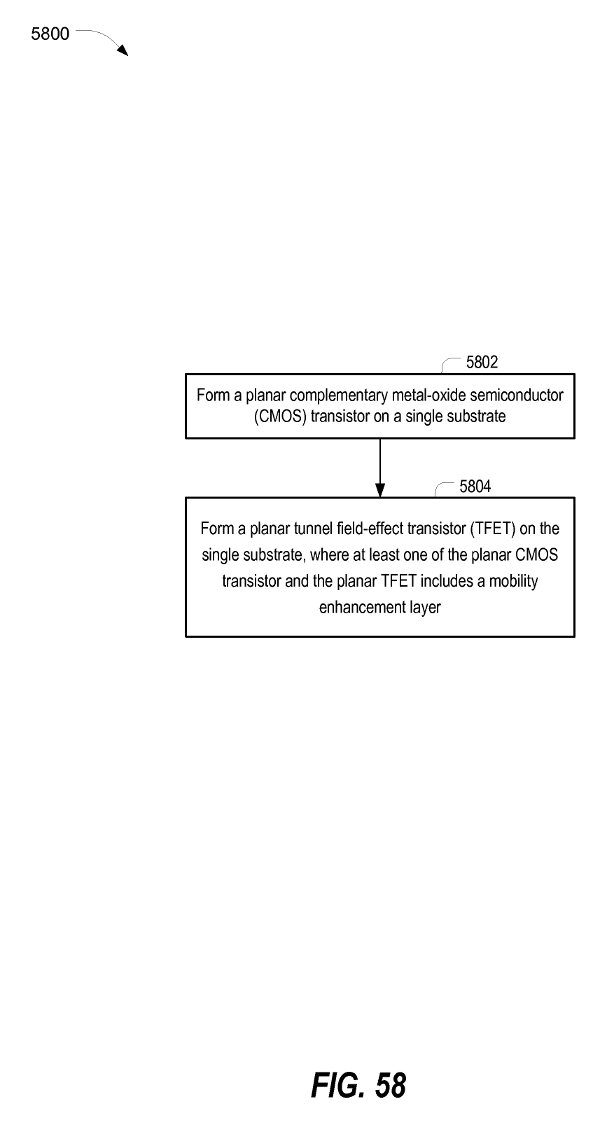

FIG. 58 is a flow chart illustrating a particular embodiment of a method 5800 of fabricating a structure (e.g., the structure 200 of FIG. 2). The method 5800 includes forming a planar complementary metal-oxide semiconductor (CMOS) transistor on a single substrate, at 5802. For example, a planar CMOS transistor including the nMOS 204 and the pMOS 214 of FIG. 2 may be formed on the substrate 202, as described with reference to FIGS. 34-56.

The method 5800 also includes forming a planar tunnel field-effect transistor (TFET) on the single substrate, at 5804. For example, a TFET transistor including the nTFET 206 and the pTFET 216 of FIG. 2 may be formed on the substrate 202, as described with reference to FIGS. 34-56. At least one of the planar CMOS transistor or the planar TFET may include a mobility enhancement strength layer. For example, the nMOS 204 may include the n-type source 4734, the n-type drain 4736, or both. The n-type source 4734, the n-type drain 4736, or both, may correspond to a mobility enhancement strength layer. As another example, the pMOS 214 may include the p-type source 5140, the n-type drain 4738, or both. The p-type source 5140, the n-type drain 4738, or both, may correspond to a mobility enhancement strength layer. As an additional example, the nTFET 206 may include the p-type source 5284, the p-type drain 5286, or both. The p-type source 5284, the p-type drain 5286, or both, may correspond to a mobility enhancement strength layer. As a further example, the pTFET 216 may include the p-type drain 5288, the n-type source 4890, or both. The p-type drain 5288, the n-type source 4890, or both, may correspond to a mobility enhancement strength layer. The mobility enhancement strength layer may include at least one of silicon-carbide or silicon-germanium. The mobility enhancement strength layer may provide compression strength, tensile strength, or both.

The method 5800 may enable fabrication of a structure (e.g., the structure 200 of FIG. 2) that includes a planar CMOS transistor and a planar TFET on a single substrate. The planar CMOS transistor may perform higher priority (e.g., critical) operations and the planar TFET may perform lower priority (e.g., non-critical) operations. For example, higher priority operations may be assigned to the planar CMOS transistor and lower priority operations may be assigned to the planar TFET.

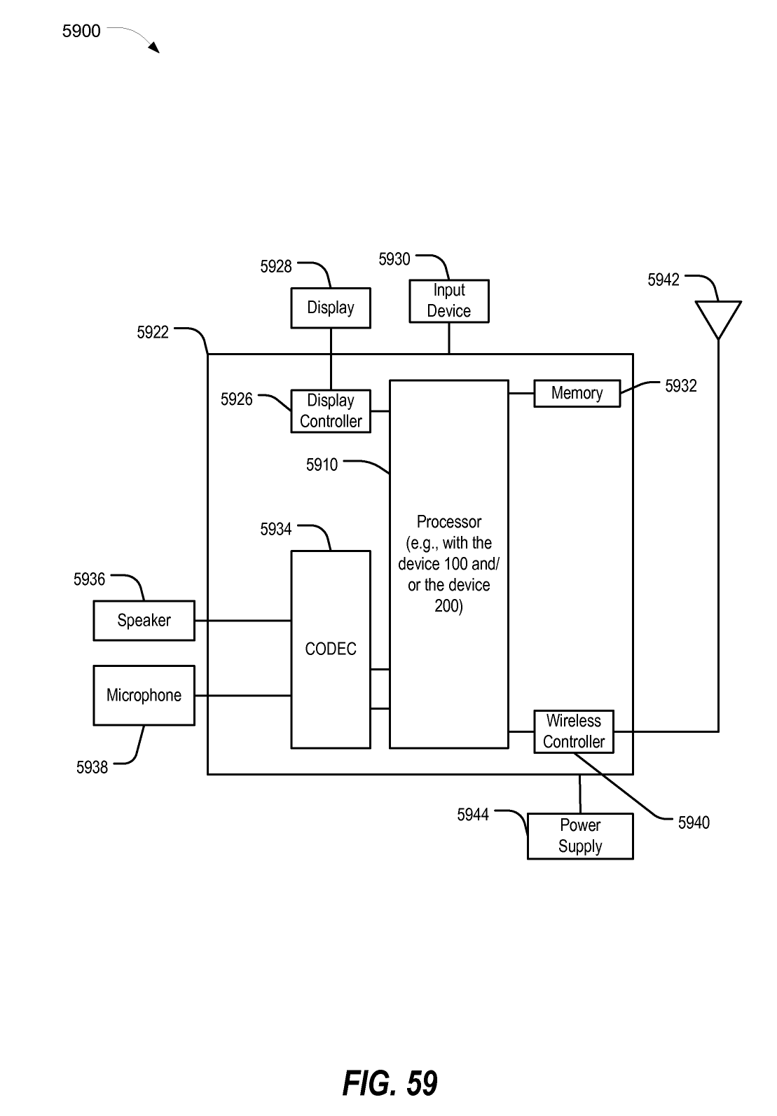

Referring to FIG. 59, a block diagram of a particular illustrative embodiment of a wireless communication device is depicted and generally designated 5900. The wireless communication device 5900 includes a processor 5910, such as a digital signal processor (DSP), coupled to a memory 5932 (e.g., a random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of non-transient storage medium known in the art). The processor 5910 may include the device 100 of FIG. 1, the device 200 of FIG. 2, or both. In a particular embodiment, the memory 5932 may include the device 100 of FIG. 1, the device 200 of FIG. 2, or both.

FIG. 59 also shows a display controller 5926 that is coupled to the processor 5910 and to a display 5928. A coder/decoder (CODEC) 5934 may also be coupled to the processor 5910. A speaker 5936 and a microphone 5938 may be coupled to the CODEC 5934.

FIG. 59 also indicates that a wireless controller 5940 may be coupled to the processor 5910 and may be further coupled to an antenna 5942. In a particular embodiment, the processor 5910, the display controller 5926, the memory 5932, the CODEC 5934, and the wireless controller 5940 are included in a system-in-package or system-on-chip device 5922. In a particular embodiment, an input device 5930 and a power supply 5944 are coupled to the system-on-chip device 5922. Moreover, in a particular embodiment, as illustrated in FIG. 59, the display 5928, the input device 5930, the speaker 5936, the microphone 5938, the antenna 5942, and the power supply 5944 are external to the system-on-chip device 5922. However, each of the display 5928, the input device 5930, the speaker 5936, the microphone 5938, the antenna 5942, and the power supply 5944 may be coupled to a component of the system-on-chip device 5922, such as an interface or a controller. The antenna 5942, the display controller 5926, the CODEC 5934, the wireless controller 5940, the input device 5930, the power supply 5944, the speaker 5936, the microphone 5938, the display 5928, or a combination thereof, may include the device 100 of FIG. 1, the device 200 of FIG. 2, or both.

The wireless communication device 5900 may include a mobile phone, a cellular phone, a portable computer, a radio, a satellite radio, a communication device, a portable music player, a portable digital video player, a navigation device, a personal digital assistant (PDA), a mobile location data unit, a set top box, an entertainment unit, a fixed location data unit, a desktop computer, a monitor, a computer monitor, a television, a tuner, a music player, a digital music player, a video player, a digital video player, a digital video disc (DVD) player, or a combination thereof.

The foregoing disclosed devices and functionalities, e.g., as described in reference to any one or more of FIGS. 1-59, may be designed and configured into computer files (e.g. RTL, GDSII, GERBER, etc.) stored on computer readable media. The computer readable media may be non-transitory. The computer files (e.g., data files) may indicate design information corresponding to one or more semiconductor devices. Some or all such files may be provided to fabrication handlers who fabricate devices based on the design information. Resulting products include semiconductor wafers that are then cut into semiconductor die and packaged into a semiconductor chip. The semiconductor chips may be employed in the devices described above.

Although one or more of FIGS. 1-59 may illustrate systems, devices, and/or methods according to the teachings of the disclosure, the disclosure is not limited to these illustrated systems, devices, and/or methods. Embodiments of the disclosure may be suitably employed in any device that includes integrated circuitry including memory, a processor, and on-chip circuitry.

One or more functions or components of any of FIGS. 1-59 as illustrated or described herein may be combined with one or more other portions of another of FIGS. 1-59. Accordingly, no single embodiment described herein should be construed as limiting and embodiments of the disclosure may be suitably combined without departing form the teachings of the disclosure.

Those of skill would further appreciate that the various illustrative logical blocks, configurations, modules, circuits, and algorithm steps described in connection with the embodiments disclosed herein may be implemented as electronic hardware, computer software executed by a processor, or combinations of both. Various illustrative components, blocks, configurations, modules, circuits, and steps have been described above generally in terms of their functionality. Whether such functionality is implemented as hardware or processor executable instructions depends upon the particular application and design constraints imposed on the overall system. Skilled artisans may implement the described functionality in varying ways for each particular application, but such implementation decisions should not be interpreted as causing a departure from the scope of the present disclosure.

The steps of a method or algorithm described in connection with the embodiments disclosed herein may be embodied directly in hardware, in a software module executed by a processor, or in a combination of the two. A software module may reside in random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of non-transient storage medium known in the art. An exemplary storage medium is coupled to the processor such that the processor can read information from, and write information to, the storage medium. In the alternative, the storage medium may be integral to the processor. The processor and the storage medium may reside in an application-specific integrated circuit (ASIC). The ASIC may reside in a computing device or a user terminal. In the alternative, the processor and the storage medium may reside as discrete components in a computing device or user terminal A storage device is not a signal.

The previous description of the disclosed embodiments is provided to enable a person skilled in the art to make or use the disclosed embodiments. Various modifications to these embodiments will be readily apparent to those skilled in the art, and the principles defined herein may be applied to other embodiments without departing from the scope of the disclosure. Thus, the present disclosure is not intended to be limited to the embodiments shown herein but is to be accorded the widest scope possible consistent with the principles and novel features as defined by the following claims.

1. An apparatus comprising a structure that includes:
a single substrate;
a planar complementary metal-oxide semiconductor (CMOS) transistor formed on the single substrate;
a planar tunnel field-effect transistor (TFET) formed on the single substrate; and
a mobility enhancement strength layer included in the planar CMOS transistor or included in the planar TFET.

2. The apparatus of claim 1, wherein the mobility enhancement strength layer comprises at least one of silicon-carbide or silicon-germanium.

3. The apparatus of claim 1, wherein the mobility enhancement strength layer corresponds to an n-type source of the planar CMOS transistor or to an n-type drain of the planar CMOS transistor.

4. The apparatus of claim 3, wherein the n-type source and the n-type drain comprise silicon carbide.

5. The apparatus of claim 1, wherein the mobility enhancement strength layer corresponds to a p-type source of the planar CMOS transistor or to a p-type drain of the planar CMOS transistor.

6. The apparatus of claim 5, wherein the p-type source and the p-type drain comprise silicon germanium.

7. The apparatus of claim 1, wherein the mobility enhancement strength layer corresponds to a p-type source of the planar TFET or to an n-type drain of the planar TFET.

8. The apparatus of claim 7, wherein the p-type source comprises silicon germanium, and wherein the n-type drain comprises silicon carbide.

9. The apparatus of claim 1, wherein the mobility enhancement strength layer corresponds to an n-type source of the planar TFET or to a p-type drain of the planar TFET.

10. The apparatus of claim 9, wherein the n-type source comprises silicon carbide, and wherein the p-type drain comprises silicon germanium.

11. An apparatus comprising a structure that includes:
a single substrate;
a complementary metal-oxide semiconductor (CMOS) transistor formed on the single substrate; and
a tunnel field-effect transistor (TFET) formed on the single substrate, at least one of the CMOS transistor or the TFET configured to support a current flow direction between a source and a drain that is perpendicular to the single substrate.

12. The apparatus of claim 11, wherein the CMOS transistor is a fin-shaped field effect transistor (finFET).

13. The apparatus of claim 11, further comprising:
a first n-type source and a first p-type source of the CMOS transistor; and
a first n-type drain and a first p-type drain of the TFET,
wherein the first n-type source, the first p-type source, the first n-type drain, and the first p-type drain are co-planar.

14. The apparatus of claim 13, further comprising:
a second n-type drain and a second p-type drain of the CMOS transistor; and
a second p-type source and a second n-type source of the TFET,
wherein the second n-type drain is aligned with the first n-type source,
wherein the second p-type drain is aligned with the first p-type source,
wherein the second p-type source is aligned with the first n-type drain,
wherein the second n-type source is aligned with the first p-type drain, and
wherein the second n-type drain, the second p-type drain, the second n-type source, and the second p-type source are co-planar.

15. The apparatus of claim 14, further comprising:
a first intrinsic layer of the CMOS transistor, the first intrinsic layer between the first re-type source and the second n-type drain;
a second intrinsic layer of the CMOS transistor, the second intrinsic layer between the first p-type source and the second p-type drain;
a third intrinsic layer of the TFET, the third intrinsic layer between the first n-type drain and the second p-type source; and
a fourth intrinsic layer of the TFET, the fourth intrinsic layer between the first p-type drain and the second n-type source,
wherein the first intrinsic layer, the second intrinsic layer, the third intrinsic layer, and the fourth intrinsic layer are co-planar.

16. A method of forming a structure, the method comprising:
forming a complementary metal-oxide semiconductor (CMOS) transistor on a single substrate; and
forming a tunnel field-effect transistor (TFET) on the single substrate, at least one of the CMOS transistor or the TFET configured to support a current flow direction between a source and a drain that is perpendicular to the single substrate.

17. The method of claim 16, wherein forming the CMOS transistor includes forming a first n-type source and a first p-type source on the single substrate, and wherein forming the TFET includes forming a first n-type drain and a first p-type drain on the single substrate.

18. The method of claim 17, wherein the first n-type source, the first n-type drain, the first p-type source, and the first p-type drain are co-planar.

19. The method of claim 17, wherein forming the CMOS transistor includes forming a second n-type drain on the first n-type source and forming a second p-type drain on the first p-type source, and wherein forming the TFET includes forming a second p-type source on the first n-type drain and forming a second n-type source on the first p-type drain.

20. The method of claim 19, wherein the second n-type drain, the second p-type source, the second p-type drain, and the second n-type source are co-planar.

21. The method of claim 19, wherein forming the CMOS transistor includes forming a first intrinsic layer on the first n-type source, wherein the second n-type drain is formed on the first intrinsic layer, wherein forming the TFET includes forming a second intrinsic layer on the first n-type drain, and wherein the second p-type source is formed on the second intrinsic layer.

22. The method of claim 21, wherein the first intrinsic layer and the second intrinsic layer are co-planar.

23. The method of claim 19, wherein forming the CMOS transistor includes forming a first intrinsic layer on the first p-type source, wherein the second p-type drain is formed on the first intrinsic layer, wherein forming the TFET includes forming a second intrinsic layer on the first p-type drain, and wherein the second n-type source is formed on the second intrinsic layer.

24. The method of claim 23, wherein the first intrinsic layer and the second intrinsic layer are co-planar.

25. A method of forming a structure, the method comprising:
forming a planar complementary metal-oxide semiconductor (CMOS) transistor on a single substrate; and
forming a planar tunnel field-effect transistor (TFET) on the single substrate, wherein at least one of the planar CMOS transistor or the planar TFET includes a mobility enhancement strength layer.

26. The method of claim 25, wherein the mobility enhancement strength layer comprises at least one of silicon-carbide or silicon-germanium.

27. The method of claim 25, further comprising forming a first n-type source, a first p-type source, a first n-type drain, and a first p-type drain of the planar CMOS transistor, wherein the mobility enhancement strength layer includes at least one of the first n-type source, the first p-type source, the first n-type drain, or the first p-type drain.

28. The method of claim 25, further comprising forming a second p-type source, a second n-type source, a second n-type drain, and a second p-type drain of the planar TFET, wherein the mobility enhancement strength layer includes at least one of the second n-type source, the second p-type source, the second n-type drain, or the second p-type drain.

29. The method of claim 28, wherein at least one of the second n-type source or the second n-type drain includes silicon-carbide.

30. The method of claim 28, wherein at least one of the second p-type source or the second p-type drain includes silicon-germanium.

31. A computer-readable medium storing data which is usable by fabrication equipment to form a device, the device comprising:
a single substrate;
a planar complementary metal-oxide semiconductor (CMOS) transistor formed on the single substrate;
a planar tunnel field-effect transistor (TFET) formed on the single substrate; and
a mobility enhancement strength layer included in the planar CMOS transistor or included in the planar TFET.

32. The computer-readable medium of claim 31, wherein the mobility enhancement strength layer comprises at least one of silicon-carbide or silicon-germanium.

33. A computer-readable medium storing data which is usable by fabrication equipment to form a device, the device comprising:
a single substrate;
a complementary metal-oxide semiconductor (CMOS) transistor formed on the single substrate; and
a tunnel field-effect transistor (TFET) formed on the single substrate, at least one of the CMOS transistor or the TFET configured to support a current flow direction between a source and a drain that is perpendicular to the single substrate.

34. The computer-readable medium of claim 33, wherein the CMOS transistor comprises a fin-shaped field effect transistor (finFET).
